(19) United States
(12) Patent Application Publication
(10) Pub. No.: US 2006/0268623 A1
(43) Pub. Date: Nov. 30, 2006

(54) Transmitting/receiving apparatus and method in a closed-loop MIMO system

(75) Inventors: Chan-Byoung Chae, Seoul (KR); Sung-Ryul Yun, Suwon-si (KR); Won-Il Roh, Yongin-si (KR); Hong-Sil Jeong, Seoul (KR); Dong-Seek Park, Yongin-si (KR); Jeong-Tae Oh, Yongin-si (KR); Kyun-Byoung Ko, Hwasung-si (KR); Seung-Hoon Nam, Seoul (KR); Marcos Daniel Katz, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/370,803

(22) Filed: Mar. 9, 2006

(30) Foreign Application Priority Data
Mar. 9, 2005 (KR) 2005-0019851
Mar. 14, 2005 (KR) 2005-0021163
Apr. 28, 2005 (KR) 2005-0035675
May 3, 2005 (KR) 2005-0037174

(51) Int. Cl. G11C 7/10

(52) U.S. Cl. 365/189.01

(57) ABSTRACT

An apparatus and method for preventing power imbalance between antennas in a closed-loop MIMO system are provided. In a transmitter in the MIMO system, a first calculator generates a vector by multiplying a transmission vector by a beamforming matrix and a second calculator generates a plurality of antenna signals by multiplying the vector by a predetermined phase rotation matrix.

### CROSS REFERENCE TO RELATED PATENT APPLICATIONS

This application claims the benefit under 35 U.S.C. § 119(a) of Korean patent applications serial numbers 2005-19851, 2005-21163, 2005-35675 and 2005-37174 filed in the Korean Intellectual Property Office on Mar. 9, 2005, Mar. 14, 2005, Apr. 28, 2005 and May 3, 2005, respectively. The entire contents of all four of these Korean patent applications are hereby incorporated by reference.

### BACKGROUND OF THE INVENTION

1. Field of the Invention

The present invention relates to a closed-loop Multiple-Input Multiple-Output (MIMO) system. More particularly, the present invention relates to an apparatus and method for correcting power imbalance between antennas in a closed-loop MIMO communication system using a codebook.

2. Description of the Related Art

In general, many systems use beamforming for transmission in order to increase received Signal-to-Noise Ratio (SNR) or decrease the Mean Square Error (MSE) of a received signal. To select an optimal beamforming vector or matrix, a receiver (or terminal) needs to compute the following equation and sends back the resulting vector or matrix w₁ to a transmitter on a feedback channel.

$$arg {min}_{xbit} \frac{{E}_{s}}{{N}_{o}} tr \{ {( {I}_{{N}_{t}} + \frac{{E}_{s}}{{N}_{r} {N}_{o}} {w}_{l}^{H} {H}^{H} {Hw}_{l} )}^{- 1} \} \qquad ( 1 )$$

where w₁ denotes a beamforming vector or matrix selected from a known codebook, Nₜ denotes the number of transmit antennas, Nᵣ denotes the number of receive antennas, I denotes an identity matrix, H denotes a channel coefficient matrix between the transmit antennas and the receive antennas, Eₛ denotes signal energy, and Nₒ denotes noise power.

Particularly, since the Frequency Division Duplex (FDD) system cannot utilize channel reciprocity, it uses quantized feedback information. The current IEEE 802.16e system determines a beamforming matrix using 3-bit or 6-bit quantized feedback information.

For better understanding, the beamforming matrix codebook used for the IEEE 802.16e system is taken as an example. Table 1 below illustrates part of the codebook.

TABLE 1

| Index | Column 1 | Column 2 |
|---|---|---|
| w1 | 0 | 0 |
| | 1 | 0 |
| | 0 | 1 |
| w2 | −0.7201 + j0.3126 | 0.2483 + j0.2684 |
| | −0.2326 | 0.1898 + j0.5419 |
| | 0.1898 − j0.5419 | 0.7325 |
| w3 | −0.0659 − j0.1371 | −0.6283 + j0.5763 |
| | 0.9537 | 0.0752 + j0.2483 |
| | 0.0752 − j0.2483 | −0.4537 |
| w4 | −0.0063 − j0.6527 | 0.4621 + j0.3321 |
| | 0.1477 | 0.4394 − j0.5991 |
| | 0.4394 + j0.5991 | 0.3522 |
| w5 | 0.7171 − j0.3202 | −0.2533 − j0.2626 |
| | −0.2337 | 0.1951 + j0.5390 |
| | 0.1951 − j0.5390 | 0.7337 |
| w6 | 0.4819 + j0.4517 | 0.2963 + j0.4801 |
| | 0.1354 | −0.7127 − j0.1933 |
| | −0.7127 + j0.1933 | 0.3692 |
| w7 | 0.0686 + j0.1386 | 0.6200 − j0.5845 |
| | 0.9522 | 0.0770 + j0.2521 |
| | 0.0770 − j0.2521 | −0.4522 |
| w8 | −0.0054 + j0.6540 | −0.4566 − j0.3374 |
| | 0.1446 | 0.4363 − j0.6009 |
| | 0.4363 + j0.6009 | 0.3554 |

In Table 1, Column 1 and Column 2 represent transmission streams and the rows in each w represent transmit antennas, that is, first, second and third antennas, respectively. Table 1 is for the case of three transmit antennas, two transmission streams and 3-bit feedback information. The receiver computes Eq. (1) sequentially over the beamforming matrices w1 to w8 in the above codebook and selects a beamforming matrix that minimizes Eq. (1). The receiver then feeds back the index of the selected beamforming matrix in three bits. The transmitter carried out beamforming by multiplying a transmission vector by the beamforming matrix indicated by the index. This beamforming enhances link performance. The current IEEE 802.16e system adopts 19 different codebooks for two to four transmit antennas, one to four streams, and 3-bit or 6-bit feedback information.

As noted from Table 1, however, the codebook-based beamforming widely used suffers from power imbalance due to power concentration on a particular antenna. If the receiver selects w1 as an optimal w over a received channel in Table 1, the first antenna is excluded from transmission in w1. The same problem is observed in many other codebooks. Typically, a system separately allocates its limited total transmit power to antennas and given w1, it concentrates the transmit power on the second and third antennas.

FIG. 1 is a block diagram of a conventional closed-loop MIMO system.

Referring to FIG. 1, a transmitter includes a coder and modulator 101, a beamforming matrix decider 102, a beamformer 103, and a plurality of transmit antennas 104 to 105. A receiver includes a plurality of receive antennas 106 to 107, a channel and symbol estimator 108, a demodulator and decoder 109, and a beamforming matrix selector 110.

In a transmission operation, the coder and modulator 101 encodes transmission data in a predetermined coding scheme and modulates the coded data in a predetermined modulation scheme. The beamforming matrix decider 102 generates a beamforming matrix indicated by a feedback index received from the receiver. The beamformer 103 multiplies the transmission vector (that is, complex symbols) received form the coder and modulator 101 by the beamforming matrix and transmits the resulting signals through the antennas 104 to 105.

In a reception operation, signals received through the antennas 106 to 107 are added with noise n₁ to n_{N}_{_{R}} and then provided to the channel and symbol estimator 108. The channel and symbol estimator 108 calculates a channel coefficient matrix by channel estimation and estimates received symbols using a received vector and the channel coefficient matrix. The demodulator and decoder 109 demodulates and decodes the estimated symbols, thereby recovering the original information data. Meanwhile, the beamforming matrix selector 110 selects a beamforming matrix by computing Eq. (1) using the channel coefficient matrix and a codebook and feeds back the index of the selected beamforming matrix to the transmitter.

However, the codebooks proposed so far include beamforming matrices which lead to power concentration on particular antennas, as described above. Accordingly, a need exists for a method of correcting power imbalance between antennas.

### SUMMARY OF THE INVENTION

An exemplary object of the present invention is to address at least the above problems and/or disadvantages and to provide at least the advantages below. Accordingly, an object of the present invention is to provide an apparatus and method for correcting power imbalance between antennas and reducing peak power in a closed-loop MIMO communication system.

Another exemplary object of the present invention is to provide an apparatus and method for preventing power concentration on a particular antenna and reducing peak power by multiplying a transmission vector by a beamforming matrix and then multiplying the product by a predetermined phase rotation matrix in a closed-loop MIMO communication system.

A further exemplary object of the present invention is to provide an apparatus and method for preventing power concentration on a particular antenna and reducing peak power by multiplying a transmission vector by a beamforming matrix and then multiplying the product by a unitary matrix in a closed-loop MIMO communication system using a codebook.

Still another object of the present invention is to provide an apparatus and method for preventing power concentration on a particular antenna and reducing peak power by multiplying a transmission vector by a beamforming matrix and then multiplying the product by a Hadamard matrix in a closed-loop MIMO communication system using a codebook.

Yet another exemplary object of the present invention is to provide an apparatus and method for preventing power concentration on a particular antenna and reducing peak power by multiplying a transmission vector by a beamforming matrix and then multiplying the product by a Vandermonde matrix in a closed-loop MIMO communication system using a codebook.

Yet further exemplary object of the present invention is to provide an apparatus and method for preventing power concentration on a particular antenna and reducing peak power by multiplying a transmission vector by a beamforming matrix and then multiplying the product by a Fast Fourier Transform (FFT) matrix in a closed-loop MIMO communication system using a codebook.

The above exemplary objects are achieved by providing an apparatus and method for preventing power imbalance between antennas in a closed-loop MIMO system.

According to one exemplary aspect of the present invention, in a transmitter in a MIMO system, a first calculator generates a vector by multiplying a transmission vector by a beamforming matrix and a second calculator generates a plurality of antenna signals by multiplying the vector by a predetermined phase rotation matrix.

According to another exemplary aspect of the present invention, in a transmission method in a MIMO system, a vector is generated by multiplying a transmission vector by a beamforming matrix, and a plurality of antenna signals are generated by multiplying the vector by a predetermined phase rotation matrix.

According to a further exemplary aspect of the present invention, in a transmitter in a MIMO system, a generator, which has a codebook with new beamforming matrices created by multiplying predetermined beamforming matrices by a phase rotation matrix, generates a beamforming matrix by searching the codebook based on feedback information received from a receiver. A calculator generates a plurality of antenna signals by multiplying a transmission vector by the generated beamforming matrix.

According to still another exemplary aspect of the present invention, in a transmission method in a MIMO system, a beamforming matrix is generated by searching a stored codebook based on feedback information received from a receiver. The codebook has new beamforming matrices created by multiplying predetermined beamforming matrices by a phase rotation matrix. A plurality of antenna signals are generated by multiplying a transmission vector by the generated beamforming matrix.

### BRIEF DESCRIPTION OF THE DRAWINGS

The above and other objects, features and advantages of the present invention will become more apparent from the following detailed description when taken in conjunction with the accompanying drawings in which like reference numerals will be understood to refer to like parts, components and structures, where:

FIG. 1 is a block diagram of a conventional closed-loop MIMO system;

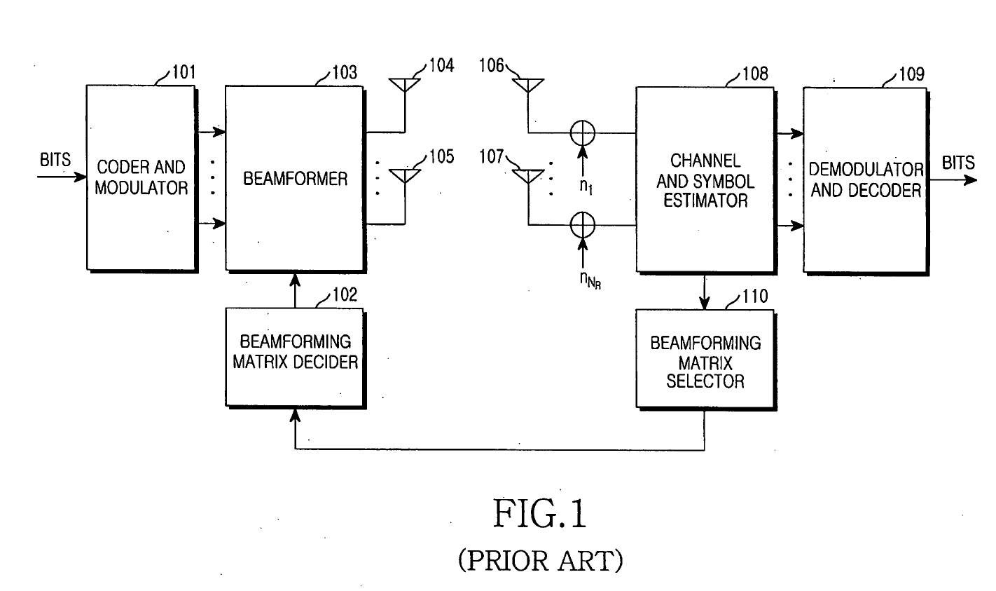

FIG. 2 is a block diagram of a closed-loop MIMO system according to an embodiment of the present invention;

FIG. 3 is a graph illustrating the Complementary Cumulative Distribution Function (CCDF) of the Peak-to-Average Power Ratios (PAPRs) of antennas for the use of a conventional codebook and the use of a codebook of the present invention; and

FIG. 4 is a graph comparing the conventional codebook with the codebook of the present invention in terms of link performance.

### DETAILED DESCRIPTION OF EXEMPLARY EMBODIMENTS

Certain exemplary embodiments of the present invention will be described herein below with reference to the accompanying drawings. In the following description, description of well-known functions or constructions have been omitted for clarity and conciseness.

An exemplary implementation of the present invention is intended to provide a method of correcting power imbalance between antennas by multiplying a transmission vector by a beamforming matrix and then by a predetermined phase rotation matrix, prior to transmission in a closed-loop MIMO communication system.

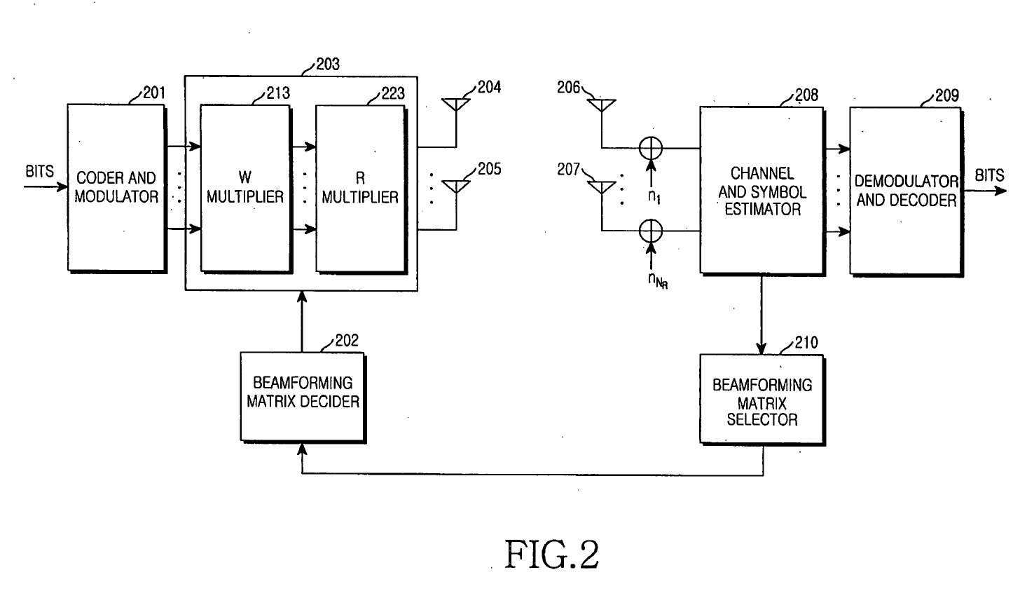

FIG. 2 is a block diagram of a closed-loop MIMO system according to an exemplary embodiment of the present invention.

Referring to FIG. 2, a transmitter includes a coder and modulator 201, a beamforming matrix decider 202, a beamformer 203, and a plurality of transmit antennas 204 to 205. A receiver includes a plurality of receive antennas 206 to 207, a channel and symbol estimator 208, a demodulator and decoder 209, and a beamforming matrix selector 210. In an exemplary implementation of the present invention, the beamformer 203 includes a beamforming matrix W multiplier 213 and a phase rotation matrix R multiplier 223 according to the present invention.

In a reception operation, signals received through the antennas 206 to 207 are added with noise n₁ to n_{N}_{_{R}} and then provided to the channel and symbol estimator 208. The channel and symbol estimator 208 calculates a channel coefficient matrix by channel estimation and estimates received symbols using a received vector and the channel coefficient matrix. A Zero-Forcing (ZF) or Minimum Mean Square Error (MMSE) algorithm can be used as a symbol estimation algorithm. The demodulator and decoder 209 demodulates and decodes the estimated symbols, thereby recovering the original information data.

Meanwhile, the beamforming matrix selector 210 selects a beamforming matrix by computing Eq. (1) using the channel coefficient matrix and a codebook according to an exemplary embodiment of the present invention and feeds back the index of the selected beamforming matrix to the transmitter. Eq. (1) is one of many algorithms available in selection of a beamforming matrix and thus any other algorithm can be used instead.

A codebook according to an exemplary embodiment of the present invention includes beamforming matrices w_{new} created by multiplying beamforming matrices w by a predetermined phase rotation matrix R. The codebook may provide only the new beamforming matrices w_{new}, or both beamforming matrices w and the phase rotation matrix R. Hence, the feedback information sent to the transmitter can be an index indicating w_{new} or w. Exemplary embodiments of the phase rotation matrix R will be described later in detail with reference to relevant equations.

In a transmission operation, the coder and modulator 201 encodes transmission data in a predetermined coding scheme and modulates the coded data in a predetermined modulation scheme. The coding scheme can be convolutional coding, turbo coding, complementary turbo coding, or Low Density Parity Check (LDPC) coding. The modulation scheme can be Binary Phase Shift Keying (BPSK), Quadrature Phase Shift Keying (QPSK), 8ary Quadrature Amplitude Modulation (8 QAM), 16 QAM or 64 QAM. One bit (s=1) is mapped to one signal point (complex signal) in BPSK, two bits (s=2) to one complex signal in QPSK, three bits (s=3) to one complex signal in 8 QAM, four bits (s=4) to one complex signal in 16 QAM, and six bits (s=6) to one complex signal in 64 QAM.

The beamforming matrix selector 202 generates a beamforming matrix w and the phase rotation matrix R according to the feedback index received from the receiver.

In the beamformer 203, the W multiplier 213 multiplies the transmission vector (that is, complex symbols) received form the coder and modulator 201 by the beamforming matrix w. The R multiplier 223 multiplies the vector received form the W multiplier 213 by the phase rotation matrix R and transmits the resulting signals through the antennas 204 to 205. Consequently, the transmission vector is multiplied by the new beamforming matrix w_{new} of the present invention, prior to transmission.

The following is a description of a phase rotation matrix R according to an exemplary embodiment the present invention.

The phase rotation matrix R has no effects on link performance, that is, the nature of an optimally designed codebook. It does not affect the PAPR of each antenna either. Yet, the use of the phase rotation matrix R addresses the problems of power imbalance and high peak power.

In order to keep the nature of the current codebooks intact, the phase rotation matrix R should be designed so as to substantially fulfill the following conditions.

The phase rotation matrix R should be unitary. Although any unitary matrix can be used as the phase rotation matrix R, the following three exemplary implementations are provided to facilitate understanding, considering implementation complexity.

<Hadamard Matrix>

For two transmit antennas (Nₜ=2), a 2×2 Hadamard matrix is used as the phase rotation matrix R, expressed as

$${R}_{2} = \frac{1}{\sqrt{2}} [ \begin{matrix}1 & 1 \\ 1 & - 1\end{matrix} ] \qquad ( 2 )$$

For four transmit antennas (Nₜ=4), a 4×4 Hadamard matrix is used as the phase rotation matrix R, expressed as

$${R}_{4} = \frac{1}{2} [ \begin{matrix}1 & 1 & 1 & 1 \\ 1 & - 1 & 1 & - 1 \\ 1 & 1 & - 1 & - 1 \\ 1 & - 1 & - 1 & 1\end{matrix} ] \qquad ( 3 )$$

<Vandermonde Matrix>

For Nₜ antennas, a Nₜ×Nₜ Vandermonde matrix is used as the phase rotation matrix R, expressed as

$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ] \qquad ( 4 )$$

where aᵢ=exp(j2π(i+¼)/Nₜ), (i=0, 1, 2, . . . , Nₜ−1)

With the Vandermonde matrix, a unitary matrix can be created freely for any number of transmit antennas.

For example, for two transmit antennas (Nₜ=2), a 2×2 Vandermonde matrix is used as the phase rotation matrix R, expressed as

$${R}_{2} = \frac{1}{\sqrt{2}} [ \begin{matrix}1 & {ⅇ}^{j π / 4} \\ 1 & {ⅇ}^{j 5 π / 4}\end{matrix} ] \qquad ( 5 )$$

For three transmit antennas (Nₜ=3), a 3×3 Vandermonde matrix is used as the phase rotation matrix R, expressed as

$${R}_{3} = \frac{1}{\sqrt{3}} [ \begin{matrix}1 & {ⅇ}^{j 5 π / 4} & {ⅇ}^{j 10 π / 9} \\ 1 & {ⅇ}^{j 11 π / 4} & {ⅇ}^{j 4 π / 9} \\ 1 & {ⅇ}^{j 17 π / 4} & {ⅇ}^{j 16 π / 9}\end{matrix} ] \qquad ( 6 )$$

<FFT Matrix>

For Nₜ antennas, a Nₜ×Nₜ FFT matrix is used as the phase rotation matrix R, expressed as

$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ] \qquad ( 7 )$$

where aₖⁿ=exp(−j2π×k×n)/Nₜ), (k, n=0, 1, 2, . . . , Nₜ−1)

Like the Vandermonde matrix, with the FFT matrix, a unitary matrix can be created freely for any number of transmit antennas.

The phase rotation matrices R created in the above exemplary manner are multiplied by the following codebook adopted in IEEE 802.16e, resulting in a new codebook as shown in Table 2 below.

TABLE 2
For two transmit antennas, one transmission
stream, and 3-bit feedback information,

```
m_cb(:, :, 1) =
  1.0000
  −0.0000 − 0.0000i
m_cb(:, :, 2) =
  0.7940 − 0.0000i
  −0.5801 + 0.1818i
m_cb(:, :, 3) =
  0.7940
  0.0576 + 0.6501i
m_cb(:, :, 4) =
  0.7941 − 0.0000i
  −0.2978 − 0.5298i
m_cb(:, :, 5) =
  0.7941
  0.6038 + 0.0689i
m_cb(:, :, 6) =
  0.3289 − 0.0000i
  0.6614 + 0.6740i
m_cb(:, :, 7) =
  0.5112
  0.4754 − 0.7160i
m_cb(:, :, 8) =
  0.3289 + 0.0000i
  −0.8779 − 0.3481i
```

For two transmit antennas, one transmission
stream, and 6-bit feedback information,

```
m_cb(:, :, 1) =
  1.0000 + 0.0000i
  0 − 0.0000i
m_cb(:, :, 2) =
  0.9744 + 0.0000i
  0.2035 − 0.0961i
m_cb(:, :, 3) =
  0.9743 − 0.0000i
  −0.2250 − 0.0050i
m_cb(:, :, 4) =
  0.9743 + 0.0000i
  −0.0621 + 0.2166i
m_cb(:, :, 5) =
  0.9741 + 0.0000i
  0.1822 + 0.1340i
m_cb(:, :, 6) =
  0.9739 + 0.0000i
  0.0022 − 0.2268i
m_cb(:, :, 7) =
  0.9321 + 0.0000i
  −0.2925 + 0.2136i
m_cb(:, :, 8) =
  0.9320 + 0.0000i
  −0.2243 − 0.2847i
m_cb(:, :, 9) =
  0.9208 − 0.0000i
  0.3890 + 0.0303i
m_cb(:, :, 10) =
  0.9207 + 0.0000i
  0.2238 − 0.3196i
m_cb(:, :, 11) =
  0.9127 + 0.0000i
  0.2039 + 0.3542i
m_cb(:, :, 12) =
  0.9048 − 0.0000i
  −0.4083 − 0.1212i
m_cb(:, :, 13) =
  0.8992 − 0.0000i
  −0.0783 + 0.4305i
m_cb(:, :, 14) =
  0.8972 + 0.0000i
  0.0093 − 0.4416i
m_cb(:, :, 15) =
  0.8694 + 0.0000i
  0.4479 − 0.2085i
m_cb(:, :, 16) =
  0.8629 − 0.0000i
  0.4307 + 0.2645i
m_cb(:, :, 17) =
  0.8603 + 0.0000i
  −0.4974 + 0.1120i
m_cb(:, :, 18) =
  0.8436 + 0.0000i
  −0.3229 + 0.4291i
m_cb(:, :, 19) =
  0.8361 + 0.0000i
  −0.2299 − 0.4980i
m_cb(:, :, 20) =
  0.8221 − 0.0000i
  0.1186 + 0.5569i
m_cb(:, :, 21) =
  0.8218 + 0.0000i
  −0.4533 − 0.3452i
m_cb(:, :, 22) =
  0.8160 + 0.0000i
  0.2462 − 0.5229i
m_cb(:, :, 23) =
  0.8094 + 0.0000i
  0.5844 + 0.0586i
m_cb(:, :, 24) =
  0.7886 + 0.0000i
  −0.6044 − 0.1135i
m_cb(:, :, 25) =
  0.7757 + 0.0000i
  0.3859 + 0.4993i
m_cb(:, :, 26) =
  0.7741 + 0.0000i
  −0.0058 − 0.6330i
m_cb(:, :, 27) =
  0.7737 − 0.0000i
  −0.1463 + 0.6164i
m_cb(:, :, 28) =
  0.7618 + 0.0000i
  −0.5536 + 0.3364i
m_cb(:, :, 29) =
  0.7556 + 0.0000i
  0.4976 − 0.4259i
m_cb(:, :, 30) =
  0.7252 + 0.0000i
  0.6112 + 0.3170i
m_cb(:, :, 31) =
  0.7194 − 0.0000i
  0.6705 − 0.1815i
m_cb(:, :, 32) =
  0.6907 − 0.0000i
  −0.4194 + 0.5891i
m_cb(:, :, 33) =
  0.6842 + 0.0000i
  −0.2715 − 0.6769i
m_cb(:, :, 34) =
  0.6828 + 0.0000i
  −0.7221 + 0.1111i
m_cb(:, :, 35) =
  0.6762 + 0.0000i
  0.2196 + 0.7032i
m_cb(:, :, 36) =
  0.6744 + 0.0000i
  −0.5482 − 0.4946i
m_cb(:, :, 37) =
  0.6657 − 0.0000i
  0.3454 − 0.6615i
m_cb(:, :, 38) =
  0.6343 + 0.0000i
  −0.7415 − 0.2187i
m_cb(:, :, 39) =
  0.6156 − 0.0000i
  0.5315 + 0.5819i
m_cb(:, :, 40) =
  0.6129 + 0.0000i
  0.0320 − 0.7895i
m_cb(:, :, 41) =
  0.6128 + 0.0000i
  −0.1037 + 0.7834i
m_cb(:, :, 42) =
  0.5915 − 0.0000i
  −0.6850 + 0.4254i
m_cb(:, :, 43) =
  0.5837 − 0.0000i
  0.6336 − 0.5078i
m_cb(:, :, 44) =
  0.5645 + 0.0000i
  0.7888 + 0.2432i
m_cb(:, :, 45) =
  0.5466 + 0.0000i
  0.8211 − 0.1643i
m_cb(:, :, 46) =
  0.5173 − 0.0000i
  −0.4757 − 0.7114i
m_cb(:, :, 47) =
  0.5119 + 0.0000i
  −0.4493 + 0.7322i
m_cb(:, :, 48) =
  0.5018 + 0.0000i
  −0.8626 + 0.0643i
m_cb(:, :, 49) =
  0.4938 − 0.0000i
  0.2917 + 0.8192i
m_cb(:, :, 50) =
  0.4780 + 0.0000i
  0.3911 − 0.7865i
m_cb(:, :, 51) =
  0.4562 + 0.0000i
  −0.7982 − 0.3934i
m_cb(:, :, 52) =
  0.4281 + 0.0000i
  0.6905 + 0.5831i
m_cb(:, :, 53) =
  0.4259 + 0.0000i
  −0.0806 − 0.9012i
m_cb(:, :, 54) =
  0.3921 + 0.0000i
  −0.7794 + 0.4887i
m_cb(:, :, 55) =
  0.3822 − 0.0000i
  0.7782 − 0.4983i
m_cb(:, :, 56) =
  0.3761 − 0.0000i
  0.9220 + 0.0917i
m_cb(:, :, 57) =
  0.3716 − 0.0000i
  −0.1199 + 0.9206i
m_cb(:, :, 58) =
  0.3080 − 0.0000i
  −0.5759 − 0.7573i
m_cb(:, :, 59) =
  0.2816 + 0.0000i
  −0.9571 − 0.0684i
m_cb(:, :, 60) =
  0.2568 + 0.0000i
  0.3374 − 0.9057i
m_cb(:, :, 61) =
  0.2346 + 0.0000i
  0.4811 + 0.8447i
m_cb(:, :, 62) =
  0.1951 − 0.0000i
  −0.5888 + 0.7844i
m_cb(:, :, 63) =
  0.1653 + 0.0000i
  0.9768 − 0.1362i
m_cb(:, :, 64) =
  0.0866 − 0.0000i
  −0.6811 − 0.7271i
```

For two transmit antennas, two transmission
streams, and 3-bit feedback information,

| | |
|---|---|
| m_cb(:, :, 1) = | |
| 1 0 | |
| 0 1 | |
| m_cb(:, :, 2) = | |
| 0.7940 | −0.5801 − 0.1818i |
| −0.5801 + 0.1818i | −0.7940 |
| m_cb(:, :, 3) = | |
| 0.7940 | 0.0576 − 0.6051i |
| 0.0576 + 0.6051i | −0.7940 |
| m_cb(:, :, 4) = | |
| 0.7941 | −0.2978 + 0.5298i |
| −0.2978 − 0.5298i | −0.7941 |
| m_cb(:, :, 5) = | |
| 0.7941 | 0.6038 − 0689i |
| 0.6038 + 0.0689i | −0.7941 |
| m_cb(:, :, 6) = | |
| 0.3289 | 0.6614 − 0.6740i |
| 0.6614 + 0.6740i | −0.3289 |
| m_cb(:, :, 7) = | |
| 0.5112 | 0.4754 + 0.7160i |
| 0.4754 − 7160i | −0.5112 |
| m_cb(:, :, 8) = | |
| 0.3289 | −0.8779 + 0.3481i |
| −0.8779 − 0.3481i | −0.3289 |

For two transmit antennas, two transmission
streams, and 6-bit feedback information,

| | |
|---|---|
| m_cb(:, :, 1) = | |
| 1 0 | |
| 0 1 | |
| m_cb(:, :, 2) = | |
| 0.9744 | 0.2035 + 0.0961i |
| 0.2035 − 0.0961i | −0.9744 |
| m_cb(:, :, 3) = | |
| 0.9743 | −0.2250 + 0.0050i |
| −0.2250 − 0.0050i | − 0.9743 |
| m_cb(:, :, 4) = | |
| 0.9743 | −0.0621 − 0.2166i |
| −0.0621 + 0.2166i | −0.9743 |
| m_cb(:, :, 5) = | |
| 0.9741 | 0.1822 − 0.1340i |
| 0.1822 + 0.1340i | −0.9741 |
| m_cb(:, :, 6) = | |
| 0.9739 | 0.0022 + 0.2268i |
| 0.0022 − 0.2268i | −0.9739 |
| m_cb(:, :, 7) = | |
| 0.9321 | −0.2925 − 0.2136i |
| −0.2925 + 0.2136i | −0.9321 |
| m_cb(:, :, 8) = | |
| 0.9320 | −0.2243 + 0.2847i |
| −0.2243 − 0.2847i | −0.9320 |
| m_cb(:, :, 9) = | |
| 0.9208 | 0.3890 − 0.0303i |
| 0.3890 + 0.0303i | −0.9208 |
| m_cb(:, :, 10) = | |
| 0.9207 | 0.2238 + 0.3196i |
| 0.2238 − 0.3196i | −0.9207 |
| m_cb(:, :, 11) = | |
| 0.9127 | 0.2039 − 0.3542i |
| 0.2039 + 0.3542i | −0.9127 |
| m_cb(:, :, 12) = | |
| 0.9048 | −0.4083 + 0.1212i |
| −0.4083 − 0.1212i | −0.9048 |
| m_cb(:, :, 13) = | |
| 0.8992 | −0.0783 − 0.4305i |
| −0.0783 + 0.4305i | −0.8992 |
| m_cb(:, :, 14) = | |
| 0.8972 | 0.0093 + 0.4416i |
| 0.0093 − 0.4416i | −0.8972 |
| m_cb(:, :, 15) = | |
| 0.8694 | 0.4479 + 0.2085i |
| 0.4479 − 0.2085i | −0.8694 |
| m_cb(:, :, 16) = | |
| 0.8629 | 0.4307 − 0.2645i |
| 0.4307 + 0.2645i | −0.8629 |
| m_cb(:, :, 17) = | |
| 0.8603 | −0.4974 − 0.1120i |
| −0.4974 + 0.1120i | −0.8603 |
| m_cb(:, :, 18) = | |
| 0.8436 | −0.3229 − 0.4291i |
| −0.3229 + 0.4291i | −0.8436 |
| m_cb(:, :, 19) = | |
| 0.8361 | −0.2299 − 0.4980i |
| −0.2299 − 0.4980i | −0.8361 |
| m_cb(:, :, 20) = | |
| 0.8221 | 10.1186 − 0.5569i |
| 0.1186 ÷ 0.5569i | −0.8221 |
| m_cb(:, :, 21) = | |
| 0.8218 | −0.4533 + 0.3452i |
| −0.4533 − 0.3452i | −0.8218 |
| m_cb(:, :, 22) = | |
| 0.8160 | 0.2462 + 0.5229i |
| 0.2462 − 0.5229i | −0.8160 |
| m_cb(:, :, 23) = | |
| 0.8094 | 0.5844 − 0.0586i |
| 0.5844 + 0.0586i | −0.8094 |
| m_cb(:, :, 24) = | |
| 0.7886 | −0.6044 + 0.1135i |
| −0.6044 − 0.1135i | −0.7886 |
| m_cb(:, :, 25) = | |
| 0.7757 | 0.3859 − 0.4993i |
| 0.3859 ÷ 0.4993i | −0.7757 |
| m_cb(:, :, 26) = | |
| 0.7741 | −0.0058 + 0.6330i |
| −0.0058 − 0.6330i | −0.7741 |
| m_cb(:, :, 27) = | |
| 0.7737 | −0.1463 − 0.6164i |
| −0.1463 + 0.6164i | −0.7737 |
| m_cb(:, :, 28) = | |
| 0.7618 | −0.5536 − 0.3364i |
| −0.5536 + 0.3364i | −0.7618 |
| m_cb(:, :, 29) = | |
| 0.7556 | 0.4976 + 0.4259i |
| 0.4976 − 0.4259i | −0.7556 |
| m_cb(:, :, 30) = | |
| 0.7252 | 0.6112 − 0.3170i |
| 0.6112 + 0.3170i | −0.7252 |
| m_cb(:, :, 31) = | |
| 0.7194 | 0.6705 + 0.1815i |
| 0.6705 − 0.1815i | −0.7194 |
| m_cb(:, :, 32) = | |
| 0.6907 | −0.4194 − 0.5891i |
| −0.4194 + 0.5891i | −0.6907 |
| m_cb(:, :, 33) = | |
| 0.6842 | −0.2715 + 0.6769i |
| −0.2715 − 0.6769i | −0.6842 |
| m_cb(:, :, 34) = | |
| 0.6828 | −0.7221 − 0.1111i |
| −0.7221 + 0.1111i | −0.6828 |
| m_cb(:, :, 35) = | |
| 0.6762 | 0.2196 − 0.7032i |
| 0.2196 + 0.7032i | −0.6762 |
| m_cb(:, :, 36) = | |
| 0.6744 | −0.5482 + 0.4946i |
| −0.5482 − 0.4946i | −0.6744 |
| m_cb(:, :, 37) = | |
| 0.6657 | 0.3454 + 0.6615i |
| 0.3454 − 0.6615i | −0.6657 |
| m_cb(:, :, 38) = | |
| 0.6343 | −0.7415 + 0.2187i |
| −0.7415 − 0.2187i | −0.6343 |
| m_cb(:, :, 39) = | |
| 0.6156 | 0.5315 − 0.5819i |
| 0.5315 + 0.5819i | −0.6156 |
| m_cb(:, :, 40) = | |
| 0.6129 | 0.0320 + 0.7895i |
| 0.0320 − 0.7895i | −0.6129 |
| m_cb(:, :, 41) = | |
| 0.6128 | −0.1037 − 0.7834i |
| −0.1037 + 0.7834i | −0.6128 |
| m_cb(:, :, 42) = | |
| 0.5915 | −0.6850 − 0.4254i |
| −0.6850 + 0.4254i | −0.5915 |
| m_cb(:, :, 43) = | |
| 0.5837 | 0.6336 + 0.5078i |
| 0.6336 − 0.5078i | −0.5837 |
| m_cb(:, :, 44) = | |
| 0.5645 | 0.7888 − 0.2432i |
| 0.7888 + 0.2432i | −0.5645 |
| m_cb(:, :, 45) = | |
| 0.5466 | 0.8211 + 0.1643i |
| 0.8211 − 0.1643i | −0.5468 |
| m_cb(:, :, 46) = | |
| 0.5173 | −0.4757 + 0.7114i |
| −0.4757 − 0.7114i | −0.5173 |
| m_cb(:, :, 47) = | |
| 0.5119 | −0.4493 − 0.7322i |
| −0.4493 + 0.7322i | −0.5119 |
| m_cb(:, :, 48) = | |
| 0.5018 | −0.8626 − 0.0643i |
| −0.8626 + 0.0643i | −0.5018 |
| m_cb(:, :, 49) = | |
| 0.4938 | 0.2917 + 0.8192i |
| 0.2917 + 0.8192i | −0.4938 |
| m_cb(:, :, 50) = | |
| 0.4780 | 0.3911 + 0.7865i |
| 0.3911 − 0.7865i | −0.4780 |
| m_cb(:, :, 51) = | |
| 0.4562 | −0.7982 + 0.3934i |
| −0.7982 − 0.3934i | −0.4562 |
| m_cb(:, :, 52) = | |
| 0.4281 | 0.6905 − 0.5831i |
| 0.6905 + 0.5831i | −0.4281 |
| m_cb(:, :, 53) = | |
| 0.4259 | −0.0806 + 0.9012i |
| −0.0806 − 0.9012i | −0.4259 |
| m_cb(:, :, 54) = | |
| 0.3921 | −0.7794 − 0.4887i |
| −0.7794 + 0.4887i | −0.3921 |
| m_cb(:, :, 55) = | |
| 0.3822 | 0.7782 + 0.4983i |
| 0.7782 − 0.4983i | −0.3822 |
| m_cb(:, :, 56) = | |
| 0.3761 | 0.9220 − 0.0917i |
| 0.9220 + 0.0917i | −0.3761 |
| m_cb(:, :, 57) = | |
| 0.3716 | −0.1199 − 0.9206i |
| −0.1199 + 0.9206i | −0.3716 |
| m_cb(:, :, 58) = | |
| 0.3080 | −0.5759 + 0.7573i |
| −0.5759 − 0.7573i | −0.3080 |
| m_cb(:, :, 59) = | |
| 0.2816 | −0.9571 + 0.0684i |
| −0.9571 − 0.0684i | −0.2816 |
| m_cb(:, :, 60) = | |
| 0.2568 | 0.3374 + 0.9057i |
| 0.3374 − 0.9057i | −0.2568 |
| m_cb(:, :, 61) = | |
| 0.2346 | 0.4811 − 0.8447i |
| 0.4811 + 0.8447i | −0.2346 |
| m_cb(:, :, 62) = | |
| 0.1951 | −0.5888 − 0.7844i |
| −0.5888 + 0.7844i | −0.1951 |
| m_cb(:, :, 63) = | |
| 0.1653 | 0.9768 + 0.1362i |
| 0.9768 − 0.1362i | −0.1653 |
| m_cb(:, :, 64) = | |
| 0.0866 | −0.6811 + 0.7271i |
| −0.6811 − 0.7271i | −0.0866 |

For three transmit antennas, one
transmission stream, and 3-bit feedback
information,

```
m_cb(:, :, 1) =
  1.0000
  −0.0000 − 0.0000i
  0.0000 − 0.0000i
m_cb(:, :, 2) =
  0.5000 + 0.0000i
  −0.7201 − 0.3126i
  0.2483 − 0.2684i
m_cb(:, :, 3) =
  0.5000 − 0.0000i
  −0.0659 + 0.1371i
  −0.6283 − 0.5763i
m_cb(:, :, 4) =
  0.5000 − 0.0000i
  −0.0063 + 0.6527i
  0.4621 − 0.3321i
m_cb(:, :, 5) =
  0.5000
  0.7171 + 0.3202i
  −0.2533 + 0.2626i
m_cb(:, :, 6) =
  0.4954 − 0.0000i
  0.4819 − 0.4517i
  0.2963 − 0.4801i
m_cb(:, :, 7) =
  0.5000
  0.0686 − 0.1386i
  0.6200 + 0.5845i
m_cb(:, :, 8) =
  0.5000 − 0.0000i
  −0.0054 − 0.6540i
  −0.4586 + 0.3374i
```

For three transmit antennas, one
transmission stream, and 6-bit feedback
information,

```
m_cb(:, :, 1) =
  0.5774
  −0.2887 + 0.5000i
  −0.2887 − 0.5000i
m_cb(:, :, 2) =
  0.5466 + 0.0000i
  0.2895 − 0.5522i
  0.2440 + 0.5030i
m_cb(:, :, 3) =
  0.5246 − 0.0000i
  −0.7973 − 0.0214i
  −0.2517 − 0.1590i
m_cb(:, :, 4) =
  0.5973 − 0.0000i
  0.7734 + 0.0785i
  0.1208 + 0.1559i
m_cb(:, :, 5) =
  0.4462
  −0.3483 − 0.6123i
  −0.5457 + 0.0829i
m_cb(:, :, 6) =
  0.6662
  0.2182 + 0.5942i
  0.3876 − 0.0721i
m_cb(:, :, 7) =
  0.4120 + 0.0000i
  0.3538 − 0.2134i
  −0.8046 − 0.1101i
m_cb(:, :, 8) =
  0.6840 + 0.0000i
  −0.4292 + 0.1401i
  0.5698 + 0.0605i
m_cb(:, :, 9) =
  0.4201 + 0.0000i
  0.1033 + 0.5446i
  −0.6685 − 0.2632i
m_cb(:, :, 10) =
  0.6591 + 0.0000i
  −0.1405 − 0.6096i
  0.3470 + 0.2319i
m_cb(:, :, 11) =
  0.4070 − 0.0000i
  −0.5776 + 0.5744i
  −0.4133 + 0.0006i
m_cb(:, :, 12) =
  0.6659 + 0.0000i
  0.6320 − 0.3939i
  0.0417 + 0.0157i
m_cb(:, :, 13) =
  0.3550
  −0.7412 − 0.0290i
  −0.3542 + 0.4454i
m_cb(:, :, 14) =
  0.7173 + 0.0000i
  0.4710 + 0.3756i
  0.1394 − 0.3211i
m_cb(:, :, 15) =
  0.3070 + 0.0000i
  −0.0852 − 0.4143i
  −0.5749 + 0.6295i
m_cb(:, :, 16) =
  0.7400
  −0.3257 + 0.3461i
  0.3689 − 0.3007i
m_cb(:, :, 17) =
  0.3169 − 0.0000i
  0.4970 + 0.1434i
  −0.6723 + 0.4243i
m_cb(:, :, 18) =
  0.7031
  −0.4939 − 0.4297i
  0.2729 − 0.0509i
m_cb(:, :, 19) =
  0.3649 − 0.0000i
  0.1983 + 0.7795i
  −0.3404 + 0.3224i
m_cb(:, :, 20) =
  0.6658 + 0.0000i
  0.2561 − 0.6902i
  −0.0958 − 0.0746i
m_cb(:, :, 21) =
  0.3942 − 0.0000i
  −0.3862 + 0.6614i
  0.0940 + 0.4992i
m_cb(:, :, 22) =
  0.6825
  0.5632 + 0.0490i
  −0.1901 − 0.4225i
m_cb(:, :, 23) =
  0.3873 + 0.0000i
  −0.4531 − 0.0567i
  0.2298 + 0.7672i
m_cb(:, :, 24) =
  0.7029 + 0.0000i
  −0.1291 + 0.4563i
  0.0228 − 0.5296i
m_cb(:, :, 25) =
  0.3870
  0.2812 − 0.3980i
  −0.0077 + 0.7828i
m_cb(:, :, 26) =
  0.6658 + 0.0000i
  −0.6858 − 0.0919i
  0.0666 − 0.2711i
m_cb(:, :, 27) =
  0.4436 + 0.0000i
  0.7305 + 0.2507i
  −0.0580 + 0.4511i
m_cb(:, :, 28) =
  0.5972
  −0.2385 − 0.7188i
  −0.2493 − 0.0873i
m_cb(:, :, 29) =
  0.5198 + 0.0000i
  0.2157 + 0.7332i
  0.2877 + 0.2509i
m_cb(:, :, 30) =
  0.5710 − 0.0000i
  0.4513 − 0.3043i
  −0.5190 − 0.3292i
m_cb(:, :, 31) =
  0.5517 + 0.0000i
  −0.3892 + 0.3011i
  0.5611 + 0.3724i
m_cb(:, :, 32) =
  0.5818 + 0.0000i
  0.1190 + 0.4328i
  −0.3964 − 0.5504i
m_cb(:, :, 33) =
  0.5437
  −0.1363 − 0.4648i
  0.4162 + 0.5446i
m_cb(:, :, 34) =
  0.5579
  −0.6391 + 0.3224i
  −0.2285 − 0.3523i
m_cb(:, :, 35) =
  0.5649 + 0.0000i
  0.6592 − 0.3268i
  0.1231 + 0.3526i
m_cb(:, :, 36) =
  0.4840 − 0.0000i
  −0.6914 − 0.3911i
  −0.3669 + 0.0096i
m_cb(:, :, 37) =
  0.6348
  0.5910 + 0.4415i
  0.2296 − 0.0034i
m_cb(:, :, 38) =
  0.4209
  0.0760 − 0.5484i
  −0.7180 + 0.0283i
m_cb(:, :, 39) =
  0.6833 + 0.0000i
  −0.1769 + 0.4784i
  0.5208 − 0.0412i
m_cb(:, :, 40) =
  0.4149
  0.3501 + 0.2162i
  −0.7772 − 0.2335i
m_cb(:, :, 41) =
  0.6726 + 0.0000i
  −0.4225 − 0.2866i
  0.5061 + 0.1754i
m_cb(:, :, 42) =
  0.4190 + 0.0000i
  −0.2524 + 0.6679i
  −0.5320 − 0.1779i
m_cb(:, :, 43) =
  0.6547
  0.2890 − 0.6562i
  0.1615 + 0.1765i
m_cb(:, :, 44) =
  0.3843 + 0.0000i
  −0.7637 + 0.3120i
  −0.3465 + 0.2272i
m_cb(:, :, 45) =
  0.6900
  0.6998 + 0.0252i
  0.0406 − 0.1786i
m_cb(:, :, 46) =
  0.3263 − 0.0000i
  −0.4920 − 0.3199i
  −0.4413 + 0.5954i
m_cb(:, :, 47) =
  0.7365 + 0.0000i
  0.0693 + 0.4971i
  0.2728 − 0.3623i
m_cb(:, :, 48) =
  0.3038 + 0.0000i
  0.3052 − 0.2326i
  −0.6770 + 0.5496i
m_cb(:, :, 49) =
  0.7270 − 0.0000i
  −0.5479 − 0.0130i
  0.3750 − 0.1748i
m_cb(:, :, 50) =
  0.3401
  0.4380 + 0.5298i
  −0.5470 + 0.3356i
m_cb(:, :, 51) =
  0.6791 − 0.0000i
  −0.1741 − 0.7073i
  0.0909 − 0.0028i
m_cb(:, :, 52) =
  0.3844 + 0.0000i
  −0.1123 + 0.8251i
  −0.1082 + 0.3836i
m_cb(:, :, 53) =
  0.6683 − 0.0000i
  0.5567 − 0.3796i
  −0.2017 − 0.2423i
m_cb(:, :, 54) =
  0.3940 − 0.0000i
  −0.5255 + 0.3339i
  0.2176 + 0.6401i
m_cb(:, :, 55) =
  0.6976 + 0.0000i
  0.2872 + 0.3740i
  −0.0927 − 0.5314i
m_cb(:, :, 56) =
  0.3819 − 0.0000i
  −0.1507 − 0.3542i
  0.1342 + 0.8294i
m_cb(:, :, 57) =
  0.6922 + 0.0000i
  −0.5051 + 0.2745i
  0.0904 − 0.4269i
m_cb(:, :, 58) =
  0.4083 − 0.0000i
  0.6327 − 0.1488i
  −0.0942 + 0.6341i
m_cb(:, :, 59) =
  0.6306 + 0.0000i
  −0.5866 − 0.4869i
  −0.0583 − 0.1337i
m_cb(:, :, 60) =
  0.4841 − 0.0000i
  0.5572 + 0.5928i
  0.0898 + 0.3096i
m_cb(:, :, 61) =
  0.5761
  0.1868 − 0.6492i
  −0.4292 − 0.1659i
m_cb(:, :, 62) =
  0.5431 + 0.0000i
  −0.1479 + 0.6238i
  0.4646 + 0.2796i
m_cb(:, :, 63) =
  0.5764 − 0.0000i
  0.4156 + 0.1263i
  −0.4947 − 0.4840i
m_cb(:, :, 64) =
  0.5490 + 0.0000i
  −0.3963 − 0.1208i
  0.5426 + 0.4822i
```

For three transmit antennas, two
transmission streams, and 3-bit feedback
information,

| | |
|---|---|
| m_cb(:, :, 1) = | |
| 0 0 | |
| 1 0 | |
| 0 1 | |
| m_cb(:, :, 2) = | |
| −0.7201 + 0.3126i | 0.2483 + 0.2684i |
| −0.2326 | 0.1698 + 0.5419i |
| 0.1898 − 0.5419i | 0.7325 |
| m_cb(:, :, 3) = | |
| −0.0659 − 0.1371i | −0.6283 + 0.5763i |
| 0.9537 | 0.0752 + 0.2483i |
| 0.0752 − 0.2483i | −0.4537 |
| m_cb(:, :, 4) = | |
| −0.0063 − 0.6527i | 0.4621 + 0.3321i |
| 0.1477 | 0.4394 − 0.5991i |
| 0.4394 + 0.5991i | 0.3522 |
| m_cb(:, :, 5) = | |
| 0.7171 − 0.3202i | −0.2533 − 0.2626i |
| −0.2337 | 0.1951 + 0.5390i |
| 0.1951 − 0.5390i | 0.7337 |
| m_cb(:, :, 6) = | |
| 0.4819 + 0.4517i | 0.2963 + 0.4801i |
| 0.1354 | −0.7127 − 0.1933i |
| −0.7127 + 0.1933i | 0.3592 |
| m_cb(:, :, 7) = | |
| 0.0686 + 0.13861 | 0.6200 − 0.5845i |
| 0.9522 | 0.0770 + 0.2521i |
| 0.0770 − 0.2521i | −0.4522 |
| m_cb(:, :, 8) = | |
| −0.0054 + 0.6540i | −0.4566 − 0.3374i |
| 0.1446 | 0.4363 − 0.6009i |
| 0.4363 + 0.6009i | 0.3554 |

For three transmit antennas, two
transmission streams, and 6-bit feedback
information,

| | |
|---|---|
| m_cb(:, :, 1) = | |
| 1.0000 | 0 |
| 0 | 1.0000 |
| 0 | −0.0000 − 0.0000i |
| m_cb(:, :, 2) = | |
| 1.0000 | 0 |
| 0 | 0.7940 − 0.0000i |
| 0 | −0.5801 + 0.1818i |
| m_cb(:, :, 3) = | |
| 1.0000 | 0 |
| 0 | 0.7940 |
| 0 | 0.0576 + 0.6051i |
| m_cb(:, :, 4) = | |
| 1.0000 | 0 |
| 0 | 0.7941 − 0.0000i |
| 0 | −0.2978 − 0.5298i |
| m_cb(:, :, 5) = | |
| 1.0000 | 0 |
| 0 | 0.7941 |
| 0 | 0.6038 + 0.0689i |
| m_cb(:, :, 6) = | |
| 1.0000 | 0 |
| 0 | 0.3289 − 0.0000i |
| 0 | 0.6614 + 0.6740i |
| m_cb(:, :, 7) = | |
| 1.0000 | 0 |
| 0 | 0.5112 |
| 0 | 0.4754 − 0.7160i |
| m_cb(:, :, 8) = | |
| 1.0000 | 0 |
| 0 | 0.3289 + 0.0000i |
| 0 | −0.8779 − 0.3481i |
| m_cb(:, :, 9) = | |
| 0.5000 | −0.7201 + 0.3126i |
| −0.7201 − 0.3126i | −0.2326 − 0.0000i |
| 0.2483 − 0.2684i | 0.1898 − 0.5419i |
| m_cb(:, :, 10) = | |
| 0.5000 | −7646 + 0.1377i |
| −0.7201 − 0.3126i | −0.3932 − 0.2798i |
| 0.2483 − 0.2684i | −0.2742 − 0.2971i |
| m_cb(:, :, 11) = | |
| 0.5000 | −0.7199 + 0.4140i |
| −0.7201 − 0.3126i | −0.5016 + 0.1460i |
| 0.2483 − 0.2684i | 0.1929 + 0.0130i |
| m_cb(:, :, 12) = | |
| 0.5000 | −0.5036 + 0.0368i |
| −0.7201 − 0.3126i | 0.0459 − 0.2619i |
| 0.2483 − 0.2684i | −0.0674 − 0.8184i |
| m_cb(:, :, 13) = | |
| 0.5000 | −0.4404 + 0.4275i |
| −0.7201 − 0.3126i | −0.1074 + 0.3403i |
| 0.2483 − 0.2684i | 0.5930 − 0.3799i |
| m_cb(:, :, 14) = | |
| 0.5000 | −0.2535 + 0.4478i |
| −0.7201 − 0.3126i | −0.3162 + 0.4863i |
| 0.2483 − 0.2684i | 0.5470 + 0.3155i |
| m_cb(:, :, 15) = | |
| 0.5000 | −0.0579 + 0.1096i |
| −0.7201 − 0.3126i | 0.3593 + 0.1217i |
| 0.2483 − 0.2684i | 0.4453 − 0.8015i |
| m_cb(:, :, 16) = | |
| 0.5000 | −0.3614 − 0.2193i |
| −0.7201 − 0.3126i | −0.0545 − 0.5418i |
| 0.2483 − 0.2684i | −0.5807 − 0.4332i |
| m_cb(:, :, 17) = | |
| 0.5000 | −0.0659 − 0.1371i |
| −0.0659 + 0.1371i | 0.9537 − 0.0000i |
| 0.6283 − 0.5763i | 0.0752 − 0.2483i |
| m_cb(:, :, 18) = | |
| 0.5000 | 0.2073 − 0.5574i |
| −0.0859 + 0.1371i | 0.6685 − 0.1304i |
| −0.6283 − 0.5763i | 0.3229 − 0.2798i |
| m_cb(:, :, 19) = | |
| 0.5000 | −0.4373 − 0.4559i |
| −0.0659 + 0.1371i | 0.6114 + 0.0598i |
| −0.6283 − 0.5763i | 0.0336 − 0.4717i |
| m_cb(:, :, 20) = | |
| 0.5000 | 0.4400 + 0.0523i |
| −0.0659 + 0.1371i | 0.8665 − 0.1138i |
| −0.6283 − 0.5763i | 0.1948 + 0.0432i |
| m_cb(:, :, 21) = | |
| 0.5000 | −0.4714 + 0.1958i |
| −0.0659 + 0.1371i | 0.7857 + 0.1551i |
| −0.6283 − 0.5763i | −0.2143 − 0.2284i |
| m_cb(:, :, 22) = | |
| 0.5000 | −0.8257 − 0.0874i |
| −0.0659 + 0.1371i | 0.1960 + 0.2149i |
| −0.6283 − 0.5763i | −0.2754 − 0.3875i |
| m_cb(:, :, 23) = | |
| 0.5000 | 0.0802 + 0.6537i |
| −0.0659 + 0.1371i | 0.7011 + 0.0842i |
| −0.6283 − 0.5763i | −0.1773 + 0.1979i |
| m_cb(:, :, 24) = | |
| 0.5000 | 0.7304 − 0.3323i |
| −0.0659 + 0.1371i | 0.3341 − 0.2441i |
| −0.6283 − 0.5763i | 0.4230 + 0.0763i |
| m_cb(:, :, 25) = | |
| 0.5000 | −0.0063 − 0.6527i |
| −0.0063 + 0.6527i | 0.1477 + 0.0000i |
| 0.4621 − 0.3321i | 0.4394 + 0.5991i |
| m_cb(:, :, 26) = | |
| 0.5000 | −0.3335 − 0.6269i |
| −0.0063 + 0.6527i | −0.0287 + 0.4274i |
| 0.4621 − 0.3321i | 0.1446 + 0.5397i |
| m_cb(:, :, 27) = | |
| 0.5000 | −0.1794 − 0.2195i |
| −0.0063 + 0.6527i | 0.5051 + 0.2314i |
| 0.4621 − 0.3321i | 0.3692 + 0.6889i |
| m_cb(:, :, 28) = | |
| 0.5000 | 0.0333 − 0.8621i |
| −0.0063 + 0.6527i | −0.3309 − 0.0544i |
| 0.4621 − 0.3321i | 0.2441 + 0.2892i |
| m_cb(:, :, 29) = | |
| 0.5000 | 0.2511 − 0.2860i |
| −0.0063 + 0.6527i | 0.4239 − 0.3315i |
| 0.4621 − 0.3321i | 0.5617 + 0.5000i |
| m_cb(:, :, 30) = | |
| 0.5000 | 0.0797 + 0.3185i |
| −0.0063 + 0.6527i | 0.7431 − 0.1001i |
| 0.4621 − 0.3321i | 0.3775 + 0.4345i |
| m_cb(:, :, 31) = | |
| 0.5000 | 0.4543 − 0.5067i |
| −0.0063 + 0.6527i | −0.1445 − 0.5995i |
| 0.4621 − 0.3321i | 0.3921 + 0.0541i |
| m_cb(:, :, 32) = | |
| 0.5000 | −0.2922 − 0.6671i |
| −0.0063 + 0.6527i | −0.5457 + 0.3730i |
| 0.4621 − 0.3321i | −0.1647 + 0.0744i |
| m_cb(:, :, 33) = | |
| 0.5000 | 0.7171 − 0.3202i |
| 0.7171 + 0.3202i | −0.2337 − 0.0000i |
| −0.2533 + 0.2626i | 0.1951 − 0.5390i |
| m_cb(:, :, 34) = | |
| 0.5000 | 0.7641 − 0.1480i |
| 0.7171 + 0.3202i | −0.3967 − 0.2772i |
| −0.2533 + 0.2626i | −0.2706 − 0.2946i |
| m_cb(:, :, 35) = | |
| 0.5000 | 0.7138 − 0.4227i |
| 0.7171 + 0.3202i | −0.5005 + 0.1491i |
| −0.2533 + 0.2626i | 0.1972 + 0.0160i |
| m_cb(:, :, 36) = | |
| 0.5000 | 0.5058 − 0.0418i |
| 0.7171 + 0.3202i | 0.0418 − 0.2639i |
| −0.2533 + 0.2626i | −0.0635 − 0.8167i |
| m_cb(:, :, 37) = | |
| 0.5000 | 0.4347 − 0.4303i |
| 0.7171 + 0.3202i | −0.1049 + 0.3389i |
| −0.2533 + 0.2626i | 0.5980 − 0.3775i |
| m_cb(:, :, 38) = | |
| 0.5000 | 0.2453 − 0.4498i |
| 0.7171 + 0.3202i | −0.3111 + 0.4880i |
| −0.2533 + 0.2626i | 0.5495 + 0.3173i |
| m_cb(:, :, 39) = | |
| 0.5000 | 0.0581 − 0.1072i |
| 0.7171 + 0.3202i | 0.3592 + 0.1165i |
| −0.2533 + 0.2626i | 0.4486 − 0.8008i |
| m_cb(:, :, 40) = | |
| 0.5000 | 0.3868 + 0.2134i |
| 0.7171 + 0.3202i | −0.0606 − 0.5411i |
| −0.2533 + 0.2626i | −0.5799 − 0.4326i |
| m_cb(:, :, 41) = | |
| 0.4954 | 0.4819 + 0.4517i |
| 0.4819 − 0.4517i | 0.1354 + 0.0000i |
| 0.2963 − 0.4801i | −0.7127 + 0.1933i |
| m_cb(:, :, 42) = | |
| 0.4954 | 0.1235 + 0.1340i |
| 0.4819 − 0.4517i | 0.5561 − 0.0174i |
| 0.2963 − 0.4801i | −0.7801 + 0.2206i |
| m_cb(:, :, 43) = | |
| 0.4954 | 0.1092 + 0.5656i |
| 0.4819 − 0.4517i | 0.1835 − 0.4424i |
| 0.2963 − 0.4801i | −0.5447 + 0.3769i |
| m_cb(:, :, 44) = | |
| 0.4954 | 0.5488 + 0.0588i |
| 0.4819 − 0.4517i | 0.2174 + 0.4352i |
| 0.2963 − 0.4801i | −0.6760 − 0.0421i |
| m_cb(:, :, 45) = | |
| 0.4954 | 0.5286 + 0.6690i |
| 0.4819 − 0.4517i | −0.3095 − 0.1658i |
| 0.2963 − 0.4801i | −0.3431 + 0.1789i |
| m_cb(:, :, 46) = | |
| 0.4954 | 0.0309 + 0.6659i |
| 0.4819 − 0.4517i | −0.2966 − 0.6083i |
| 0.2963 − 0.4801i | 0.0098 + 0.3124i |
| m_cb(:, :, 47) = | |
| 0.4954 | 0.7310 + 0.2470i |
| 0.4819 − 0.4517i | −0.4080 + 0.4184i |
| 0.2963 − 0.4801i | −0.1888 − 0.1655i |
| m_cb(:, :, 48) = | |
| 0.4954 | 0.0655 − 0.3761i |
| 0.4819 − 0.4517i | 0.6030 + 0.4178i |
| 0.2963 − 0.4801i | −0.5585 − 0.0649i |
| m_cb(:, :, 49) = | |
| 0.5000 | 0.0686 + 0.1386i |
| 0.0686 − 0.1386i | 0.9522 − 0.0000i |
| 0.6200 + 0.5845i | 0.0770 − 0.2521i |
| m_cb(:, :, 50) = | |
| 0.5000 | −0.1989 + 0.5618i |
| 0.0686 − 0.1386i | 0.6656 − 0.1322i |
| 0.6200 + 0.5845i | 0.3234 − 0.2823i |
| m_cb(:, :, 51) = | |
| 0.5000 | 0.4439 + 0.4516i |
| 0.0686 − 0.1386i | 0.6080 + 0.0611i |
| 0.6200 + 0.5845i | 0.0351 − 0.4738i |
| m_cb(:, :, 52) = | |
| 0.5000 | −0.4398 − 0.0443i |
| 0.0686 − 0.1386i | 0.8668 − 0.1158i |
| 0.6200 + 0.5845i | 0.1958 + 0.0394i |
| m_cb(:, :, 53) = | |
| 0.5000 | 0.4691 − 0.2002i |
| 0.0686 − 0.1386i | 0.7853 + 0.1575i |
| 0.6200 + 0.5845i | −0.2119 − 0.2313i |
| m_cb(:, :, 54) = | |
| 0.5000 | 0.8286 + 0.0769i |
| 0.0686 − 0.1386i | 0.1942 + 0.2186i |
| 0.6200 + 0.5845i | −0.2738 − 0.3877i |
| m_cb(:, :, 55) = | |
| 0.5000 | −0.0887 − 0.6510i |
| 0.0686 − 0.1386i | 0.7038 + 0.0647i |
| 0.6200 + 0.5845i | −0.1756 + 0.1949i |
| m_cb(:, :, 56) = | |
| 0.5000 | −0.7252 + 0.3429i |
| 0.0686 − 0.1386i | 0.3333 − 0.2481i |
| 0.6200 + 0.5845i | 0.4223 + 0.0745i |
| m_cb(:, :, 57) = | |
| 0.5000 | −0.0054 + 0.8540i |
| −0.0054 − 0.6540i | 0.1446 + 0.0000i |
| −0.4566 + 0.3374i | 0.4363 + 0.6009i |
| m_cb(:, :, 58) = | |
| 0.5000 | 0.3218 + 0.6320i |
| −0.0054 − 0.6540i | −0.0291 + 0.4278i |
| −0.4566 + 0.3374i | 0.1403 + 0.5417i |
| m_cb(:, :, 59) = | |
| 0.5000 | 0.1736 + 0.2236i |
| −0.0054 − 0.6540i | 0.5035 + 0.2295i |
| −0.4566 + 0.3374i | 0.3669 + 0.6922i |
| m_cb(:, :, 60) = | |
| 0.5000 | −0.0471 + 0.8617i |
| −0.0054 − 0.6540i | −0.3334 − 0.0522i |
| −0.4566 + 0.3374i | 0.2407 + 0.2889i |
| m_cb(:, :, 61) = | |
| 0.5000 | −0.2568 + 0.2842i |
| −0.0054 − 0.6540i | 0.4196 − 0.3328i |
| −0.4566 + 0.3374i | 0.5611 + 0.5016i |
| m_cb(:, :, 62) = | |
| 0.5000 | −0.0764 − 0.3158i |
| −0.0054 − 0.6540i | 0.7411 − 0.1033i |
| −0.4566 + 0.3374i | 0.3788 + 0.4372i |
| m_cb(:, :, 63) = | |
| 0.5000 | −0.4614 + 0.5008i |
| −0.0054 − 0.6540i | −0.1489 − 0.5981i |
| −0.4566 + 0.3374i | 0.3920 + 0.0527i |
| m_cb(:, :, 64) = | |
| 0.5000 | 0.2816 + 0.6702i |
| −0.0054 − 0.6540i | −0.5446 + 0.3756i |
| −0.4566 + 0.3374i | −0.1685 + 0.0739i |

For three transmit antennas, three
transmission streams, and 3-bit feedback
information,

| | |
|---|---|
| m_cb(:, :, 1) = | |
| 1 0 0 | |
| 0 1 0 | |
| 0 0 1 | |
| m_cb(:, :, 2) = | |
| Columns 1 through 2 | |
| 0.5000 | −0.7201 + 0.3126i |
| −0.7201 − 0.3126i | −0.2326 |
| 0.2483 − 0.2684i | 0.1898 − 0.5419i |
| Column 3 | |
| 0.2483 + 0.2684i | |
| 0.1898 + 0.5419i | |
| 0.7325 | |
| m_cb(:, :, 3) = | |
| Columns 1 through 2 | |
| 0.5000 | −0.0659 − 0.1371i |
| −0.0659 + 0.1371i | 0.9537 |
| −0.6283 − 0.5763i | 0.0752 − 0.2483i |
| Column 3 | |
| −0.6283 + 0.5763i | |
| 0.0752 + 0.2483i | |
| −0.4537 | |
| m_cb(:, :, 4) = | |
| Columns 1 through 2 | |
| 0.5000 | −0.0063 − 0.6527i |
| −0.0063 + 0.6527i | 0.1477 |
| 0.4621 − 0.3321i | 0.4394 + 0.5991i |
| Column 3 | |
| 0.4821 + 0.3321i | |
| 0.4394 − 0.5991i | |
| 0.3522 | |
| m_cb(:, :, 5) = | |
| Columns 1 through 2 | |
| 0.5000 | 0.7171 − 0.3202i |
| 0.7171 + 0.3202i | −0.2337 |
| −0.2533 + 0.2626i | 0.1951 − 0.5390i |
| Column 3 | |
| −0.2533 − 0.2626i | |
| 0.1951 + 0.5390i | |
| 0.7337 | |
| m_cb(:, :, 6) = | |
| Columns 1 through 2 | |
| 0.4954 | 0.4819 + 0.4517i |
| 0.4819 − 0.4517i | 0.1354 |
| 0.2983 − 0.4801i | −0.7127 + 0.1933i |
| Column 3 | |
| 0.2963 + 0.4801i | |
| −0.7127 − 0.1933i | |
| 0.3692 | |
| m_cb(:, :, 7) = | |
| Columns 1 through 2 | |
| 0.5000 | 0.0686 + 0.1386i |
| 0.0686 − 0.1386i | 0.9522 |
| 0.6200 + 0.5845i | 0.0770 − 0.2521i |
| Column 3 | |
| 0.6200 − 0.5845i | |
| 0.0770 + 0.2521i | |
| −0.4522 | |
| m_cb(:, :, 8) = | |
| Columns 1 through 2 | |
| 0.5000 | −0.0054 + 0.6540i |
| −0.0054 − 0.6540i | 0.1446 |
| −0.4566 + 0.3374i | 0.4363 + 0.6009i |
| Column 3 | |
| −0.4566 − 0.3374i | |
| 0.4363 − 0.6009i | |
| 0.3554 | |

For three transmit antennas, three
transmission streams, and 6-bit feedback
information,

| | |
|---|---|
| m_cb(:, :, 1) = | |
| 1 0 0 | |
| 0 1 0 | |
| 0 0 1 | |
| m_cb(:, :, 2) = | |
| Columns 1 through 2 | |
| 1.0000 | 0 |
| 0 | 0.7940 |
| 0 | −0.5801 + 0.1818i |
| Column 3 | |
| 0 | |
| −0.5801 − 0.1818i | |
| −0.7940 | |
| m_cb(:, :, 3) = | |
| Columns 1 through 2 | |
| 1.0000 | 0 |
| 0 | 0.7940 |
| 0 | 0.0576 + 0.6051i |
| Column 3 | |
| 0 | |
| −0.0576 − 0.6051i | |
| −0.7940 | |
| m_cb(:, :, 4) = | |
| Columns 1 through 2 | |
| 1.0000 | 0 |
| 0 | 0.7941 |
| 0 | −0.2978 − 0.5298i |
| Column 3 | |
| 0 | |
| −0.2978 + 0.5298i | |
| −0.7941 | |
| m_cb(:, :, 5) = | |
| Columns 1 through 2 | |
| 1.0000 | 0 |
| 0 | 0.7941 |
| 0 | 0.6038 + 0.0689i |
| Column 3 | |
| 0 | |
| 0.6038 − 0.0689i | |
| −0.7941 | |
| m_cb(:, :, 6) = | |
| Columns 1 through 2 | |
| 1.0000 | 0 |
| 0 | 0.3289 |
| 0 | 0.6614 + 0.6740i |
| Column 3 | |
| 0 | |
| 0.6614 − 0.6740i | |
| −0.3289 | |
| m_cb(:, :, 7) = | |
| Columns 1 through 2 | |
| 1.0000 | 0 |
| 0 | 0.5112 |
| 0 | 0.4754 − 0.7160i |
| Column 3 | |
| 0 | |
| 0.4754 + 0.7160i | |
| −0.5112 | |
| m_cb(:, :, 8) = | |
| Columns 1 through 2 | |
| 1.0000 | 0 |
| 0 | 0.3289 |
| 0 | −0.8779 − 0.3481i |
| Column 3 | |
| 0 | |
| −0.8779 + 0.3481i | |
| −0.3289 | |
| m_cb(:, :, 9) = | |
| Columns 1 through 2 | |
| 0.5000 | −0.7201 + 0.3126i |
| −0.7201 − 0.3126i | −0.2326 |
| 0.2483 − 0.2684i | 0.1898 − 0.5419i |
| Column 3 | |
| 0.2483 + 0.2684i | |
| 0.1898 + 0.5419i | |
| 0.7325 | |
| m_cb(:, :, 10) = | |
| Columns 1 through 2 | |
| 0.5000 | −0.7646 + 0.1377i |
| −0.7201 − 0.3126i | −0.3932 − 0.2798i |
| 0.2483 − 0.2684i | −0.2742 − 0.2971i |
| Column 3 | |
| 0.2773 − 0.2636i | |
| −0.0158 − 0.3880i | |
| −0.7903 + 0.2798i | |
| m_cb(:, :, 11) = | |
| Columns 1 through 2 | |
| 0.5000 | −0.7199 + 0.4140i |
| −0.7201 − 0.3126i | −0.5016 + 0.1460i |
| 0.2483 − 0.2684i | 0.1929 + 0.0130i |
| Column 3 | |
| −0.0494 + 0.2406i | |
| −0.1641 − 0.2895i | |
| −0.8967 − 0.1460i | |
| m_cb(:, :, 12) = | |
| Columns 1 through 2 | |
| 0.5000 | −0.5036 + 0.0368i |
| −0.7201 − 0.3126i | 0.0459 − 0.2619i |
| 0.2483 − 0.2684i | −0.0674 − 0.8184i |
| Column 3 | |
| −0.1484 − 0.6878i | |
| −0.0815 − 0.5535i | |
| −0.3512 + 0.2619i | |
| m_cb(:, :, 13) = | |
| Columns 1 through 2 | |
| 0.5000 | −0.4404 + 0.4275i |
| −0.7201 − 0.3126i | −0.1074 + 0.3403i |
| 0.2483 − 0.2684i | 0.5930 − 0.3799i |
| Column 3 | |
| −0.6105 + 0.0252i | |
| −0.2911 + 0.4143i | |
| −0.5045 − 0.3403i | |
| m_cb(:, :, 14) = | |
| Columns 1 through 2 | |
| 0.5000 | −0.2535 + 0.4478i |
| −0.7201 − 0.3126i | −0.3162 + 0.4863i |
| 0.2483 − 0.2684i | 0.5470 + 0.3155i |
| Column 3 | |
| −0.3472 + 0.6039i | |
| −0.2162 − 0.0215i | |
| −0.4806 − 0.4863i | |
| m_cb(:, :, 15) = | |
| Columns 1 through 2 | |
| 0.5000 | −0.0579 + 0.1096i |
| −0.7201 − 0.3126i | 0.3593 + 0.1217i |
| 0.2483 − 0.2684i | 0.4453 − 0.8015i |
| Column 3 | |
| −0.6931 − 0.5042i | |
| −0.2076 − 0.4435i | |
| 0.1037 − 0.1217i | |
| m_cb(:, :, 16) = | |
| Columns 1 through 2 | |
| 0.5000 | −0.3614 − 0.2193i |
| −0.7201 − 0.3126i | −0.0545 − 0.5418i |
| 0.2463 − 0.2684i | −0.5807 − 0.4332i |
| Column 3 | |
| 0.4417 − 0.6134i | |
| 0.1417 − 0.2592i | |
| −0.2189 + 0.5418i | |
| m_cb(:, :, 17) = | |
| Columns 1 through 2 | |
| 0.5000 | −0.0659 − 0.1371i |
| −0.0659 + 0.1371i | 0.9537 |
| −0.6283 − 0.5763i | 0.0752 − 0.2483i |
| Column 3 | |
| −0.6283 + 0.5763i | |
| 0.0752 + 0.2483i | |
| −0.4537 | |
| m_cb(:, :, 18) = | |
| Columns 1 through 2 | |
| 0.5000 | 0.2073 − 0.5574i |
| −0.0659 + 0.1371i | 0.6685 − 0.1304i |
| −0.6283 − 0.5763i | 0.3229 − 0.2796i |
| Column 3 | |
| 0.5122 − 0.3661i | |
| −0.6129 − 0.3705i | |
| 0.2715 + 0.1304i | |
| m_cb(:, :, 19) = | |
| Columns 1 through 2 | |
| 0.5000 | −0.4373 − 0.4559i |
| −0.0659 + 0.1371i | 0.6114 + 0.0598i |
| −0.6283 − 0.5763i | 0.0338 − 0.4717i |
| Column 3 | |
| 0.4121 − 0.4256i | |
| −0.0048 − 0.7743i | |
| 0.2143 − 0.0598i | |
| m_cb(:, :, 20) = | |
| Columns 1 through 2 | |
| 0.5000 | 0.4400 + 0.0523i |
| −0.0659 + 0.1371i | 0.8665 − 0.1138i |
| −0.6283 − 0.5763i | 0.1948 + 0.0432i |
| Column 3 | |
| 0.5912 − 0.4518i | |
| −0.3437 + 0.8081i | |
| 0.4695 + 0.1138i | |
| m_cb(:, :, 21) = | |
| Columns 1 through 2 | |
| 0.5000 | −0.4714 + 0.1958i |
| −0.0659 + 0.1371i | 0.7857 + 0.1551i |
| −0.6283 − 0.5763i | −0.2143 − 0.2284i |
| Column 3 | |
| 0.4497 − 0.5359i | |
| 0.5162 − 0.2629i | |
| 0.3886 − 0.1551i | |
| m_cb(:, :, 22) = | |
| Columns 1 through 2 | |
| 0.5000 | −0.8257 − 0.0874i |
| −0.0659 + 0.1371i | 0.1960 + 0.2149i |
| −0.6283 − 0.5763i | −0.2754 − 0.3875i |
| Column 3 | |
| 0.0706 − 0.2358i | |
| 0.6061 − 0.7245i | |
| 0.0316 − 0.2149i | |
| m_cb(:, :, 23) = | |
| Columns 1 through 2 | |
| 0.5000 | 0.0802 + 0.6537i |
| −0.0659 + 0.1371i | 0.7011 + 0.0642i |
| −0.6283 − 0.5763i | −0.1773 + 0.1979i |
| Column 3 | |
| 0.3880 − 0.4070i | |
| 0.4150 + 0.5559i | |
| 0.4455 − 0.0642i | |
| m_cb(:, :, 24) = | |
| Columns 1 through 2 | |
| 0.5000 | 0.7304 − 0.3323i |
| −0.0659 + 0.1371i | 0.3341 − 0.2441i |
| −0.6283 − 0.5763i | 0.4230 + 0.0763i |
| Column 3 | |
| 0.3123 − 0.0921i | |
| −0.8620 + 0.2503i | |
| 0.1697 + 0.2441i | |
| m_cb(:, :, 25) = | |
| Columns 1 through 2 | |
| 0.5000 | −0.0063 − 0.6527i |
| −0.0063 + 0.6527i | 0.1477 |
| 0.4621 − 0.3321i | 0.4394 + 0.5991i |
| Column 3 | |
| 0.4621 + 0.3321i | |
| 0.4394 − 0.5991i | |
| 0.3522 | |
| m_cb(:, :, 26) = | |
| Columns 1 through 2 | |
| 0.5000 | −0.3335 − 0.6269i |
| −0.0063 + 0.8527i | −0.0287 + 0.4274i |
| 0.4621 − 0.3321i | 0.1446 + 0.5397i |
| Column 3 | |
| −0.4819 + 0.1161i | |
| −0.4346 + 0.4489i | |
| −0.4257 − 0.4274i | |
| m_cb(:, :, 27) = | |
| Columns 1 through 2 | |
| 0.5000 | −0.1794 − 0.2195i |
| −0.0063 + 0.6527i | 0.5051 + 0.2314i |
| 0.4621 − 0.3321i | 0.3692 + 0.6889i |
| Column 3 | |
| −0.7623 − 0.2975i | |
| −0.3404 + 0.3863i | |
| 0.1081 − 0.2314i | |
| m_cb(:, :, 28) = | |
| Columns 1 through 2 | |
| 0.5000 | 0.0333 − 0.8621i |
| −0.0063 + 0.6527i | −0.3309 − 0.0544i |
| 0.4621 − 0.3321i | 0.2441 + 0.2892i |
| Column 3 | |
| −0.0193 − 0.0727i | |
| −0.3930 + 0.5541i | |
| −0.7280 + 0.0544i | |
| m_cb(:, :, 29) = | |
| Columns 1 through 2 | |
| 0.5000 | 0.2511 − 0.2860i |
| −0.0063 + 0.6527i | 0.4239 − 0.3315i |
| 0.4621 − 0.3321i | 0.5617 + 0.5000i |
| Column 3 | |
| −0.4158 − 0.6575i | |
| −0.2598 + 0.4656i | |
| 0.0269 + 0.3315i | |
| m_cb(:, :, 30) = | |
| Columns 1 through 2 | |
| 0.5000 | 0.0797 + 0.3165i |
| −0.0063 + 0.6527i | 0.7431 − 0.1001i |
| 0.4621 − 0.3321i | 0.3775 + 0.4345i |
| Column 3 | |
| −0.5962 − 0.5367i | |
| −0.0468 + 0.0975i | |
| 0.5786 + 0.1001i | |
| m_cb(:, :, 31) = | |
| Columns 1 through 2 | |
| 0.5000 | 0.4543 − 0.5067i |
| −0.0063 + 0.6527i | −0.1445 − 0.5995i |
| 0.4621 − 0.3321i | 0.3921 + 0.0541i |
| Column 3 | |
| 0.2281 − 0.4848i | |
| −0.1544 + 0.4121i | |
| −0.4001 + 0.5995i | |
| m_cb(:, :, 32) = | |
| Columns 1 through 2 | |
| 0.5000 | −0.2922 − 0.6671i |
| −0.0063 + 0.6527i | −0.5457 + 0.3730i |
| 0.4621 − 0.3321i | −0.1647 + 0.0744i |
| Column 3 | |
| 0.0808 + 0.4616i | |
| −0.2742 + 0.2485i | |
| −0.7102 − 0.3730i | |
| m_cb(:, :, 33) = | |
| Columns 1 through 2 | |
| 0.5000 | 0.7171 − 0.3202i |
| 0.7171 + 0.3202i | −0.2337 |
| −0.2533 + 0.2626i | 0.1951 − 0.5390i |
| Column 3 | |
| −0.2533 − 0.2628i | |
| 0.1951 + 0.5390i | |
| 0.7337 | |
| m_cb(:, :, 34) = | |
| Columns 1 through 2 | |
| 0.5000 | 0.7641 − 0.1480i |
| 0.7171 + 0.3202i | −0.3967 − 0.2772i |
| −0.2533 + 0.2626i | −0.2706 − 0.2946i |
| Column 3 | |
| −0.2731 + 0.2639i | |
| −0.0194 − 0.3855i | |
| −0.7937 + 0.2772i | |
| m_cb(:, :, 35) = | |
| Columns 1 through 2 | |
| 0.5000 | 0.7138 − 0.4227i |
| 0.7171 + 0.3202i | −0.5005 + 0.1491i |
| −0.2533 + 0.2626i | 0.1972 + 0.0160i |
| Column 3 | |
| 0.0486 − 0.2439i | |
| −0.1684 − 0.2865i | |
| −0.8975 − 0.1491i | |
| m_cb(:, :, 36) = | |
| Columns 1 through 2 | |
| 0.5000 | 0.5058 − 0.0419i |
| 0.7171 + 0.3202i | 0.0418 − 0.2639i |
| −0.2533 + 0.2626i | −0.0635 − 0.8167i |
| Column 3 | |
| 0.1573 + 0.6839i | |
| −0.0854 − 0.5518i | |
| −0.3552 + 0.2639i | |
| m_cb(:, :, 37) = | |
| Columns 1 through 2 | |
| 0.5000 | 0.4347 − 0.4303i |
| 0.7171 + 0.3202i | −0.1049 + 0.3389i |
| −0.2533 + 0.2626i | 0.5980 − 0.3775i |
| Column 3 | |
| 0.6121 − 0.0342i | |
| −0.2961 − 0.4119i | |
| −0.5020 − 0.3389i | |
| m_cb(:, :, 38) = | |
| Columns 1 through 2 | |
| 0.5000 | 0.2453 − 0.4498i |
| 0.7171 + 0.3202i | −0.3111 + 0.4880i |
| −0.2533 + 0.2626i | 0.5495 + 0.3173i |
| Column 3 | |
| 0.3418 − 0.6088i | |
| −0.2188 − 0.0197i | |
| −0.4755 − 0.4880i | |
| m_cb(:, :, 39) = | |
| Columns 1 through 2 | |
| 0.5000 | 0.0581 − 0.1072i |
| 0.7171 + 0.3202i | 0.3592 + 0.1165i |
| −0.2533 + 0.2626i | 0.4486 − 0.8008i |
| Column 3 | |
| 0.6997 + 0.4955i | |
| −0.2109 − 0.4428i | |
| 0.1036 − 0.1165i | |
| m_cb(:, :, 40) = | |
| Columns 1 through 2 | |
| 0.5000 | 0.3668 + 0.2134i |
| 0.7171 + 0.3202i | −0.0606 − 0.5411i |
| −0.2533 + 0.2626i | −0.5799 − 0.4326i |
| Column 3 | |
| −0.4348 + 0.6171i | |
| 0.1410 − 0.2586i | |
| −0.2250 + 0.5411i | |
| m_cb(:, :, 41) = | |
| Columns 1 through 2 | |
| 0.4954 | 0.4819 + 0.4517i |
| 0.4819 − 0.4517i | 0.1354 |
| 0.2963 − 0.4801i | −0.7127 + 0.1933i |
| Column 3 | |
| 0.2963 + 0.4801i | |
| −0.7127 − 0.1933i | |
| 0.3692 | |
| m_cb(:, :, 42) = | |
| Columns 1 through 2 | |
| 0.4954 | 0.1235 + 0.1340i |
| 0.4819 − 0.4517i | 0.5561 − 0.0174i |
| 0.2963 − 0.4801i | −0.7801 + 0.2206i |
| Column 3 | |
| −0.4327 − 0.7309i | |
| 0.4874 + 0.1289i | |
| 0.1554 + 0.0174i | |
| m_cb(:, :, 43) = | |
| Columns 1 through 2 | |
| 0.4854 | 0.1092 + 0.5656i |
| 0.4819 − 0.4517i | 0.1835 − 0.4424i |
| 0.2963 − 0.4801i | −0.5447 + 0.3769i |
| Column 3 | |
| 0.0658 − 0.6469i | |
| 0.5737 + 0.0715i | |
| −0.2172 + 0.4424i | |
| m_cb(:, :, 44) = | |
| Columns 1 through 2 | |
| 0.4954 | 0.5488 + 0.0588i |
| 0.4819 − 0.4517i | 0.2174 + 0.4352i |
| 0.2963 − 0.4801i | −0.6760 − 0.0421i |
| Column 3 | |
| −0.6181 − 0.2605i | |
| 0.5257 + 0.2253i | |
| −0.1834 − 0.4352i | |
| m_cb(:, :, 45) = | |
| Columns 1 through 2 | |
| 0.4954 | 0.5286 + 0.6690i |
| 0.4819 − 0.4517i | −0.3095 − 0.1658i |
| 0.2963 − 0.4801i | −0.3431 + 0.1789i |
| Column 3 | |
| 0.0868 − 0.1418i | |
| 0.6478 + 0.1442i | |
| −0.7102 + 0.1658i | |
| m_cb(:, :, 46) = | |
| Columns 1 through 2 | |
| 0.4954 | 0.0309 + 0.6659i |
| 0.4819 − 0.4517i | −0.2966 − 0.6083i |
| 0.2963 − 0.4801i | 0.0098 + 0.3124i |
| Column 3 | |
| 0.5258 − 0.1840i | |
| 0.3240 − 0.0277i | |
| −0.4626 + 0.6083i | |
| m_cb(:, :, 47) = | |
| Columns 1 through 2 | |
| 0.4954 | 0.7310 + 0.2470i |
| 0.4819 − 0.4517i | −0.4080 + 0.4184i |
| 0.2963 − 0.4801i | −0.1888 − 0.1655i |
| Column 3 | |
| −0.2458 + 0.3143i | |
| 0.4288 + 0.1958i | |
| −0.6660 − 0.4184i | |
| m_cb(:, :, 48) = | |
| Columns 1 through 2 | |
| 0.4954 | 0.0655 − 0.3761i |
| 0.4819 − 0.4517i | 0.6030 + 0.4178i |
| 0.2963 − 0.4801i | −0.5585 − 0.0649i |
| Column 3 | |
| −0.6777 − 0.3867i | |
| 0.1155 + 0.1107i | |
| 0.4370 − 0.4178i | |
| m_cb(:, :, 49) = | |
| Columns 1 through 2 | |
| 0.5000 | 0.0686 + 0.1386i |
| 0.0686 − 0.1386i | 0.9522 |
| 0.6200 + 0.5845i | 0.0770 − 0.2521i |
| Column 3 | |
| 0.6200 − 0.5845i | |
| 0.0770 + 0.2521i | |
| −0.4522 | |
| m_cb(:, :, 50) = | |
| Columns 1 through 2 | |
| 0.5000 | −0.1989 + 0.5618i |
| 0.0686 − 0.1386i | 0.6656 − 0.1322i |
| 0.6200 + 0.5845i | 0.3234 − 0.2823i |
| Column 3 | |
| −0.5069 + 0.3713i | |
| −0.6134 − 0.3732i | |
| 0.2686 + 0.1322i | |
| m_cb(:, :, 51) = | |
| Columns 1 through 2 | |
| 0.5000 | 0.4439 + 0.4516i |
| 0.0686 − 0.1386i | 0.6080 + 0.0611i |
| 0.6200 + 0.5845i | 0.0351 − 0.4738i |
| Column 3 | |
| −0.4045 + 0.4306i | |
| −0.0063 − 0.7763i | |
| 0.2109 − 0.0611i | |
| m_cb(:, :, 52) = | |
| Columns 1 through 2 | |
| 0.5000 | −0.4398 − 0.0443i |
| 0.0686 − 0.1386i | 0.8668 − 0.1158i |
| 0.6200 + 0.5845i | 0.1958 + 0.0394i |
| Column 3 | |
| −0.5862 + 0.4593i | |
| −0.3447 + 0.3043i | |
| 0.4697 + 0.1158i | |
| m_cb(:, :, 53) = | |
| Columns 1 through 2 | |
| 0.5000 | 0.4691 − 0.2002i |
| 0.0686 − 0.1386i | 0.7853 + 0.1575i |
| 0.6200 + 0.5845i | −0.2119 − 0.2313i |
| Column 3 | |
| −0.4414 + 0.5432i | |
| 0.5138 − 0.2658i | |
| 0.3882 − 0.1575i | |
| m_cb(:, :, 54) = | |
| Columns 1 through 2 | |
| 0.5000 | 0.8266 + 0.0769i |
| 0.0686 − 0.1386i | 0.1942 + 0.2186i |
| 0.6200 + 0.5845i | −0.2738 − 0.3877i |
| Column 3 | |
| −0.0651 + 0.2377i | |
| 0.6045 − 0.7247i | |
| 0.0297 − 0.2186i | |
| m_cb(:, :, 55) = | |
| Columns 1 through 2 | |
| 0.5000 | − 0.0887 − 0.6510i |
| 0.0686 − 0.1386i | 0.7038 + 0.0647i |
| 0.6200 + 0.5845i | −0.1756 + 0.1949i |
| Column 3 | |
| −0.3836 + 0.4138i | |
| 0.4133 + 0.5529i | |
| 0.4482 − 0.0647i | |
| m_cb(:, :, 58) = | |
| Columns 1 through 2 | |
| 0.5000 | −0.7252 + 0.3429i |
| 0.0686 − 0.1386i | 0.3333 − 0.2481i |
| 0.6200 + 0.5845i | 0.4223 + 0.0745i |
| Column 3 | |
| −0.3124 + 0.0944i | |
| −0.8612 + 0.2485i | |
| 0.1689 + 0.2481i | |
| m_cb(:, :, 57) = | |
| Columns 1 through 2 | |
| 0.5000 | −0.0054 + 0.6540i |
| −0.0054 − 0.6540i | 0.1446 |
| −0.4566 + 0.3374i | 0.4363 + 0.6009i |
| Column 3 | |
| −0.4566 − 0.3374i | |
| 0.4363 − 0.6009i | |
| 0.3554 | |
| m_cb(:, :, 58) = | |
| Columns 1 through 2 | |
| 0.5000 | 0.3218 + 0.6320i |
| −0.0054 − 0.6540i | −0.0291 + 0.4278i |
| −0.4566 + 0.3374i | 0.1403 + 0.5417i |
| Column 3 | |
| 0.4846 − 0.1105i | |
| −0.4303 + 0.4508i | |
| −0.4261 − 0.4278i | |
| m_cb(:, :, 59) = | |
| Columns 1 through 2 | |
| 0.5000 | 0.1736 + 0.2236i |
| −0.0054 − 0.6540i | 0.5035 + 0.2295i |
| −0.4566 + 0.3374i | 0.3669 + 0.6922i |
| Column 3 | |
| 0.7580 + 0.3088i | |
| −0.3381 + 0.3896i | |
| 0.1065 − 0.2295i | |
| m_cb(:, :, 60) = | |
| Columns 1 through 2 | |
| 0.5000 | −0.0471 + 0.8617i |
| −0.0054 − 0.6540i | −0.3334 − 0.0522i |
| −0.4566 + 0.3374i | 0.2407 + 0.2889i |
| Column 3 | |
| 0.0177 + 0.0703i | |
| −0.3895 + 0.5537i | |
| −0.7305 + 0.0522i | |
| m_cb(:, :, 61) = | |
| Columns 1 through 2 | |
| 0.5000 | −0.2568 + 0.2842i |
| −0.0054 − 0.6540i | 0.4196 − 0.3328i |
| −0.4566 + 0.3374i | 0.5611 + 0.5016i |
| Column 3 | |
| 0.4043 + 0.6632i | |
| −0.2592 + 0.4672i | |
| 0.0226 + 0.3328i | |
| m_cb(:, :, 62) = | |
| Columns 1 through 2 | |
| 0.5000 | −0.0764 − 0.3158i |
| −0.0054 − 0.6540i | 0.7411 − 0.1033i |
| −0.4566 + 0.3374i | 0.3786 + 0.4372i |
| Column 3 | |
| 0.5874 + 0.5472i | |
| −0.0479 + 0.1002i | |
| 0.5767 + 0.1033i | |
| m_cb(:, :, 63) = | |
| Columns 1 through 2 | |
| 0.5000 | −0.4614 + 0.5008i |
| −0.0054 − 0.6540i | −0.1489 − 0.5981i |
| −0.4566 + 0.3374i | 0.3920 + 0.0527i |
| Column 3 | |
| −0.2374 + 0.4795i | |
| −0.1543 + 0.4107i | |
| −0.4045 + 0.5981i | |
| m_cb(:, :, 64) = | |
| Columns 1 through 2 | |
| 0.5000 | 0.2816 + 0.6702i |
| −0.0054 − 0.6540i | −0.5446 + 0.3756i |
| −0.4566 + 0.3374i | −0.1685 + 0.0739i |
| Column 3 | |
| −0.0727 − 0.4650i | |
| −0.2704 + 0.2479i | |
| −0.7091 − 0.3756i | |

For four transmit antennas, one transmission
stream, and 3-bit feedback information,

```
m_cb(:, :, 1) =
  1.0000
  0.0000 − 0.0000i
  −0.0000 + 0.0000i
  0.0000 + 0.0000i
m_cb(:, :, 2) =
  0.3780
  −0.2698 − 0.5668i
  0.5957 + 0.1578i
  0.1587 − 0.2411i
m_cb(:, :, 3) =
  0.3780
  −0.7103 + 0.1326i
  −0.2350 − 0.1467i
  0.1371 + 0.4893i
m_cb(:, :, 4) =
  0.3780
  0.2830 − 0.0940i
  0.0702 − 0.8261i
  −0.2801 + 0.0491i
m_cb(:, :, 5) =
  0.3780
  −0.0841 + 0.6478i
  0.0184 + 0.0490i
  −0.3272 − 0.5662i
m_cb(:, :, 6) =
  0.3780
  0.5247 + 0.3532i
  0.4115 + 0.1825i
  0.2639 + 0.4299i
m_cb(:, :, 7) =
  0.3780
  0.2058 − 0.1369i
  −0.5211 + 0.0833i
  0.6136 − 0.3755i
m_cb(:, :, 8) =
  0.3780
  0.0618 − 0.3332i
  −0.3456 + 0.5029i
  −0.5704 + 0.2113i
```

For four transmit antennas, one transmission
stream, and 6-bit feedback information,

```
m_cb(:, :, 1) =
  0.5000
  −0.0000 + 0.5000i
  −0.5000 − 0.0000i
  0.0000 − 0.5000i
m_cb(:, :, 2) =
  0.4529 − 0.0000i
  −0.0061 − 0.3221i
  0.5831 + 0.3664i
  0.4656 + 0.0082i
m_cb(:, :, 3) =
  0.4175 + 0.0000i
  −0.8206 − 0.0812i
  −0.0467 − 0.1325i
  −0.3040 + 0.1832i
m_cb(:, :, 4) =
  0.5034
  −0.1137 + 0.3084i
  0.0057 + 0.0632i
  −0.3257 − 0.7269i
m_cb(:, :, 5) =
  0.5260 − 0.0000i
  0.4579 + 0.1394i
  −0.1299 + 0.4665i
  0.1388 + 0.4904i
m_cb(:, :, 6) =
  0.1673 − 0.0000i
  −0.8917 − 0.2667i
  0.1500 + 0.2390i
  0.1110 + 0.1176i
m_cb(:, :, 7) =
  0.2104 − 0.0000i
  −0.1631 − 0.1634i
  0.2091 + 0.3930i
  −0.1900 − 0.8174i
m_cb(:, :, 8) =
  0.7564
  0.2752 + 0.4443i
  0.1752 + 0.1139i
  −0.0804 + 0.3234i
m_cb(:, :, 9) =
  0.3210
  0.2486 − 0.6005i
  −0.4694 − 0.0852i
  −0.2080 + 0.4513i
m_cb(:, :, 10) =
  0.3436
  0.4402 + 0.0658i
  −0.5670 − 0.0322i
  0.5583 − 0.2228i
m_cb(:, :, 11) =
  0.6039 + 0.0000i
  0.0822 + 0.3279i
  0.7147 + 0.0599i
  −0.0624 + 0.0513i
m_cb(:, :, 12) =
  0.6378 + 0.0000i
  −0.1355 − 0.2827i
  −0.2835 − 0.3188i
  −0.1532 + 0.5380i
m_cb(:, :, 13) =
  0.6384 + 0.0000i
  0.3739 + 0.1332i
  −0.3179 − 0.3015i
  0.1651 − 0.4645i
m_cb(:, :, 14) =
  0.1962 + 0.0000i
  0.0906 + 0.0725i
  0.5721 + 0.7826i
  0.0910 + 0.0031i
m_cb(:, :, 15) =
  0.6758 − 0.0000i
  −0.5192 − 0.0784i
  0.1092 − 0.3313i
  0.1450 + 0.3534i
m_cb(:, :, 16) =
  0.6264 + 0.0000i
  0.1144 − 0.1440i
  0.0745 − 0.3217i
  −0.2057 − 0.6499i
m_cb(:, :, 17) =
  0.4732 − 0.0000i
  −0.0351 + 0.4319i
  −0.6207 + 0.4209i
  −0.1480 + 0.0626i
m_cb(:, :, 18) =
  0.4043 + 0.0000i
  −0.5936 − 0.1741i
  0.4291 − 0.0666i
  0.5012 + 0.1184i
m_cb(:, :, 19) =
  0.3300 − 0.0000i
  −0.1038 − 0.5703i
  0.3323 − 0.0915i
  −0.2763 − 0.5999i
m_cb(:, :, 20) =
  0.6803 + 0.0000i
  −0.2432 + 0.5431i
  −0.1270 + 0.2543i
  −0.2626 − 0.1825i
m_cb(:, :, 21) =
  0.2751 + 0.0000i
  0.1655 − 0.3560i
  −0.0849 + 0.3618i
  0.2054 + 0.7680i
m_cb(:, :, 22) =
  0.2018 + 0.0000i
  0.8742 − 0.1496i
  −0.1556 + 0.1843i
  0.2607 − 0.2157i
m_cb(:, :, 23) =
  0.4851 + 0.0000i
  −0.4030 + 0.2771i
  0.3315 + 0.4502i
  −0.1668 − 0.4303i
m_cb(:, :, 24) =
  0.5810 + 0.0000i
  0.1119 + 0.1280i
  −0.0461 − 0.0235i
  −0.0396 + 0.7933i
m_cb(:, :, 25) =
  0.4698 + 0.0000i
  0.8120 + 0.0534i
  −0.0709 − 0.2272i
  −0.1534 − 0.1923i
m_cb(:, :, 26) =
  0.3376 − 0.0000i
  −0.0556 − 0.2153i
  −0.5304 + 0.6183i
  0.3649 − 0.1993i
m_cb(:, :, 27) =
  0.6258 − 0.0000i
  −0.1124 + 0.3086i
  0.4072 − 0.2116i
  0.1763 + 0.5087i
m_cb(:, :, 28) =
  0.5255 + 0.0000i
  0.3939 − 0.2804i
  0.1818 − 0.4618i
  −0.4844 − 0.0951i
m_cb(:, :, 29) =
  0.7339 + 0.0000i
  0.0575 + 0.0818i
  −0.6296 + 0.0292i
  0.2104 − 0.0990i
m_cb(:, :, 30) =
  0.3226
  −0.1524 + 0.1980i
  0.7728 − 0.1448i
  0.4423 + 0.1430i
m_cb(:, :, 31) =
  0.3597
  −0.2781 − 0.4906i
  0.2755 − 0.5384i
  −0.3833 + 0.1998i
m_cb(:, :, 32) =
  0.8936 + 0.0000i
  −0.1516 + 0.1154i
  −0.1195 − 0.0935i
  0.0609 − 0.3721i
m_cb(:, :, 33) =
  0.1758 + 0.0000i
  −0.0345 + 0.1074i
  −0.5181 + 0.5298i
  −0.3811 + 0.5118i
m_cb(:, :, 34) =
  0.1191
  −0.8248 + 0.1153i
  −0.0024 − 0.4536i
  0.2507 + 0.1533i
m_cb(:, :, 35) =
  0.6621 + 0.0000i
  −0.2525 − 0.2046i
  0.3214 + 0.1313i
  0.1375 − 0.5626i
m_cb(:, :, 36) =
  0.5015 + 0.0000i
  −0.2862 + 0.4416i
  −0.2458 + 0.2365i
  −0.4113 + 0.4314i
m_cb(:, :, 37) =
  0.1614
  0.5947 + 0.4582i
  −0.1229 − 0.0033i
  −0.5490 − 0.3063i
m_cb(:, :, 38) =
  0.4525 + 0.0000i
  0.3385 − 0.4039i
  −0.0662 + 0.4865i
  0.4930 − 0.1826i
m_cb(:, :, 39) =
  0.4800
  −0.4788 + 0.5464i
  0.3125 + 0.2377i
  −0.2037 + 0.2147i
m_cb(:, :, 40) =
  0.2819 + 0.0000i
  0.3244 − 0.0826i
  0.1090 − 0.2542i
  −0.7259 + 0.4528i
m_cb(:, :, 41) =
  0.7411 + 0.0000i
  0.5742 + 0.0764i
  −0.2356 + 0.0500i
  0.2346 + 0.0474i
m_cb(:, :, 42) =
  0.1668 − 0.0000i
  −0.5822 + 0.0360i
  0.2189 + 0.7604i
  0.0602 + 0.0463i
m_cb(:, :, 43) =
  0.3285 − 0.0000i
  −0.1895 + 0.0198i
  0.1261 − 0.5181i
  0.0010 + 0.7559i
m_cb(:, :, 44) =
  0.8612 + 0.0000i
  0.3610 + 0.0871i
  0.2273 − 0.2023i
  −0.0091 − 0.1665i
m_cb(:, :, 45) =
  0.4721
  −0.1615 − 0.2107i
  −0.7948 + 0.1069i
  −0.1053 + 0.2288i
m_cb(:, :, 46) =
  0.3065 + 0.0000i
  −0.2240 + 0.3579i
  −0.0063 − 0.6069i
  0.5974 + 0.0506i
m_cb(:, :, 47) =
  0.5949 + 0.0000i
  0.1557 − 0.2349i
  0.6701 − 0.1265i
  −0.0562 − 0.3138i
m_cb(:, :, 48) =
  0.7806
  −0.4452 + 0.0626i
  −0.4040 − 0.0514i
  −0.1043 + 0.1088i
m_cb(:, :, 49) =
  0.2387 − 0.0000i
  0.0441 + 0.2702i
  −0.1984 − 0.4442i
  0.0127 − 0.7945i
m_cb(:, :, 50) =
  0.2362 + 0.0000i
  0.5885 − 0.2614i
  0.3821 + 0.5878i
  0.1612 − 0.1097i
m_cb(:, :, 51) =
  0.7098
  −0.6700 + 0.0265i
  0.1179 + 0.0871i
  0.0780 − 0.1381i
m_cb(:, :, 52) =
  0.2052 + 0.0000i
  −0.1721 + 0.0352i
  −0.1656 − 0.1102i
  −0.9338 − 0.1244i
m_cb(:, :, 53) =
  0.4765 + 0.0000i
  0.6113 + 0.5146i
  −0.1360 + 0.3050i
  −0.1514 − 0.0058i
m_cb(:, :, 54) =
  0.4381
  −0.3936 − 0.4501i
  0.0606 + 0.5087i
  0.4314 − 0.0443i
m_cb(:, :, 55) =
  0.1984 − 0.0000i
  −0.3459 + 0.4714i
  0.1674 − 0.1088i
  −0.2863 + 0.7049i
m_cb(:, :, 56) =
  0.5604 + 0.0000i
  0.4187 + 0.4255i
  0.3390 + 0.0502i
  −0.4327 − 0.1581i
m_cb(:, :, 57) =
  0.6569 − 0.0000i
  0.1886 − 0.2454i
  −0.4445 + 0.1772i
  0.2727 + 0.4115i
m_cb(:, :, 58) =
  0.1785
  0.4085 + 0.5675i
  0.1164 − 0.5210i
  0.4406 − 0.0086i
m_cb(:, :, 59) =
  0.2846 + 0.0000i
  0.2028 + 0.0401i
  0.7669 − 0.0056i
  −0.5189 − 0.1373i
m_cb(:, :, 60) =
  0.9340 + 0.0000i
  0.0187 + 0.0451i
  −0.0862 − 0.1445i
  0.1596 + 0.2674i
m_cb(:, :, 61) =
  0.3030 + 0.0000i
  0.3968 − 0.2460i
  −0.3832 − 0.5395i
  −0.3259 − 0.3822i
m_cb(:, :, 62) =
  0.1683
  −0.0101 + 0.3605i
  −0.8263 + 0.0847i
  0.3460 − 0.1786i
m_cb(:, :, 63) =
  0.8254 − 0.0000i
  −0.1917 − 0.0197i
  0.4523 − 0.1278i
  0.2452 − 0.0239i
m_cb(:, :, 64) =
  0.4508
  −0.3114 − 0.3205i
  −0.3590 − 0.3506i
  −0.5871 + 0.0230i
```

For four transmit antennas, two transmission
streams, and 3-bit feedback information,

| | |
|---|---|
| m_cb(:, :, 1) = | |
| 1.0000 − 0.0000i | 0.0000 + 0.0000i |
| 0.0000 + 0.0000i | 1.0000 + 0.0000i |
| 0.0000 + 0.0000i | −0.0000 − 0.0000i |
| 0.0000 − 0.0000i | 0.0000 + 0.0000i |
| m_cb(:, :, 2) = | |
| −0.2654 + 0.2992i | −0.5775 − 0.1061i |
| −0.1726 − 0.1816i | −0.4013 − 0.3587i |
| −0.3061 − 0.0744i | 0.4080 + 0.4140i |
| −0.4903 + 0.6616i | 0.1638 − 0.0302i |
| m_cb(:, :, 3) = | |
| 0.0757 − 0.3932i | −0.4334 − 0.3347i |
| −0.4725 − 0.3610i | 0.1349 + 0.1587i |
| −0.0623 − 0.0840i | −0.0411 − 0.7644i |
| 0.4387 + 0.5317i | −0.2402 + 0.1144i |
| m_cb(:, :, 4) = | |
| −0.4279 + 0.1357i | −0.2098 + 0.1569i |
| −0.6872 + 0.0817i | −02829 + 0.1676i |
| −0.4579 − 0.1706i | 0.4212 + 0.3038i |
| 0.2782 + 0.0583i | −0.3991 + 0.6279i |
| m_cb(:, :, 5) = | |
| 0.1918 − 0.0472i | −0.3651 − 0.0228i |
| −0.3047 + 0.1116i | 0.0237 + 0.7606i |
| −0.7347 − 0.2076i | 0.1887 + 0.0124i |
| 0.1028 + 0.5121i | −0.3741 + 0.3338i |
| m_cb(:, :, 6) = | |
| 0.5901 + 01973i | −0.0758 − 0.0492i |
| −0.2801 − 0.2880i | 0.3914 + 0.3838i |
| 0.1873 − 0.1430i | −0.1034 − 0.7246i |
| 0.1643 − 0.6074i | 0.3233 − 0.2259i |
| m_cb(:, :, 7) = | |
| −0.3820 + 0.5649i | −0.2255 − 0.0721i |
| −0.4605 − 0.2626i | 0.1865 + 0.1422i |
| −0.1984 − 0.0946i | −0.8401 + 0.4105i |
| −0.1590 − 0.4246i | 0.0852 + 0.0860i |
| m_cb(:, :, 8) = | |
| 0.6863 + 0.1884i | −0.3818 − 0.1527i |
| −0.2705 − 0.2542i | 0.1367 − 0.1581i |
| −0.1384 − 0.2577i | 0.4864 − 0.0528i |
| 0.1499 + 0.4976i | 0.5162 + 0.5304i |

For four transmit antennas, two transmission
streams, and 6-bit feedback information,

| | |
|---|---|
| m_cb(:, :, 1) = | |
| 1.0000 | 0 |
| 0 | 1.0000 |
| 0 | −0.0000 − 0.0000i |
| 0 | 0.0000 − 0.0000i |
| m_cb(:, :, 2) = | |
| 1.0000 | 0 |
| 0 | 0.5000 + 0.0000i |
| 0 | −0.7201 − 0.3126i |
| 0 | 0.2483 − 0.2684i |
| m_cb(:, :, 3) = | |
| 1.0000 | 0 |
| 0 | 0.5000 − 0.0000i |
| 0 | −0.0659 + 0.1371i |
| 0 | −0.6283 − 0.5763i |
| m_cb(:, :, 4) = | |
| 1.0000 | 0 |
| 0 | 0.5000 − 0.0000i |
| 0 | −0.0063 + 0.6527i |
| 0 | 0.4621 − 0.3321i |
| m_cb(:, :, 5) = | |
| 1.0000 | 0 |
| 0 | 0.5000 |
| 0 | 0.7171 + 0.3202i |
| 0 | −0.2533 + 0.2626i |
| m_cb(:, :, 6) = | |
| 1.0000 | 0 |
| 0 | 0.4954 − 0.0000i |
| 0 | 0.4819 − 0.4517i |
| 0 | 0.2963 − 0.4801i |
| m_cb(:, :, 7) = | |
| 1.0000 | 0 |
| 0 | 0.5000 |
| 0 | 0.0686 − 0.1386i |
| 0 | 0.6200 + 0.5845i |
| m_cb(:, :, 8) = | |
| 1.0000 | 0 |
| 0 | 0.5000 − 0.0000i |
| 0 | −0.0054 − 0.6540i |
| 0 | −0.4566 + 0.3374i |
| m_cb(:, :, 9) = | |
| 0.3780 | −0.2698 + 0.5668i |
| −0.2698 − 0.5668i | 0.3865 − 0.0000i |
| 0.5957 + 0.1578i | 0.4022 − 0.4743i |
| 0.1587 − 0.2411i | −0.1509 − 0.2492i |
| m_cb(:, :, 10) = | |
| 0.3780 | −0.5091 + 0.2281i |
| −0.2698 − 0.5668i | 0.0714 − 0.3649i |
| 0.5957 + 0.1578i | −0.1747 − 0.4019i |
| 0.1587 − 0.2411i | 0.2898 − 0.5240i |
| m_cb(:, :, 11) = | |
| 0.3780 | −0.1133 + 0.1325i |
| −0.2698 − 0.5668i | 0.3301 − 0.0457i |
| 0.5957 + 0.1578i | 0.0762 + 0.0389i |
| 0.1587 − 0.2411i | −0.6507 − 0.6540i |
| m_cb(:, :, 12) = | |
| 0.3780 | 0.1178 + 0.7320i |
| −0.2698 − 0.5668i | −0.1159 + 0.4248i |
| 0.5957 + 0.1578i | 0.0666 − 0.0781i |
| 0.1587 − 0.2411i | 0.1483 − 0.4732i |
| m_cb(:, :, 13) = | |
| 0.3780 | 0.2393 + 0.3416i |
| −0.2698 − 0.5668i | 0.2926 + 0.3662i |
| 0.5957 + 0.1578i | 0.5746 − 0.0676i |
| 0.1587 − 0.2411i | −0.4468 + 0.2683i |
| m_cb(:, :, 14) = | |
| 0.3780 | 0.2449 − 0.0691i |
| −0.2698 − 0.5668i | 0.6646 + 0.1932i |
| 0.5957 + 0.1578i | 0.2298 − 0.4476i |
| 0.1587 − 0.2411i | 0.2606 − 0.3676i |
| m_cb(:, :, 15) = | |
| 0.3780 | −0.1585 + 0.4323i |
| −0.2698 − 0.5668i | 0.0374 + 0.0431i |
| 0.5957 + 0.1578i | 0.3300 − 0.5124i |
| 0.1587 − 0.2411i | 0.4929 + 0.4128i |
| m_cb(:, :, 16) = | |
| 0.3780 | −0.3952 − 0.1619i |
| −0.2698 − 0.5668i | 0.4761 − 0.4303i |
| 0.5957 + 0.1578i | 0.3319 − 0.3987i |
| 0.1587 − 0.2411i | −0.2930 + 0.2255i |
| m_cb(:, :, 17) = | |
| 0.3780 | −0.7103 − 0.1326i. |
| −0.7103 + 0.1326i | 0.1606 − 0.0000i |
| −0.2350 − 0.1467i | −0.2371 − 0.2176i |
| 0.1371 + 0.4893i | 0.0522 + 0.5880i |
| m_cb(:, :, 18) = | |
| 0.3780 | −0.2374 − 0.2568i |
| −0.7103 + 0.1326i | 0.1742 − 0.2426i |
| −0.2350 − 0.1467i | −0.7492 − 0.4656i |
| 0.1371 + 0.4893i | 0.0987 − 0.0251i |
| m_cb(:, :, 19) = | |
| 0.3780 | −0.7279 + 0.1203i |
| −0.7103 + 0.1326i | −0.3056 + 0.2925i |
| −0.2350 − 0.1467i | −0.3693 + 0.0109i |
| 0.1371 + 0.4893i | −0.3733 − 0.0302i |
| m_cb(:, :, 20) = | |
| 0.3780 | −0.5486 − 0.4923i |
| −0.7103 + 0.1326i | −0.2314 − 0.4452i |
| −0.2350 − 0.1467i | −0.0975 + 0.3374i |
| 0.1371 + 0.4893i | 0.1957 + 0.2079i |
| m_cb(:, :, 21) = | |
| 0.3780 | −0.4769 + 0.1236i |
| −0.7103 + 0.1326i | −0.0182 + 0.2428i |
| −0.2350 − 0.1467i | 0.5078 + 0.2545i |
| 0.1371 + 0.4893i | −0.0510 + 0.8106i |
| m_cb(:, :, 22) = | |
| 0.3780 | −0.5932 − 0.0997i |
| −0.7103 + 0.1326i | −0.2033 + 0.0126i |
| −0.2350 − 0.1467i | 0.2813 − 0.6292i |
| 0.1371 + 0.4893i | 0.3486 + 0.0085i |
| m_cb(:, :, 23) = | |
| 0.3760 | 0.0201 − 0.2469i |
| −0.7103 + 0.1326i | 0.4703 − 0.2863i |
| −0.2350 − 0.1467i | 0.1344 − 0.2272i |
| 0.1371 + 0.4893i | 0.4213 + 0.6232i |
| m_cb(:, :, 24) = | |
| 0.3780 | −0.1555 + 0.3563i |
| −0.7103 + 0.1326i | 0.3984 + 0.4400i |
| −0.2350 − 0.1467i | −0.1482 − 0.5560i |
| 0.1371 + 0.4893i | −0.1421 + 0.3812i |
| m_cb(:, :, 25) = | |
| 0.3780 | 0.2830 + 0.0940i |
| 0.2830 − 0.0940i | 0.8570 + 0.0000i |
| 0.0702 − 0.8261i | −0.1568 + 0.3653i |
| −0.2801 + 0.0491i | 0.1349 + 0.0200i |
| m_cb(:, :, 26) = | |
| 0.3780 | 0.2665 − 0.5068i |
| 0.2830 − 0.0940i | 0.4553 + 0.2709i |
| 0.0702 − 0.8261i | −0.0771 + 0.0985i |
| −0.2801 + 0.0491i | 0.3283 − 0.5177i |
| m_cb(:, :, 27) = | |
| 0.3780 | 0.1713 + 0.1944i |
| 0.2830 − 0.0940i | 0.3927 − 0.0626i |
| 0.0702 − 0.8261i | −0.3435 + 0.3427i |
| −0.2801 + 0.0491i | −0.5358 − 0.5023i |
| m_cb(:, :, 28) = | |
| 0.3780 | −0.5439 + 0.1579i |
| 0.2830 − 0.0940i | 0.7236 − 0.1540i |
| 0.0702 − 0.8261i | −0.1547 − 0.0874i |
| −0.2801 + 0.0491i | 0.2297 − 0.2181i |
| m_cb(:, :, 29) = | |
| 0.3780 | 0.0112 + 0.6008i |
| 0.2830 − 0.0940i | 0.4041 − 0.2717i |
| 0.0702 − 0.8261i | −0.0819 + 0.2673i |
| −0.2801 + 0.0491i | −0.2008 + 0.5323i |
| m_cb(:, :, 30) = | |
| 0.3780 | 0.4406 + 0.5329i |
| 0.2830 − 0.0940i | 0.2144 − 0.1759i |
| 0.0702 − 0.8261i | −0.2755 + 0.0733i |
| −0.2801 + 0.0491i | 0.5368 − 0.2750i |
| m_cb(:, :, 31) = | |
| 0.3780 | 0.1159 − 0.1003i |
| 0.2830 − 0.0940i | 0.4624 + 0.0631i |
| 0.0702 − 0.8261i | 0.1887 + 0.0266i |
| −0.2801 + 0.0491i | 0.6643 + 0.5302i |
| m_cb(:, :, 32) = | |
| 0.3780 | 0.8258 − 0.0754i |
| 0.2830 − 0.0940i | 0.1357 + 0.1591i |
| 0.0702 − 0.8261i | 0.0016 + 0.4513i |
| −0.2801 + 0.0491i | −0.0906 + 0.2382i |
| m_cb(:, :, 33) = | |
| 0.3780 | −0.0841 − 0.6478i |
| −0.0841 + 0.6478i | 0.3140 + 0.0000i |
| 0.0184 + 0.0490i | −0.0485 + 0.0258i |
| −0.3272 − 0.5662i | 0.5454 − 0.4174i |
| m_cb(:, :, 34) = | |
| 0.3780 | 0.0001 − 0.0660i |
| −0.0841 + 0.6478i | 0.4313 − 0.0090i |
| 0.0184 + 0.0490i | −0.7253 − 0.3107i |
| −0.3272 − 0.5662i | 0.3084 − 0.3031i |
| m_cb(:, :, 35) = | |
| 0.3780 | 0.4953 − 0.4853i |
| −0.0841 + 0.6478i | 0.0616 − 0.5815i |
| 0.0184 + 0.0490i | −0.1188 + 0.1125i |
| −0.3272 − 0.5662i | 0.0740 − 0.3807i |
| m_cb(:, :, 36) = | |
| 0.3780 | 0.0266 + 0.0588i |
| −0.0841 + 0.6478i | 0.5648 − 0.0197i |
| 0.0184 + 0.0490i | −0.0025 + 0.6489i |
| −0.3272 − 0.5662i | 0.4226 − 0.2770i |
| m_cb(:, :, 37) = | |
| 0.3780 | −0.0790 − 0.5825i |
| −0.0841 + 0.6478i | −0.1173 + 0.0035i |
| 0.0184 + 0.0490i | 0.6736 + 0.3437i |
| −0.3272 − 0.5662i | 0.2353 − 0.1157i |
| m_cb(:, :, 38) = | |
| 0.3780 | 0.1200 − 0.0279i |
| −0.0841 + 0.6478i | 0.4825 − 0.1287i |
| 0.0184 + 0.0490i | 0.4762 − 0.4603i |
| −0.3272 − 0.5662i | 0.3849 − 0.3856i |
| m_cb(:, :, 39) = | |
| 0.3780 | −0.5814 − 0.1700i |
| −0.0841 + 0.6476i | 0.2443 + 0.5825i |
| 0.0184 + 0.0490i | 0.0724 − 0.0878i |
| −0.3272 − 0.5662i | 0.4689 − 0.0342i |
| m_cb(:, :, 40) = | |
| 0.3780 | −0.1158 − 0.7046i |
| −0.0841 + 0.6478i | −0.2495 + 0.0253i |
| 0.0184 + 0.0490i | −0.0575 − 0.6240i |
| −0.3272 − 0.5662i | 0.1239 − 0.1387i |
| m_cb(:, :, 41) = | |
| 0.3780 | 0.5247 − 0.3532i |
| 0.5247 + 0.3532i | 0.3569 + 0.0000i |
| 0.4115 + 0.1825i | −0.4508 + 0.0797i |
| 0.2639 + 0.4299i | −0.4667 − 0.2128i |
| m_cb(:, :, 42) = | |
| 0.3780 | −0.1409 − 0.3514i |
| 0.5247 + 0.3532i | 0.4194 + 0.3764i |
| 0.4115 + 0.1825i | −0.7300 − 0.0388i |
| 0.2639 + 0.4299i | 0.0653 − 0.0220i |
| m_cb(:, :, 43) = | |
| 0.3780 | −0.1533 + 0.0099i |
| 0.5247 + 0.3532i | 0.6349 + 0.0787i |
| 0.4115 + 0.1825i | 0.0384 + 0.1755i |
| 0.2639 + 0.4299i | −0.5564 − 0.4746i |
| m_cb(:, :, 44) = | |
| 0.3780 | 0.3581 − 0.1931i |
| 0.5247 + 0.3532i | 0.0883 − 0.0404i |
| 0.4115 + 0.1825i | −0.2999 + 0.6754i |
| 0.2639 + 0.4299i | 0.1768 − 0.4977i |
| m_cb(:, :, 45) = | |
| 0.3780 | 0.6620 + 0.0025i |
| 0.5247 + 0.3532i | −0.0570 − 0.3779i |
| 0.4115 + 0.1825i | 0.2799 + 0.1243i |
| 0.2639 + 0.4299i | −0.5324 − 0.1959i |
| m_cb(:, :, 46) = | |
| 0.3780 | 0.2476 − 0.7029i |
| 0.5247 + 0.3532i | −0.1125 + 0.4523i |
| 0.4115 + 0.1825i | 0.1119 − 0.0594i |
| 0.2639 + 0.4299i | −0.2945 − 0.3531i |
| m_cb(:, :, 47) = | |
| 0.3780 | 0.6802 − 0.3584i |
| 0.5247 + 0.3532i | −0.2773 − 0.0838i |
| 0.4115 + 0.1825i | −0.4866 − 0.1011i |
| 0.2639 + 0.4299i | 0.0838 + 0.2665i |
| m_cb(:, :, 48) = | |
| 0.3780 | 0.1653 − 0.1594i |
| 0.5247 + 0.3532i | 0.2701 + 0.0406i |
| 0.4115 + 0.1825i | −0.1616 − 0.5970i |
| 0.2639 + 0.4299i | −0.6369 + 0.2907i |
| m_cb(:, :, 49) = | |
| 0.3780 | 0.2058 + 0.1369i |
| 0.2058 − 0.1369i | 0.9018 + 0.0000i |
| −0.5211 + 0.0833i | 0.1908 + 0.0871i |
| 0.6136 − 0.3755i | −0.2857 − 0.0108i |
| m_cb(:, :, 50) = | |
| 0.3780 | 0.7053 + 0.2199i |
| 0.2058 − 0.1369i | 0.2162 + 0.0824i |
| −0.5211 + 0.0833i | −0.0997 − 0.2229i |
| 0.6136 − 0.3755i | −0.5802 − 0.0596i |
| m_cb(:, :, 51) = | |
| 0.3780 | −0.0204 − 0.5870i |
| 0.2058 − 0.1369i | 0.6359 + 0.1898i |
| −0.5211 + 0.0833i | −0.1617 − 0.3520i |
| 0.6136 − 0.3755i | −0.2538 − 0.0095i |
| m_cb(:, :, 52) = | |
| 0.3780 | 0.5689 − 0.3015i |
| 0.2058 − 0.1369i | 0.3781 + 0.2249i |
| −0.5211 + 0.0833i | 0.4299 + 0.3240i |
| 0.6136 − 0.3755i | 0.0829 + 0.3087i |
| m_cb(:, :, 53) = | |
| 0.3780 | −0.4982 − 0.0922i |
| 0.2058 − 0.1369i | 0.6851 − 0.0791i |
| −0.5211 + 0.0833i | 0.2874 + 0.3098i |
| 0.6136 − 0.3755i | 0.2937 + 0.0528i |
| m_cb(:, :, 54) = | |
| 0.3780 | 0.1753 + 0.0797i |
| 0.2058 − 0.1369i | 0.4198 + 0.0122i |
| −0.5211 + 0.0833i | 0.6394 − 0.4084i |
| 0.6136 − 0.3755i | 0.0753 − 0.4529i |
| m_cb(:, :, 55) = | |
| 0.3780 | 0.2166 + 0.7264i |
| 0.2058 − 0.1369i | 0.2685 − 0.1927i |
| −0.5211 + 0.0833i | 0.3474 + 0.4410i |
| 0.6136 − 0.3755i | −0.0321 − 0.0013i |
| m_cb(:, :, 56) = | |
| 0.3780 | −0.3556 + 0.4453i |
| 0.2058 − 0.1369i | 0.5197 − 0.2256i |
| −0.5211 + 0.0833i | −0.2437 − 0.2333i |
| 0.6136 − 0.3755i | −0.3746 − 0.3165i |
| m_cb(:, :, 57) = | |
| 0.3780 | 0.0618 + 0.3332i |
| 0.0618 − 0.3332i | 0.8154 − 0.0000i |
| −0.3456 + 0.5029i | 0.3037 + 0.1352i |
| −0.5704 + 0.2113i | 0.1698 + 0.2845i |
| m_cb(:, :, 58) = | |
| 0.3780 | −0.0758 + 0.7374i |
| 0.0618 − 0.3332i | 0.1126 − 0.1139i |
| −0.3456 + 0.5029i | −0.1661 + 0.1583i |
| −0.5704 + 0.2113i | 0.4293 + 0.4335i |
| m_cb(:, :, 59) = | |
| 0.3780 | 0.3592 + 0.6139i |
| 0.0618 − 0.3332i | 0.1355 + 0.1314i |
| −0.3456 + 0.5029i | 0.6299 + 0.1878i |
| −0.5704 + 0.2113i | −0.0903 − 0.1354i |
| m_cb(:, :, 60) = | |
| 0.3780 | 0.0275 + 0.0360i |
| 0.0618 − 0.3332i | 0.4780 + 0.0112i |
| −0.3456 + 0.5029i | 0.0381 + 0.6505i |
| −0.5704 + 0.2113i | 0.4996 − 0.3085i |
| m_cb(:, :, 61) = | |
| 0.3780 | 0.1441 − 0.4010i |
| 0.0618 − 0.3332i | 0.7005 + 0.1170i |
| −0.3456 + 0.5029i | 0.4730 − 0.0190i |
| −0.5704 + 0.2113i | −0.2574 − 0.1540i |
| m_cb(:, :, 62) = | |
| 0.3780 | −0.6336 + 0.2901i |
| 0.0618 − 0.3332i | 0.4029 − 0.3682i |
| −0.3456 + 0.5029i | 0.3644 + 0.2216i |
| −0.5704 + 0.2113i | −0.1861 + 0.0011i |
| m_cb(:, :, 63) = | |
| 0.3780 | −0.2926 − 0.2844i |
| 0.0618 − 0.3332i | 0.6814 − 0.1285i |
| −0.3456 + 0.5029i | −0.3239 − 0.0600i |
| −0.5704 + 0.2113i | 0.2550 + 0.4231i |
| m_cb(:, :, 64) = | |
| 0.3780 | 0.0356 + 0.2994i |
| 0.0618 − 0.3332i | 0.3361 − 0.0106i |
| −0.3456 + 0.5029i | 0.2564 − 0.5164i |
| −0.5704 + 0.2113i | −0.3222 + 0.5998i |

For four transmit antennas, three
transmission streams, and 3-bit feedback
information,

| | |
|---|---|
| m_cb(:, :, 1) = | |
| 0 0 0 | |
| 1 0 0 | |
| 0 1 0 | |
| 0 0 1 | |
| m_cb(:, :, 2) = | |
| Columns 1 through 2 | |
| −0.2698 + 0.5668i | 0.5957 − 0.1578i |
| 0.3665 | 0.4022 + 0.4743i |
| 0.4022 − 0.4743i | 0.3894 |
| −0.1509 − 0.2492i | −0.0908 + 0.2712i |
| Column 3 | |
| 0.1587 + 0.2411i | |
| −0.1509 + 0.2492i | |
| −0.0908 − 0.2712i | |
| 0.8660 | |
| m_cb(:, :, 3) = | |
| Columns 1 through 2 | |
| −0.7103 − 0.1326i | −0.2350 + 0.1467i |
| 0.1606 | −0.2371 + 0.2176i |
| −0.2371 − 0.2176i | 0.8766 |
| 0.0522 + 0.5880i | 0.1672 + 0.1525i |
| Column 3 | |
| 0.1371 − 0.4893i | |
| 0.0522 − 0.5880i | |
| 0.1672 − 0.1525i | |
| 0.5848 | |
| m_cb(:, :, 4) = | |
| Columns 1 through 2 | |
| 0.2830 + 0.0940i | 0.0702 + 0.8261i |
| 0.8570 | −0.1568 − 0.3653i |
| −0.1568 + 0.3653i | −0.1050 |
| 0.1349 + 0.0200i | 0.0968 + 0.3665i |
| Column 3 | |
| −0.2801 − 0.0491i | |
| 0.1349 − 0.0200i | |
| 0.0968 − 0.3665i | |
| 0.8700 | |
| m_cb(:, :, 5) = | |
| Columns 1 through 2 | |
| −0.0841 − 0.6478i | 0.0184 − 0.0490i |
| 0.3140 | −0.0485 − 0.0258i |
| −0.0485 + 0.0258i | 0.9956 |
| 0.5454 − 0.4174i | 0.0543 − 0.0090i |
| Column 3 | |
| −0.3272 + 0.5662i | |
| 0.5454 + 0.4174i | |
| 0.0543 + 0.0090i | |
| 0.3125 | |
| m_cb(:, :, 6) = | |
| Columns 1 through 2 | |
| 0.5247 − 0.3532i | 0.4115 − 0.1825i |
| 0.3569 | −0.4508 − 0.0797i |
| −0.4508 + 0.0797i | 0.6742 |
| −0.4667 − 0.2128i | −0.3007 − 0.2070i |
| Column 3 | |
| 0.2639 − 0.4299i | |
| −0.4667 + 0.2128i | |
| −0.3007 + 0.2070i | |
| 0.5910 | |
| m_cb(:, :, 7) = | |
| Columns 1 through 2 | |
| 0.2058 + 0.1369i | −0.5211 − 0.0833i |
| 0.9018 | 0.1908 − 0.0871i |
| 0.1908 + 0.0871i | 0.5522 |
| −02857 − 0.0108i | 0.5644 − 0.2324i |
| Column 3 | |
| 0.6136 + 0.3755i | |
| −0.2857 + 0.0108i | |
| 0.5644 + 0.2324i | |
| 0.1680 | |
| m_cb(:, :, 8) = | |
| Columns 1 through 2 | |
| 0.0618 + 0.3332i | −0.3456 − 0.5029i |
| 0.8154 | 0.3037 − 0.1352i |
| 0.3037 + 0.1352i | 0.4015 |
| 0.1698 + 0.2845i | −0.4877 − 0.3437i |
| Column 3 | |
| −0.5704 − 0.2113i | |
| 0.1698 − 0.2845i | |
| −0.4877 + 0.3437i | |
| 0.4052 | |

For four transmit antennas, three
transmission streams, and 6-bit feedback
information,

| | |
|---|---|
| m_cb(:, :, 1) = | |
| Columns 1 through 2 | |
| −0.0000 − 0.5000i | −0.5000 + 0.0000i |
| 0.5000 | 0.0000 + 0.5000i |
| 0.0000 − 0.5000i | 0.5000 |
| 0.5000 + 0.0000i | 0 − 0.5000i |
| Column 3 | |
| 0.0000 + 0.5000i | |
| 0.5000 − 0.0000i | |
| 0 + 0.5000i | |
| 0.5000 | |
| m_cb(:, :, 2) = | |
| Columns 1 through 2 | |
| −0.0061 + 0.3221i | 0.5831 − 0.3664i |
| 0.8103 | 0.2222 + 0.3391i |
| 0.2222 − 0.3391i | 0.1332 |
| 0.0100 − 0.2740i | −0.5017 + 0.3031i |
| Column 3 | |
| 0.4656 − 0.0082i | |
| 0.0100 + 0.2740i | |
| −0.5017 − 0.3031i | |
| 0.6036 | |
| m_cb(:, :, 3) = | |
| Columns 1 through 2 | |
| −0.8206 + 0.0812i | −0.0467 + 0.1325i |
| −0.1674 | −0.0842 + 0.1801i |
| −0.0842 − 0.1801i | 0.9661 |
| −0.4027 + 0.3005i | 0.0173 + 0.0838i |
| Column 3 | |
| −0.3040 − 0.1832i | |
| −0.4027 − 0.3005i | |
| 0.0173 − 0.0838i | |
| 0.7837 | |
| m_cb(:, :, 4) = | |
| Columns 1 through 2 | |
| −0.1137 − 0.3084i | 0.0057 − 0.0632i |
| 0.7825 | −0.0379 − 0.0180i |
| −0.0379 + 0.0180i | 0.9919 |
| 0.3768 − 0.3687i | 0.0963 − 0.0331i |
| Column 3 | |
| −0.3257 + 0.7269i | |
| 0.3768 + 0.3687i | |
| 0.0963 + 0.0331i | |
| −0.2778 | |
| m_cb(:, :, 5) = | |
| Columns 1 through 2 | |
| 0.4579 − 0.1394i | −0.1299 − 0.4665i |
| 0.5167 | −0.0116 + 0.4888i |
| −0.0116 − 0.4888i | 0.5053 |
| −0.2782 − 0.4329i | −0.4446 + 0.2710i |
| Column 3 | |
| 0.1388 − 0.4904i | |
| −0.2782 + 0.4329i | |
| −0.4446 − 0.2710i | |
| 0.4520 | |
| m_cb(:, :, 6) = | |
| Columns 1 through 2 | |
| −0.8917 + 0.2667i | 0.1500 − 0.2390i |
| −0.0403 | 0.2371 − 0.2079i |
| 0.2371 + 0.2079i | 0.9044 |
| 0.1565 + 0.0904i | −0.0537 + 0.0107i |
| Column 3 | |
| 0.1110 − 0.1176i | |
| 0.1565 − 0.0904i | |
| −0.0537 − 0.0107i | |
| 0.9686 | |
| m_cb(:, :, 7) = | |
| Columns 1 through 2 | |
| −0.1631 + 0.1634i | 0.2091 − 0.3930i |
| 0.9325 | 0.1245 − 0.0379i |
| 0.1245 + 0.0379i | 0.7490 |
| −0.2064 − 0.1295i | 0.4572 + 0.1219i |
| Column 3 | |
| −0.1900 + 0.8174i | |
| −0.2084 + 0.1295i | |
| 0.4572 − 0.1219i | |
| 0.1081 | |
| m_cb(:, :, 8) = | |
| Columns 1 through 2 | |
| 0.2752 − 0.4443i | 0.1752 − 0.1139i |
| −0.1213 | −0.4056 − 0.1908i |
| −0.4056 + 0.1908i | 0.8208 |
| −0.4991 − 0.5120i | −0.0934 − 0.2701i |
| Column 3 | |
| −0.0804 − 0.3234i | |
| −0.4991 + 0.5120i | |
| −0.0934 + 0.2701i | |
| 0.5441 | |
| m_cb(:, :, 9) = | |
| Columns 1 through 2 | |
| 0.2486 + 0.6005i | −0.4694 + 0.0852i |
| 0.3779 | 0.0965 − 0.4464i |
| 0.0965 + 0.4464i | 0.6648 |
| 0.4753 + 0.0187i | −0.0871 + 0.3381i |
| Column 3 | |
| −0.2080 − 0.4513i | |
| 0.4753 − 0.0187i | |
| −0.0871 − 0.3381i | |
| 0.6364 | |
| m_cb(:, :, 10) = | |
| Columns 1 through 2 | |
| 0.4402 − 0.0658i | −0.5670 + 0.0322i |
| 0.6982 | 0.3834 + 0.0353i |
| 0.3834 − 0.0353i | 0.5086 |
| −0.3520 + 0.2054i | 0.4713 − 0.2198i |
| Column 3 | |
| 0.5583 + 0.2228i | |
| −0.3520 − 0.2054i | |
| 0.4713 + 0.2198i | |
| 0.4496 | |
| m_cb(:, :, 11) = | |
| Columns 1 through 2 | |
| 0.0822 − 0.3279i | 0.7147 − 0.0599i |
| 0.7114 | −0.1980 − 0.5793i |
| −0.1980 + 0.5793i | −0.2989 |
| −0.0295 − 0.0623i | 0.1049 − 0.1019i |
| Column 3 | |
| −0.0624 − 0.0513i | |
| −0.0295 + 0.0623i | |
| 0.1049 + 0.1019i | |
| 0.9835 | |
| m_cb(:, :, 12) = | |
| Columns 1 through 2 | |
| −0.1355 + 0.2827i | −0.2835 + 0.3188i |
| 0.7287 | −0.3549 − 0.1020i |
| −0.3549 + 0.1020i | 0.4975 |
| 0.3626 + 0.3208i | 0.3537 + 0.5559i |
| Column 3 | |
| −0.1532 − 0.5380i | |
| 0.3626 − 0.3208i | |
| 0.3537 − 0.5559i | |
| 0.1360 | |
| m_cb(:, :, 13) = | |
| Columns 1 through 2 | |
| 0.3739 − 0.1332i | −0.3179 + 0.3015i |
| 0.5644 | 0.4397 − 0.1947i |
| 0.4397 + 0.1947i | 0.4692 |
| 0.0004 + 0.5410i | −0.2422 − 0.5459i |
| Column 3 | |
| 0.1651 + 0.4645i | |
| 0.0004 − 0.5410i | |
| −0.2422 + 0.5459i | |
| 0.3280 | |
| m_cb(:, :, 14) = | |
| Columns 1 through 2 | |
| 0.0906 − 0.0725i | 0.5721 − 0.7826i |
| 0.9832 | −0.1351 + 0.0366i |
| −0.1351 − 0.0366i | −0.1691 |
| −0.0105 + 0.0079i | −0.0678 + 0.0864i |
| Column 3 | |
| 0.0910 − 0.0031i | |
| −0.0105 − 0.0079i | |
| −0.0678 − 0.0864i | |
| 0.9897 | |
| m_cb(:, :, 15) = | |
| Columns 1 through 2 | |
| −0.5192 + 0.0784i | 0.1092 + 0.3313i |
| 0.1496 | 0.0948 + 0.5569i |
| 0.0948 − 0.5569i | 0.6247 |
| 0.3176 + 0.5310i | 0.3123 − 0.2672i |
| Column 3 | |
| 0.1450 − 0.3534i | |
| 0.3176 − 0.5310i | |
| 0.3123 + 0.2672i | |
| 0.5499 | |
| m_cb(:, :, 16) = | |
| Columns 1 through 2 | |
| 0.1144 + 0.1440i | 0.0745 + 0.3217i |
| 0.9095 | −0.1468 − 0.0698i |
| −0.1468 + 0.0698i | 0.7080 |
| −0.1875 + 0.2784i | −0.5186 + 0.3069i |
| Column 3 | |
| −0.2057 + 0.6499i | |
| −0.1875 − 0.2784i | |
| −0.5186 − 0.3069i | |
| −0.2439 | |
| m_cb(:, :, 17) = | |
| Columns 1 through 2 | |
| −0.0351 − 0.4319i | −0.6207 − 0.4209i |
| 0.6436 | −0.3864 + 0.4809i |
| −0.3864 − 0.4809i | −0.0678 |
| −0.0612 − 0.1172i | −0.2245 − 0.0445i |
| Column 3 | |
| −0.1480 − 0.0626i | |
| −0.0612 + 0.1172i | |
| −0.2245 + 0.0445i | |
| 0.9509 | |
| m_cb(:, :, 18) = | |
| Columns 1 through 2 | |
| −0.5936 + 0.1741i | 0.4291 + 0.0666i |
| 0.3575 | 0.4082 + 0.1918i |
| 0.4082 − 0.1918i | 0.6834 |
| 0.5341 − 0.0285i | −0.3478 − 0.1413i |
| Column 3 | |
| 0.5012 − 0.1184i | |
| 0.5341 + 0.0285i | |
| −0.3478 + 0.1413i | |
| 0.5548 | |
| m_cb(:, :, 19) = | |
| Columns 1 through 2 | |
| −0.1038 + 0.5703i | 0.3323 + 0.0915i |
| 0.4984 | −0.0264 + 0.2970i |
| −0.0264 − 0.2970i | 0.8227 |
| −0.5535 + 0.1423i | 0.0551 + 0.3353i |
| Column 3 | |
| −0.2763 + 0.5999i | |
| −0.5535 − 0.1423i | |
| 0.0551 − 0.3353i | |
| 0.3489 | |
| m_cb(:, :, 20) = | |
| Columns 1 through 2 | |
| −0.2432 − 0.5431i | −0.1270 − 0.2543i |
| −0.1076 | −0.5287 + 0.0222i |
| −0.5287 − 0.0222i | 0.7472 |
| 0.1102 − 0.5849i | 0.0408 − 0.2814i |
| Column 3 | |
| −0.2626 + 0.1825i | |
| 0.1102 + 0.5849i | |
| 0.0408 + 0.2814i | |
| 0.6801 | |
| m_cb(:, :, 21) = | |
| Columns 1 through 2 | |
| 0.1655 + 0.3560i | −0.0849 − 0.3618i |
| 0.7873 | 0.1971 + 0.0409i |
| 0.1971 − 0.0409i | 0.8095 |
| 0.3303 − 0.2763i | −0.3592 + 0.1925i |
| Column 3 | |
| 0.2054 − 0.7680i | |
| 0.3303 + 0.2763i | |
| −0.3592 − 0.1925i | |
| 0.1281 | |
| m_cb(:, :, 22) = | |
| Columns 1 through 2 | |
| 0.8742 + 0.1496i | −0.1556 − 0.1843i |
| 0.0145 | 0.2049 + 0.1727i |
| 0.2049 − 0.1727i | 0.9271 |
| −0.3260 + 0.1874i | 0.1006 + 0.0182i |
| Column 3 | |
| 0.2607 + 0.2157i | |
| −0.3260 − 0.1874i | |
| 0.1006 − 0.0182i | |
| 0.8565 | |
| m_cb(:, :, 23) = | |
| Columns 1 through 2 | |
| −0.4030 −0.2771i | 0.3315 − 0.4502i |
| 0.5354 | 0.0172 − 0.5307i |
| 0.0172 + 0.5307i | 0.3931 |
| 0.1009 − 0.4266i | 0.4836 + 0.1311i |
| Column 3 | |
| −0.1668 + 0.4303i | |
| 0.1009 + 0.4266i | |
| 0.4836 − 0.1311i | |
| 0.5864 | |
| m_cb(:, :, 24) = | |
| Columns 1 through 2 | |
| 0.1119 − 0.1280i | −0.0461 + 0.0235i |
| 0.9310 | 0.0195 + 0.0078i |
| 0.0195 − 0.0078i | 0.9936 |
| −0.2318 − 0.2239i | 0.0402 + 0.0895i |
| Column 3 | |
| −0.0396 − 0.7933i | |
| −0.2318 + 0.2239i | |
| 0.0402 − 0.0895i | |
| −0.5056 | |
| m_cb(:, :, 25) = | |
| Columns 1 through 2 | |
| 0.8120 − 0.0534i | −0.0709 + 0.2272i |
| −0.2488 | 0.1314 − 0.3409i |
| 0.1314 + 0.3409i | 0.8931 |
| 0.2543 + 0.2790i | −0.1029 + 0.0401i |
| Column 3 | |
| −0.1534 + 0.1923i | |
| 0.2543 − 0.2790i | |
| −0.1029 − 0.0401i | |
| 0.8859 | |
| m_cb(:, :, 26) = | |
| Columns 1 through 2 | |
| −0.0556 + 0.2153i | −0.5304 − 0.6183i |
| 0.9254 | 0.1564 − 0.2243i |
| 0.1564 + 0.2243i | −0.0020 |
| −0.0341 − 0.1353i | 0.4782 + 0.1811i |
| Column 3 | |
| 0.3649 + 0.1993i | |
| −0.0341 + 0.1353i | |
| 0.4782 − 0.1811i | |
| 0.7390 | |
| m_cb(:, :, 27) = | |
| Columns 1 through 2 | |
| −0.1124 − 0.3086i | 0.4072 + 0.2116i |
| 0.7117 | 0.2968 − 0.2723i |
| 0.2968 + 0.2723i | 0.4372 |
| −0.3667 + 0.2982i | 0.0959 − 0.6533i |
| Column 3 | |
| 0.1763 − 0.5087i | |
| −0.3667 − 0.2982i | |
| 0.0959 + 0.6533i | |
| 0.2253 | |
| m_cb(:, :, 28) = | |
| Columns 1 through 2 | |
| 0.3939 + 0.2804i | 0.1818 + 0.4618i |
| 0.5072 | −0.4238 − 0.2760i |
| −0.4238 + 0.2760i | 0.4809 |
| 0.3459 + 0.3653i | 0.0929 + 0.5079i |
| Column 3 | |
| −0.4844 + 0.0951i | |
| 0.3459 − 0.3653i | |
| 0.0929 − 0.5079i | |
| 0.4864 | |
| m_cb(:, :, 29) = | |
| Columns 1 through 2 | |
| 0.0575 − 0.0818i | −0.6296 − 0.0292i |
| 0.9624 | 0.1270 + 0.2000i |
| 0.1270 − 0.2000i | −0.4930 |
| −0.0150 + 0.0861i | 0.5088 − 0.2112i |
| Column 3 | |
| 0.2104 + 0.0990i | |
| −0.0150 − 0.0861i | |
| 0.5088 + 0.2112i | |
| 0.7967 | |
| m_cb(:, :, 30) = | |
| Columns 1 through 2 | |
| −0.1524 − 0.1960i | 0.7728 + 0.1448i |
| 0.9090 | 0.2157 − 0.1910i |
| 0.2157 + 0.1910i | 0.0874 |
| 0.0581 + 0.1602i | −0.4741 − 0.2577i |
| Column 3 | |
| 0.4423 − 0.1430i | |
| 0.0581 − 0.1602i | |
| −0.4741 + 0.2577i | |
| 0.6809 | |
| m_cb(:, :, 31) = | |
| Columns 1 through 2 | |
| −0.2781 + 0.4906i | 0.2755 + 0.5384i |
| 0.5033 | −0.2929 + 0.4449i |
| −0.2929 − 0.4449i | 0.4287 |
| −0.0133 + 0.3805i | 0.3329 + 0.2363i |
| Column 3 | |
| −0.3833 − 0.1998i | |
| −0.0133 − 0.3805i | |
| 0.3329 − 0.2363i | |
| 0.7082 | |
| m_cb(:, :, 32) = | |
| Columns 1 through 2 | |
| −0.1516 − 0.1154i | −0.1195 + 0.0935i |
| 0.6587 | −0.0688 + 0.2628i |
| −0.0688 − 0.2628i | 0.7837 |
| 0.4904 − 0.4642i | −0.2586 − 0.4713i |
| Column 3 | |
| 0.0609 + 0.3721i | |
| 0.4904 + 0.4642i | |
| −0.2586 + 0.4713i | |
| −0.3360 | |
| m_cb(:, :, 33) = | |
| Columns 1 through 2 | |
| −0.0345 − 0.1074i | −0.5181 − 0.5298i |
| 0.9846 | −0.0907 + 0.0453i |
| −0.0907 − 0.0453i | 0.3337 |
| −0.0826 − 0.0282i | −0.5686 + 0.0768i |
| Column 3 | |
| −0.3811 − 0.5118i | |
| −0.0826 + 0.0282i | |
| −0.5686 − 0.0768i | |
| 0.5059 | |
| m_cb(:, :, 34) = | |
| Columns 1 through 2 | |
| −0.8248 − 0.1153i | −0.0024 + 0.4536i |
| 0.2125 | 0.0571 + 0.4251i |
| 0.0571 − 0.4251i | 0.7664 |
| 0.2147 + 0.1764i | 0.0796 − 0.1287i |
| Column 3 | |
| 0.2507 − 0.1533i | |
| 0.2147 − 0.1764i | |
| 0.0796 + 0.1287i | |
| 0.9020 | |
| m_cb(:, :, 35) = | |
| Columns 1 through 2 | |
| −0.2525 + 0.2046i | 0.3214 − 0.1313i |
| 0.6874 | 0.3197 + 0.0965i |
| 0.3197 − 0.0965i | 0.6432 |
| −0.2378 − 0.5037i | 0.0878 + 0.5887i |
| Column 3 | |
| 0.1375 + 0.5626i | |
| −0.2378 + 0.5037i | |
| 0.0878 − 0.5887i | |
| 0.0073 | |
| m_cb(:, :, 36) = | |
| Columns 1 through 2 | |
| −0.2862 − 0.4416i | −0.2458 − 0.2365i |
| 0.4445 | −0.3506 + 0.0820i |
| −0.3506 − 0.0820i | 0.7666 |
| −0.6182 − 0.1167i | −0.4074 + 0.0175i |
| Column 3 | |
| −0.4113 − 0.4314i | |
| −0.6182 + 0.1167i | |
| −0.4074 − 0.0175i | |
| 0.2875 | |
| m_cb(:, :, 37) = | |
| Columns 1 through 2 | |
| 0.5947 − 0.4582i | −0.1229 + 0.0033i |
| 0.3279 | 0.0889 + 0.0648i |
| 0.0889 − 0.0648i | 0.9820 |
| 0.5567 − 0.0827i | −0.0816 − 0.0428i |
| Column 3 | |
| −0.5490 + 0.3063i | |
| 0.5567 + 0.0827i | |
| −0.0816 + 0.0428i | |
| 0.5287 | |
| m_cb(:, :, 38) = | |
| Columns 1 through 2 | |
| 0.3385 + 0.4039i | −0.0662 − 0.4865i |
| 0.4927 | 0.3998 + 0.2520i |
| 0.3998 − 0.2520i | 0.5597 |
| −0.4396 − 0.2508i | 0.2218 + 0.4160i |
| Column 3 | |
| 0.4930 + 0.1826i | |
| −0.4396 + 0.2508i | |
| 0.2218 − 0.4160i | |
| 0.4951 | |
| m_cb(:, :, 39) = | |
| Columns 1 through 2 | |
| −0.4788 − 0.5464i | 0.3125 − 0.2377i |
| −0.0151 | 0.0380 − 0.5473i |
| 0.0380 + 0.5473i | 0.7035 |
| −0.4132 − 0.0163i | 0.0242 − 0.2222i |
| Column 3 | |
| −0.2037 − 0.2147i | |
| −0.4132 + 0.0163i | |
| 0.0242 + 0.2222i | |
| 0.8315 | |
| m_cb(:, :, 40) = | |
| Columns 1 through 2 | |
| 0.3244 + 0.0826i | 0.1090 + 0.2542i |
| 0.8440 | −0.0784 − 0.1023i |
| −0.0784 + 0.1023i | 0.8935 |
| 0.3800 − 0.1211i | 0.2705 + 0.1883i |
| Column 3 | |
| −0.7259 − 0.4528i | |
| 0.3800 + 0.1211i | |
| 0.2705 − 0.1883i | |
| −0.0194 | |
| m_cb(:, :, 41) = | |
| Columns 1 through 2 | |
| 0.5742 − 0.0764i | −0.2356 − 0.0500i |
| −0.2959 | 0.5077 + 0.1803i |
| 0.5077 − 0.1803i | 0.7760 |
| −0.5342 − 0.0359i | 0.2043 + 0.0884i |
| Column 3 | |
| 0.2346 − 0.0474i | |
| −0.5342 + 0.0359i | |
| 0.2043 − 0.0884i | |
| 0.7788 | |
| m_cb(:, :, 42) = | |
| Columns 1 through 2 | |
| −0.5822 − 0.0360i | 0.2189 − 0.7604i |
| 0.5917 | 0.1200 − 0.5408i |
| 0.1200 + 0.5408i | 0.2485 |
| 0.0401 + 0.0349i | −0.0581 + 0.0428i |
| Column 3 | |
| 0.0602 − 0.0463i | |
| 0.0401 − 0.0349i | |
| −0.0581 − 0.0428i | |
| 0.9931 | |
| m_cb(:, :, 43) = | |
| Columns 1 through 2 | |
| −0.1895 − 0.0198i | 0.1261 + 0.5181i |
| 0.9459 | 0.0509 + 0.1425i |
| 0.0509 − 0.1425i | 0.5766 |
| −0.0220 + 0.2134i | 0.5830 − 0.1428i |
| Column 3 | |
| 0.0010 − 0.7559i | |
| −0.0220 − 0.2134i | |
| 0.5830 + 0.1428i | |
| 0.1489 | |
| m_cb(:, :, 44) = | |
| Columns 1 through 2 | |
| 0.3610 − 0.0871i | 0.2273 + 0.2023i |
| 0.0062 | −0.4642 − 0.6690i |
| −0.4642 + 0.6690i | 0.3328 |
| 0.1281 + 0.4273i | −0.2278 + 0.2858i |
| Column 3 | |
| −0.0091 + 0.1665i | |
| 0.1281 − 0.4273i | |
| −0.2278 − 0.2858i | |
| 0.7998 | |
| m_cb(:, :, 45) = | |
| Columns 1 through 2 | |
| −0.1615 + 0.2107i | −0.7948 − 0.1069i |
| 0.8665 | −0.2005 − 0.3500i |
| −0.2005 + 0.3500i | −0.2185 |
| 0.0591 + 0.1120i | −0.2048 + 0.3231i |
| Column 3 | |
| −0.1053 − 0.2288i | |
| 0.0591 − 0.1120i | |
| −0.2048 − 0.3231i | |
| 0.8799 | |
| m_cb(:, :, 46) = | |
| Columns 1 through 2 | |
| −0.2240 − 0.3579i | −0.0063 + 0.6069i |
| 0.7430 | 0.3111 + 0.1993i |
| 0.3111 − 0.1993i | 0.4688 |
| 0.1669 + 0.3246i | 0.0497 − 0.5223i |
| Column 3 | |
| 0.5974 − 0.0506i | |
| 0.1669 − 0.3246i | |
| 0.0497 + 0.5223i | |
| 0.4817 | |
| m_cb(:, :, 47) = | |
| Columns 1 through 2 | |
| 0.1557 + 0.2349i | 0.6701 + 0.1265i |
| 0.8039 | −0.3310 + 0.3400i |
| −0.3310 − 0.3400i | −0.1480 |
| −0.1604 + 0.1532i | −0.0051 + 0.5366i |
| Column 3 | |
| −0.0562 + 0.3138i | |
| −0.1604 − 0.1532i | |
| −0.0051 − 0.5366i | |
| 0.7492 | |
| m_cb(:, :, 48) = | |
| Columns 1 through 2 | |
| −0.4452 − 0.0626i | −0.4040 + 0.0514i |
| 0.0787 | −0.8051 + 0.2194i |
| −0.8051 − 0.2194i | 0.2443 |
| −0.2426 + 0.1911i | −0.1664 + 0.2248i |
| Column 3 | |
| −0.1043 − 0.1088i | |
| −0.2426 − 0.1911i | |
| −0.1664 − 0.2248i | |
| 0.8965 | |
| m_cb(:, :, 49) = | |
| Columns 1 through 2 | |
| 0.0441 − 0.2702i | −0.1984 + 0.4442i |
| 0.9015 | 0.1692 + 0.0447i |
| 0.1692 − 0.0447i | 0.6891 |
| 0.2813 + 0.0505i | −0.4602 − 0.2145i |
| Column 3 | |
| 0.0127 + 0.7945i | |
| 0.2813 − 0.0505i | |
| −0.4602 + 0.2145i | |
| 0.1707 | |
| m_cb(:, :, 50) = | |
| Columns 1 through 2 | |
| 0.5885 + 0.2614i | 0.3821 − 0.5878i |
| 0.4571 | −0.0933 + 0.5837i |
| −0.0933 − 0.5837i | 0.3565 |
| −0.1618 + 0.0293i | 0.0037 + 0.1789i |
| Column 3 | |
| 0.1612 + 0.1097i | |
| −0.1618 − 0.0293i | |
| 0.0037 − 0.1789i | |
| 0.9502 | |
| m_cb(:, :, 51) = | |
| Columns 1 through 2 | |
| −0.6700 − 0.0265i | 0.1179 − 0.0871i |
| −0.5490 | 0.2642 − 0.2119i |
| 0.2642 + 0.2119i | 0.9259 |
| 0.1926 − 0.3117i | 0.0098 + 0.0795i |
| Column 3 | |
| 0.0780 + 0.1381i | |
| 0.1926 + 0.3117i | |
| 0.0098 − 0.0795i | |
| 0.9133 | |
| m_cb(:, :, 52) = | |
| Columns 1 through 2 | |
| −0.1721 − 0.0352i | −0.1656 + 0.1102i |
| 0.9612 | −0.0310 + 0.0312i |
| −0.0310 − 0.0312i | 0.9502 |
| −0.1967 − 0.0683i | −0.2118 + 0.1035i |
| Column 3 | |
| −0.9338 + 0.1244i | |
| −0.1967 + 0.0683i | |
| −0.2118 − 0.1035i | |
| −0.1165 | |
| m_cb(:, :, 53) = | |
| Columns 1 through 2 | |
| 0.6113 − 0.5146i | −0.1360 − 0.3050i |
| −0.2196 | −0.1410 + 0.4898i |
| −0.1410 − 0.4898i | 0.7870 |
| 0.1824 − 0.1420i | −0.0359 − 0.0897i |
| Column 3 | |
| −0.1514 + 0.0058i | |
| 0.1824 + 0.1420i | |
| −0.0359 + 0.0897i | |
| 0.9562 | |
| m_cb(:, :, 54) = | |
| Columns 1 through 2 | |
| −0.3936 + 0.4501i | 0.0606 − 0.5087i |
| 0.3638 | 0.4500 − 0.3078i |
| 0.4500 + 0.3078i | 0.5328 |
| 0.2667 − 0.3766i | −0.0064 + 0.3954i |
| Column 3 | |
| 0.4314 + 0.0443i | |
| 0.2667 + 0.3766i | |
| −0.0064 − 0.3954i | |
| 0.6652 | |
| m_cb(:, :, 55) = | |
| Columns 1 through 2 | |
| −0.3459 − 0.4714i | 0.1674 + 0.1088i |
| 0.5735 | 0.1362 − 0.0515i |
| 0.1362 + 0.0515i | 0.9503 |
| −0.5381 + 0.1358i | 0.1554 − 0.1083i |
| Column 3 | |
| −0.2863 − 0.7049i | |
| −0.5381 − 0.1358i | |
| 0.1554 + 0.1083i | |
| 0.2779 | |
| m_cb(:, :, 56) = | |
| Columns 1 through 2 | |
| 0.4187 − 0.4255i | 0.3390 − 0.0502i |
| 0.1895 | −0.3715 − 0.2803i |
| −0.3715 + 0.2803i | 0.7328 |
| 0.5651 − 0.2682i | 0.3517 + 0.0725i |
| Column 3 | |
| −0.4327 + 0.1581i | |
| 0.5651 + 0.2682i | |
| 0.3517 − 0.0725i | |
| 0.5173 | |
| m_cb(:, :, 57) = | |
| Columns 1 through 2 | |
| 0.1886 + 0.2454i | −0.4445 − 0.1772i |
| 0.7208 | 0.3711 − 0.2206i |
| 0.3711 + 0.2206i | 0.3326 |
| 0.1445 − 0.4213i | 0.1407 + 0.6740i |
| Column 3 | |
| 0.2727 − 0.4115i | |
| 0.1445 + 0.4213i | |
| 0.1407 − 0.6740i | |
| 0.2897 | |
| m_cb(:, :, 58) = | |
| Columns 1 through 2 | |
| 0.4085 − 0.5675i | 0.1164 + 0.5210i |
| 0.4048 | 0.3021 − 0.3395i |
| 0.3021 + 0.3395i | 0.653i |
| −0.2132 + 0.3087i | −0.0679 − 0.2782i |
| Column 3 | |
| 0.4406 + 0.0086i | |
| −0.2132 − 0.3087i | |
| −0.0679 + 0.2782i | |
| 0.7636 | |
| m_cb(:, :, 59) = | |
| Columns 1 through 2 | |
| 0.2028 − 0.0401i | 0.7669 + 0.0056i |
| 0.9403 | −0.2171 − 0.0446i |
| −0.2171 + 0.0446i | 0.1779 |
| 0.1548 + 0.0098i | 0.5552 + 0.1512i |
| Column 3 | |
| −0.5189 + 0.1373i | |
| 0.1548 − 0.0098i | |
| 0.5552 − 0.1512i | |
| 0.5973 | |
| m_cb(:, :, 60) = | |
| Columns 1 through 2 | |
| 0.0187 − 0.0451i | −0.0862 + 0.1445i |
| 0.9639 | 0.1231 + 0.0179i |
| 0.1231 − 0.0179i | 0.5713 |
| −0.2279 + 0.0330i | 0.7936 + 0.0001i |
| Column 3 | |
| 0.1596 − 0.2674i | |
| −0.2279 − 0.0330i | |
| 0.7936 − 0.0001i | |
| −0.469i | |
| m_cb(:, :, 61) = | |
| Columns 1 through 2 | |
| 0.3968 + 0.2460i | −0.3832 + 0.5395i |
| 0.6872 | 0.0278 − 0.4424i |
| 0.0278 + 0.4424i | 0.3717 |
| 0.0507 + 0.3326i | −0.4750 + 0.0421i |
| Column 3 | |
| −0.3259 + 0.3822i | |
| 0.0507 − 0.3328i | |
| −0.4750 − 0.0421i | |
| 0.6380 | |
| m_cb(:, :, 62) = | |
| Columns 1 through 2 | |
| −0.0101 − 0.3605i | −0.8263 − 0.0847i |
| 0.8436 | −0.0468 + 0.3571i |
| −0.0468 − 0.3571i | 0.1704 |
| 0.0816 + 0.1478i | 0.3620 − 0.1422i |
| Column 3 | |
| 0.3460 + 0.1786i | |
| 0.0816 − 0.1478i | |
| 0.3620 + 0.1422i | |
| 0.8177 | |
| m_cb(:, :, 63) = | |
| Columns 1 through 2 | |
| −0.1917 + 0.0197i | 0.4523 + 0.1278i |
| 0.7874 | 0.4821 + 0.1912i |
| 0.4821 − 0.1912i | −0.2651 |
| 0.2665 − 0.0538i | −0.6527 − 0.1176i |
| Column 3 | |
| 0.2452 + 0.0239i | |
| 0.2665 + 0.0538i | |
| −0.6527 + 0.1176i | |
| 0.6524 | |
| m_cb(:, :, 64) = | |
| Columns 1 through 2 | |
| −0.3114 + 0.3205i | −0.3590 + 0.3506i |
| 0.6364 | −0.4082 − 0.0107i |
| −0.4082 + 0.0107i | 0.5414 |
| −0.3195 + 0.3557i | −0.3692 + 0.3899i |
| Column 3 | |
| −0.5871 − 0.0230i | |
| −0.3195 − 0.3557i | |
| −0.3692 − 0.3899i | |
| 0.3714 | |

For four transmit antennas, four
transmission streams, and 3-bit feedback
information,

| | |
|---|---|
| m_cb(:, :, 1) = | |
| 1 0 0 0 | |
| 0 1 0 0 | |
| 0 0 1 0 | |
| 0 0 0 1 | |
| m_cb(:, :, 2) = | |
| Columns 1 through 2 | |
| 0.3780 | −0.2698 + 0.5668i |
| −0.2698 − 0.5668i | 0.3665 |
| 0.5957 + 0.1578i | 0.4022 − 0.4743i |
| 0.1587 − 0.2411i | −0.1509 − 0.2492i |
| Columns 3 through 4 | |
| 0.5957 − 0.1578i | 0.1587 + 0.2411i |
| 0.4022 + 0.4743i | −0.1509 + 0.2492i |
| 0.3894 | −0.0908 − 0.2712i |
| −0.0908 + 0.2712i | 0.8660 |
| m_cb(:, :, 3) = | |
| Columns 1 through 2 | |
| 0.3780 | −0.7103 − 0.1326i |
| −0.7103 + 0.1326i | 0.1606 |
| −0.2350 − 0.1467i | −0.2371 − 0.2176i |
| 0.1371 + 0.4893i | 0.0522 + 0.5880i |
| Columns 3 through 4 | |
| −0.2350 + 0.1467i | 0.1371 − 0.4893i |
| −0.2371 + 0.2176i | 0.0522 − 0.5880i |
| 0.8766 | 0.1672 − 0.1525i |
| 0.1672 + 0.1525i | 0.5848 |
| m_cb(:, :, 4) = | |
| Columns 1 through 2 | |
| 0.3780 | 0.2830 + 0.0940i |
| 0.2830 − 0.0940i | 0.8570 |
| 0.0702 − 0.8261i | −0.1568 + 0.3653i |
| −0.2801 + 0.0491i | 0.1349 + 0.0200i |
| Columns 3 through 4 | |
| 0.0702 + 0.8261i | −0.2801 − 0.0491i |
| −0.1568 − 0.3653i | 0.1349 − 0.0200i |
| −0.1050 | 0.0968 − 0.3665i |
| 0.0968 + 0.3665i | 0.8700 |
| m_cb(:, :, 5) = | |
| Columns 1 through 2 | |
| 0.3780 | −0.0841 − 0.6478i |
| −0.0841 + 0.6478i | 0.3140 |
| 0.0184 + 0.0490i | −0.0485 + 0.0258i |
| −0.3272 − 0.5662i | 0.5454 − 0.4174i |
| Columns 3 through 4 | |
| 0.0184 − 0.0490i | −0.3272 + 0.5662i |
| −0.0485 − 0.0258i | 0.5454 + 0.4174i |
| 0.9956 | 0.0543 + 0.0090i |
| 0.0543 − 0.0090i | 0.3125 |
| m_cb(:, :, 6) = | |
| Columns 1 through 2 | |
| 0.3780 | 0.5247 − 0.3532i |
| 0.5247 + 0.3532i | 0.3569 |
| 0.4115 + 0.1825i | −0.4508 + 0.0797i |
| 0.2639 + 0.4299i | −0.4667 − 0.2128i |
| Columns 3 through 4 | |
| 0.4115 − 0.1825i | 0.2639 − 0.4299i |
| −0.4508 − 0.0797i | −0.4667 + 0.2128i |
| 0.6742 | −0.3007 + 0.2070i |
| −0.3007 − 0.2070i | 0.5910 |
| m_cb(:, :, 7) = | |
| Columns 1 through 2 | |
| 0.3780 | 0.2058 + 0.1369i |
| 0.2058 − 0.1369i | 0.9018 |
| −0.5211 + 0.0833i | 0.1908 + 0.0871i |
| 0.6136 − 0.3755i | −0.2857 − 0.0108i |
| Columns 3 through 4 | |
| −0.5211 − 0.0833i | 0.6136 + 0.3755i |
| 0.1908 − 0.0871i | −0.2857 + 0.0108i |
| 0.5522 | 0.5644 + 0.2324i |
| 0.5644 − 0.2324i | 0.1680 |
| m_cb(:, :, 8) = | |
| Columns 1 through 2 | |
| 0.3780 | 0.0618 + 0.3332i |
| 0.0618 − 0.3332i | 0.8154 |
| −0.3456 + 0.5029i | 0.3037 + 0.1352i |
| −0.5704 + 0.2113i | 0.1698 + 0.2845i |
| Columns 3 through 4 | |
| −0.3456 − 0.5029i | −0.5704 − 0.2113i |
| 0.3037 − 0.1352i | 0.1698 − 0.2845i |
| 0.4015 | −0.4877 + 0.3437i |
| −0.4877 − 0.3437i | 0.4052 |

For four transmit antennas, four
transmission streams, and 6-bit feedback
information,

| | |
|---|---|
| m_cb(:, :, 1) = | |
| Columns 1 through 2 | |
| 0.5000 | −0.0000 − 0.5000i |
| −0.0000 − 0.5000i | 0.5000 |
| −0.5000 − 0.0000i | 0.0000 − 0.5000i |
| 0.0000 − 0.5000i | 0.5000 + 0.000i |
| Columns 3 through 4 | |
| −0.5000 + 0.0000i | 0.0000 + 0.5000i |
| 0.0000 + 0.5000i | 0.5000 − 0.0000i |
| 0.5000 | 0 + 0.5000i |
| 0 − 0.5000i | 0.5000 |
| m_cb(:, :, 2) = | |
| Columns 1 through 2 | |
| 0.4529 | −0.0061 + 0.3221i |
| −0.0061 − 0.3221i | 0.8103 |
| 0.5831 + 0.3664i | 0.2222 − 0.3391i |
| 0.4656 + 0.0082i | 0.0100 − 0.2740i |
| Columns 3 through 4 | |
| 0.5831 − 0.3664i | 0.4656 − 0.0082i |
| 0.2222 + 0.3391i | 0.0100 + 0.2740i |
| 0.1332 | −0.5017 − 0.3031i |
| −0.5017 + 0.3031i | 0.6036 |
| m_cb(:, :, 3) = | |
| Columns 1 through 2 | |
| 0.4175 | −0.8206 + 0.0812i |
| −0.8206 − 0.0812i | −0.1674 |
| −0.0467 − 0.1325i | −0.0842 − 0.1801i |
| −0.3040 + 0.1832i | −0.4027 + 0.3005i |
| Columns 3 through 4 | |
| −0.0467 + 0.1325i | −0.3040 − 0.1832i |
| 0.0842 + 0.1801i | −0.4027 − 0.3005i |
| 0.9661 | 0.0173 − 0.0838i |
| 0.0173 + 0.0838i | 0.7837 |
| m_cb(:, :, 4) = | |
| Columns 1 through 2 | |
| 0.5034 | −0.1137 − 0.3084i |
| −0.1137 + 0.3084i | 0.7825 |
| 0.0057 + 0.0632i | −0.0379 + 0.0180i |
| −0.3257 − 0.7269i | 0.3768 − 0.3687i |
| Columns 3 through 4 | |
| 0.0057 − 0.0632i | −0.3257 + 0.7269i |
| −0.0379 − 0.0180i | 0.3768 + 0.3687i |
| 0.9919 | 0.0963 + 0.0331i |
| 0.0963 − 0.0331i | −0.2778 |
| m_cb(:, :, 5) = | |
| Columns 1 through 2 | |
| 0.5260 | 0.4579 − 0.1394i |
| 0.4579 + 0.1394i | 0.5167 |
| −0.1299 + 0.4665i | −0.0116 − 0.4888i |
| 0.1388 + 0.4904i | −0.2782 − 0.4329i |
| Columns 3 through 4 | |
| −0.1299 − 0.4665i | 0.1388 − 0.4904i |
| −0.0116 + 0.4888i | −0.2782 + 0.4329i |
| 0.5053 | −0.4446 − 0.2710i |
| −0.4446 + 0.2710i | 0.4520 |
| m_cb(:, :, 6) = | |
| Columns 1 through 2 | |
| 0.1673 | −0.8917 + 0.2667i |
| −0.8917 − 0.2667i | −0.0403 |
| 0.1500 + 0.2390i | 0.2371 + 0.2079i |
| 0.1110 + 0.1176i | 0.1565 + 0.0904i |
| Columns 3 through 4 | |
| 0.1500 − 0.2390i | 0.1110 − 0.1176i |
| 0.2371 − 0.2079i | 0.1565 − 0.0904i |
| 0.9044 | −0.0537 − 0.0107i |
| −0.0537 + 0.0107i | 0.9686 |
| m_cb(:, :, 7) = | |
| Columns 1 through 2 | |
| 0.2104 | −0.1631 + 0.1634i |
| −0.1631 − 0.1634i | 0.9325 |
| 0.2091 + 0.3930i | 0.1245 + 0.0379i |
| −0.1900 − 0.8174i | −0.2084 − 0.1295i |
| Columns 3 through 4 | |
| 0.2091 − 0.3930i | −0.1900 + 0.8174i |
| 0.1245 − 0.0379i | −0.2084 + 0.1295i |
| 0.7490 | 0.4572 − 0.1219i |
| 0.4572 + 0.1219i | 0.108i |
| m_cb(:, :, 8) = | |
| Columns 1 through 2 | |
| 0.7564 | 0.2752 − 0.4443i |
| 0.2752 + 0.4443i | −0.1213 |
| 0.1752 + 0.1139i | −0.4056 + 0.1908i |
| −0.0804 + 0.3234i | −0.4991 − 0.5120i |
| Columns 3 through 4 | |
| 0.1752 − 0.1139i | −0.0804 − 0.3234i |
| −0.4056 − 0.1908i | −0.4991 + 0.5120i |
| 0.8208 | −0.0934 + 0.2701i |
| −0.0934 − 0.2701i | 0.5441 |
| m_cb(:, :, 9) = | |
| Columns 1 through 2 | |
| 0.3210 | 0.2486 + 0.6005i |
| −0.2486 − 0.6005i | 0.3779 |
| −0.4694 − 0.0852i | 0.0965 + 0.4464i |
| −0.2080 + 0.4513i | 0.4753 + 0.0187i |
| Columns 3 through 4 | |
| −0.4694 + 0.0852i | −0.2080 − 0.4513i |
| 0.0965 − 0.4464i | 0.4753 − 0.0187i |
| 0.6648 | −0.0871 − 0.3381i |
| −0.0871 + 0.3381i | 0.6364 |
| m_cb(:, :, 10) = | |
| Columns 1 through 2 | |
| 0.3436 | 0.4402 − 0.0658i |
| 0.4402 + 0.0658i | 0.6982 |
| −0.5670 − 0.0322i | 0.3834 − 0.0353i |
| 0.5583 − 0.2228i | −0.3520 + 0.2054i |
| Columns 3 through 4 | |
| −0.5670 + 0.0322i | 0.5583 + 0.2228i |
| 0.3834 + 0.0353i | −0.3520 − 0.2054i |
| 0.5086 | 0.4713 + 0.2198i |
| 0.4713 − 0.2198i | 0.4496 |
| m_cb(:, :, 11) = | |
| Columns 1 through 2 | |
| 0.6039 | 0.0822 − 0.3279i |
| 0.0822 + 0.3279i | 0.7114 |
| 0.7147 + 0.0599i | −0.1980 + 0.5793i |
| −0.0624 + 0.0513i | −0.0295 − 0.0623i |
| Columns 3 through 4 | |
| 0.7147 − 0.0599i | −0.0624 − 0.0513i |
| −0.1980 − 0.5793i | −0.0295 + 0.0623i |
| −0.2989 | 0.1049 + 0.1019i |
| 0.1049 − 0.1019i | 0.9835 |
| m_cb(:, :, 12) = | |
| Columns 1 through 2 | |
| 0.6378 | −0.1355 + 0.2827i |
| −0.1355 − 0.2827i | 0.7287 |
| −0.2835 − 0.3188i | −0.3549 + 0.1020i |
| −0.1532 + 0.5380i | 0.3626 + 0.3208i |
| Columns 3 through 4 | |
| −0.2835 + 0.3188i | −0.1532 − 0.5380i |
| −0.3549 − 0.1020i | 0.3626 − 0.3208i |
| 0.4975 | 0.3537 − 0.5559i |
| 0.3537 + 0.5559i | 0.1360 |
| m_cb(:, :, 13) = | |
| Columns 1 through 2 | |
| 0.6384 | 0.3739 − 0.1332i |
| 0.3739 + 0.1332i | 0.5644 |
| −0.3179 − 0.3015i | 0.4397 + 0.1947i |
| 0.1651 − 0.4645i | 0.0004 + 0.5410i |
| Columns 3 through 4 | |
| −0.3179 + 0.3015i | 0.1651 + 0.4645i |
| 0.4397 − 0.1947i | 0.0004 − 0.5410i |
| 0.4692 | −0.2422 + 0.5459i |
| −0.2422 − 0.5459i | 0.3280 |
| m_cb(:, :, 14) = | |
| Columns 1 through 2 | |
| 0.1982 | 0.0906 − 0.0725i |
| 0.0906 + 0.0725i | 0.9832 |
| 0.5721 + 0.7826i | −0.1351 − 0.0366i |
| 0.0910 + 0.0031i | −0.0105 + 0.0079i |
| Columns 3 through 4 | |
| 0.5721 − 0.7826i | 0.0910 − 0.0031i |
| −0.1351 + 0.0366i | −0.0105 − 0.0079i |
| −0.1691 | −0.0678 − 0.0864i |
| −0.0678 + 0.0864i | 0.9897 |
| m_cb(:, :, 15) = | |
| Columns 1 through 2 | |
| 0.6758 | −0.5192 + 0.0784i |
| −0.5192 − 0.0784i | 0.1496 |
| 0.1092 − 0.3313i | 0.0948 − 0.5569i |
| 0.1450 + 0.3534i | 0.3176 + 0.5310i |
| Columns 3 through 4 | |
| 0.1092 + 0.3313i | 0.1450 − 0.3534i |
| 0.0948 + 0.5569i | 0.3176 − 0.5310i |
| 0.6247 | 0.3123 + 0.2672i |
| 0.3123 − 0.2672i | 0.5499 |
| m_cb(:, :, 16) = | |
| Columns 1 through 2 | |
| 0.6264 | 0.1144 + 0.1440i |
| 0.1144 − 0.1440i | 0.9095 |
| 0.0745 − 0.3217i | −0.1468 + 0.0698i |
| −0.2057 − 0.6499i | −0.1875 + 0.2784i |
| Columns 3 through 4 | |
| 0.0745 + 0.3217i | −0.2057 + 0.6499i |
| −0.1468 − 0.0698i | −0.1875 − 0.2784i |
| 0.7080 | −0.5186 − 0.3069i |
| −0.5186 + 0.3069i | −0.2439 |
| m_cb(:, :, 17) = | |
| Columns 1 through 2 | |
| 0.4732 | −0.0351 − 0.4319i |
| −0.0351 + 0.4319i | 0.6436 |
| −0.6207 + 0.4209i | −0.3864 − 0.4809i |
| −0.1480 + 0.0626i | −0.0612 − 0.1172i |
| Columns 3 through 4 | |
| −0.6207 − 0.4209i | −0.1480 − 0.0626i |
| −0.3864 + 0.4809i | −0.0612 + 0.1172i |
| −0.0678 | −0.2245 + 0.0445i |
| −0.2245 − 0.0445i | 0.9509 |
| m_cb(:, :, 18) = | |
| Columns 1 through 2 | |
| 0.4043 | −0.5936 + 0.1741i |
| −0.5936 − 0.1741i | 0.3575 |
| 0.4291 − 0.0666i | 0.4082 − 0.1918i |
| 0.5012 + 0.1184i | 0.5341 − 0.0285i |
| Columns 3 through 4 | |
| 0.4291 + 0.0666i | 0.5012 − 0.1184i |
| 0.4082 + 0.1918i | 0.5341 + 0.0285i |
| 0.6834 | −0.3478 + 0.1413i |
| −0.3478 − 0.1413i | 0.5548 |
| m_cb(:, :, 19) = | |
| Columns 1 through 2 | |
| 0.3300 | −0.1038 + 0.5703i |
| −0.1038 − 0.5703i | 0.4984 |
| 0.3323 − 0.0915i | −0.0264 − 0.2970i |
| −0.2763 − 0.5999i | −0.5535 + 0.1423i |
| Columns 3 through 4 | |
| 0.3323 + 0.0915i | −0.2763 + 0.5999i |
| −0.0264 + 0.2970i | −0.5535 − 0.1423i |
| 0.8227 | 0.0551 − 0.3353i |
| 0.0551 + 0.3353i | 0.3489 |
| m_cb(:, :, 20) = | |
| Columns 1 through 2 | |
| 0.6803 | −0.2432 − 0.5431i |
| −0.2432 + 0.5431i | −0.1076 |
| −0.1270 + 0.2543i | −0.5287 − 0.0222i |
| −0.2626 − 0.1825i | 0.1102 − 0.5849i |
| Columns 3 through 4 | |
| −0.1270 − 0.2543i | −0.2626 + 0.1825i |
| −0.5287 + 0.0222i | 0.1102 + 0.5849i |
| 0.7472 | 0.0408 + 0.2814i |
| 0.0408 − 0.2814i | 0.6801 |
| m_cb(:, :, 21) = | |
| Columns 1 through 2 | |
| 0.2751 | 0.1655 + 0.3560i |
| 0.1655 − 0.3560i | 0.7873 |
| −0.0849 + 0.3618i | 0.1971 − 0.0409i |
| 0.2054 + 0.7680i | 0.3303 − 0.2763i |
| Columns 3 through 4 | |
| −0.0849 − 0.3618i | 0.2054 − 0.7680i |
| 0.1971 + 0.0409i | 0.3303 + 0.2763i |
| 0.8095 | −0.3592 − 0.1925i |
| −0.3592 + 0.1925i | 0.1281 |
| m_cb(:, :, 22) = | |
| Columns 1 through 2 | |
| 0.2018 | 0.8742 + 0.1496i |
| 0.8742 − 0.1496i | 0.0145 |
| −0.1556 + 0.1843i | 0.2049 + 0.1727i |
| 0.2607 − 0.2157i | −3260 + 0.1874i |
| Column 3 through 4 | |
| −0.1556 − 0.1843i | 0.2607 + 0.2157i |
| 0.2049 + 0.1727i | −3260 − 0.1874i |
| 0.9271 | 0.1006 − 0.0182i |
| 0.1006 + 0.0182i | 0.8565 |
| m_cb(:, :, 23) = | |
| Columns 1 through 2 | |
| 0.4851 | −0.4030 − 0.2771i |
| −4030 + 0.2771i | 0.5354 |
| 0.3315 + 0.4502i | 0.0172 + 0.5307i |
| −0.1668 − 0.4303i | 0.1009 − 0.4266i |
| Columns 3 through 4 | |
| 0.3315 − 0.4502i | −0.1668 + 0.4303i |
| 0.0172 − 0.5307i | 0.1009 + 0.4266i |
| 0.3931 | 0.4836 − 0.1311i |
| 0.4836 + 0.1311i | 0.5864 |
| m_cb(:, :, 24) = | |
| Columns 1 through 2 | |
| 0.5810 | 0.1119 − 0.1280i |
| 0.1119 + 0.1280i | 0.9310 |
| −0.0461 − 0.0235i | 0.0195 − 0.0078i |
| −0.0396 + 0.7933i | −0.2318 − 0.2239i |
| Columns 3 through 4 | |
| −0.0461 + 0.0235i | −0.0396 − 0.7933i |
| 0.0195 + 0.0078i | −0.2318 + 0.2239i |
| 0.9936 | 0.0402 − 0.0895i |
| 0.0402 + 0.0895i | −0.5056 |
| m_cb(:, :, 25) = | |
| Columns 1 through 2 | |
| 0.4698 | 0.8120 − 0.0534i |
| 0.8120 + 0.0534i | −0.2488 |
| −0.0709 − 0.2272i | 0.1314 + 0.3409i |
| −0.1534 − 0.1923i | 0.2543 + 0.2790i |
| Columns 3 through 4 | |
| −0.0709 + 0.2272i | −0.1534 + 0.1923i |
| 0.1314 − 0.3409i | 0.2543 − 0.290i |
| 0.8931 | −0.1029 − 0.0401i |
| −0.1029 + 0.0401i | 0.8859 |
| m_cb(:, :, 26) = | |
| Columns 1 through 2 | |
| 0.3376 | − 0.0556 + 0.2153i |
| −0.0556 − 0.2153i | 0.9254 |
| −0.5304 + 0.6183i | 0.1564 + 0.2243i |
| 0.3649 − 0.1993i | −0.0341 − 0.1353i |
| Columns 3 through 4 | |
| −0.5304 − 0.6183i | 0.3649 + 0.1993i |
| 0.1564 − 0.2243i | −0.0341 + 0.1353i |
| −0.0020 | 0.4782 − 0.1811i |
| 0.4782 + 0.1811i | 0.7390 |
| m_cb(:, :, 27) = | |
| Columns 1 through 2 | |
| 0.6258 | −0.1124 − 0.3086i |
| −0.1124 + 0.3086i | 0.7117 |
| 0.4072 − 0.2116i | 0.2968 + 0.2723i |
| 0.1763 + 0.5087i | −0.3667 + 0.2982i |
| Columns 3 through 4 | |
| 0.4072 + 0.2116i | 0.1763 − 0.5087i |
| 0.2968 − 0.2723i | −0.3667 − 0.2982i |
| 0.4372 | 0.0959 + 0.6533i |
| 0.0959 − 0.6533i | 0.2253 |
| m_cb(:, :, 28) = | |
| Columns 1 through 2 | |
| 0.5255 | 0.3939 + 0.2804i |
| 0.3939 − 0.2804i | 0.5072 |
| 0.1818 − 0.4618i | −0.4238 + 0.2760i |
| −0.4844 − 0.0951i | 0.3459 + 0.3653i |
| Columns 3 through 4 | |
| 0.1818 + 0.4618i | −0.4844 + 0.0951i |
| −0.4238 − 0.2760i | 0.3459 − 0.3653i |
| 0.4809 | 0.0929 − 0.5079i |
| 0.0929 + 0.5079i | 0.4864 |
| m_cb(:, :, 29) = | |
| Columns 1 through 2 | |
| 0.7339 | 0.0575 − 0.0818i |
| 0.0575 + 0.0818i | 0.9624 |
| −0.6296 + 0.0292i | 0.1270 − 0.2000i |
| 0.2104 − 0.0990i | −0.0150 + 0.0861i |
| Columns 3 through 4 | |
| −6296 − 0.0292i | 0.2104 + 0.0990i |
| 0.1270 + 0.2000i | −0.0150 − 0.0861i |
| −0.4930 | 0.5088 + 0.2112i |
| 0.5088 − 0.2112i | 0.7967 |
| m_cb(:, :, 30) = | |
| Columns 1 through 2 | |
| 0.3226 | −0.1524 − 0.1960i |
| −0.1524 + 0.1960i | 0.9090 |
| 0.7728 − 0.1448i | 0.2157 + 0.1910i |
| 0.4423 + 0.1430i | 0.0581 + 0.1602i |
| Columns 3 through 4 | |
| 0.7728 + 0.1448i | 0.4423 − 0.1430i |
| 0.2157 − 0.1910i | 0.0581 − 0.1602i |
| 0.0874 | −0.4741 + 0.2577i |
| −0.4741 − 0.2577i | 0.6809 |
| m_cb(:, :, 31) = | |
| Columns 1 through 2 | |
| 0.3597 | −0.2781 + 0.4906i |
| −0.2781 − 0.4906i | 0.5033 |
| 0.2755 − 0.5384i | −0.2929 − 0.4449i |
| −0.3833 + 0.1998i | −0.0133 + 0.8305i |
| Columns 3 through 4 | |
| 0.2755 + 0.5384i | −0.3833 − 0.1998i |
| −0.2929 + 0.4449i | −0.0133 − 0.3805i |
| 0.4287 | 0.3329 − 0.2363i |
| 0.3329 + 0.2363i | 0.7082 |
| m_cb(:, :, 32) = | |
| Columns 1 through 2 | |
| 0.8936 | −0.1516 − 0.1154i |
| −0.1516 + 0.1154i | 0.6587 |
| −0.1195 − 0.0935i | −0.0688 − 0.2628i |
| 0.0609 − 0.3721i | 0.4904 − 0.4642i |
| Columns 3 through 4 | |
| −0.1195 + 0.0935i | 0.0609 + 0.3721i |
| −0.0688 + 0.2628i | 0.4904 + 0.4642i |
| 0.7837 | −0.2586 + 0.4713i |
| −0.2586 − 0.4713i | −0.3360 |
| m_cb(:, :, 33) = | |
| Columns 1 through 2 | |
| 0.1758 | −0.0345 − 0.1074i |
| −0.0345 + 0.1074i | 0.9846 |
| −0.5181 + 0.5298i | −0.0907 − 0.0453i |
| −0.3811 + 0.5118i | −0.0826 − 0.0282i |
| Columns 3 through 4 | |
| −0.5181 − 0.5298i | −0.3811 − 0.5118i |
| −0.0907 + 0.0453i | −0.0826 + 0.0282i |
| 0.3337 | −0.5686 − 0.0768i |
| −0.5686 + 0.0768i | 0.5059 |
| m_cb(:, :, 34) = | |
| Columns 1 through 2 | |
| 0.1191 | −0.8248 − 0.1153i |
| −0.8248 + 0.1153i | 0.2125 |
| −0.0024 − 0.4536i | 0.0571 − 0.4251i |
| 0.2507 + 0.1533i | 0.2147 + 0.1764i |
| Columns 3 through 4 | |
| −0.0024 + 0.4536i | 0.2507 − 0.1533i |
| 0.0571 + 0.4251i | 0.2147 − 0.1764i |
| 0.7664 | 0.0796 + 0.1287i |
| 0.0796 − 0.1287i | 0.9020 |
| m_cb(:, :, 35) = | |
| Columns 1 through 2 | |
| 0.6621 | −0.2525 + 0.2046i |
| −0.2525 − 0.2046i | 0.6874 |
| 0.3214 + 0.1313i | 0.3197 − 0.0965i |
| 0.1375 − 0.5626i | −0.2378 − 0.5037i |
| Columns 3 through 4 | |
| 0.3214 − 0.1313i | 0.1375 + 0.5626i |
| 0.3197 + 0.0965i | −0.2378 + 0.5037i |
| 0.6432 | 0.0878 − 0.5887i |
| 0.0878 + 0.5887i | 0.0073 |
| m_cb(:, :, 36) = | |
| Columns 1 through 2 | |
| 0.5015 | −0.2862 − 0.4416i |
| −0.2862 + 0.4416i | 0.4445 |
| −0.2458 + 0.2365i | −0.3506 − 0.0820i |
| −0.4113 + 0.4314i | −0.6182 − 0.1167i |
| Columns 3 through 4 | |
| −0.2458 − 0.2365i | −0.4113 − 0.4314i |
| −0.3508 + 0.0820i | −0.6182 + 0.1167i |
| 0.7666 | −0.4074 − 0.0175i |
| −0.4074 + 0.0175i | 0.2875 |
| m_cb(:, :, 37) = | |
| Columns 1 through 2 | |
| 0.1614 | 0.5947 − 0.4582i |
| 0.5947 + 0.4582i | 0.3279 |
| −0.1229 − 0.0033i | 0.0889 − 0.0648i |
| −0.5490 − 0.3063i | 0.5567 − 0.0827i |
| Columns 3 through 4 | |
| −0.1229 + 0.0033i | −0.5490 + 0.3063i |
| 0.0889 + 0.0648i | 0.5567 + 0.0827i |
| 0.9820 | −0.0816 + 0.0428i |
| −0.0816 − 0.0428i | 0.5287 |
| m_cb(:, :, 38) = | |
| Columns 1 through 2 | |
| 0.4525 | 0.3385 + 0.4039i |
| 0.3385 − 0.4039i | 0.4927 |
| −0.0662 + 0.4865i | 0.3998 − 0.2520i |
| 0.4930 − 0.1826i | −0.4396 − 0.2508i |
| Columns 3 through 4 | |
| −0.0662 − 0.4865i | 0.4930 + 0.1826i |
| 0.3998 + 0.2520i | −0.4396 + 0.2508i |
| 0.5597 | 0.2218 − 0.4160i |
| 0.2218 + 0.4160i | 0.4951 |
| m_cb(:, :, 39) = | |
| Columns 1 through 2 | |
| 0.4800 | −0.4788 − 0.5464i |
| −0.4788 + 0.5464i | −0.0151 |
| 0.3125 + 0.2377i | 0.0380 + 0.5473i |
| −0.2037 + 0.2147i | −0.4132 − 0.0163i |
| Column 3 through 4 | |
| 0.3125 − 0.2377i | −0.2037 − 0.2147i |
| 0.0380 − 0.5473i | −0.4132 + 0.0163i |
| 0.7035 | 0.0242 + 0.2222i |
| 0.0242 − 0.2222i | 0.8315 |
| m_cb(:, :, 40) = | |
| Columns 1 through 2 | |
| 0.2819 | 0.3244 + 0.0826i |
| 0.3244 − 0.0826i | 0.8440 |
| 0.1090 − 0.2542i | −0.0784 + 0.1023i |
| −0.7259 + 0.4528i | 0.3800 − 0.1211i |
| Columns 3 through 4 | |
| 0.1090 + 0.2542i | −0.7259 − 0.4528i |
| −0.0784 − 0.1023i | 0.3800 + 0.1211i |
| 0.8935 | 0.2705 − 0.1883i |
| 0.2705 + 0.1883i | −0.0194 |
| m_cb(:, :, 41) = | |
| Columns 1 through 2 | |
| 0.7411 | 0.5742 − 0.0764i |
| 0.5742 + 0.0764i | −0.2959 |
| −0.2356 + 0.0500i | 0.5077 − 0.1803i |
| 0.2346 + 0.0474i | −0.5342 − 0.0359i |
| Columns 3 through 4 | |
| −0.2356 − 0.0500i | 0.2346 − 0.0474i |
| 0.5077 + 0.1803i | −0.5342 + 0.0359i |
| 0.7760 | 0.2043 − 0.0884i |
| 0.2043 + 0.0884i | 0.7788 |
| m_cb(:, :, 42) = | |
| Columns 1 through 2 | |
| 0.1668 | −0.5822 − 0.0360i |
| −0.5822 + 0.0360i | 0.5917 |
| 0.2189 + 0.7604i | 0.1200 + 0.5408i |
| 0.0602 + 0.0463i | 0.0401 + 0.0349i |
| Columns 3 through 4 | |
| 0.2189 − 0.7604i | 0.0602 − 0.0463i |
| 0.1200 − 0.5408i | 0.0401 − 0.0349i |
| 0.2485 | −0.0581 − 0.0428i |
| −0.0581 + 0.0428i | 0.9931 |
| m_cb(:, :, 43) = | |
| Columns 1 through 2 | |
| 0.3285 | −0.1895 − 0.0198i |
| −0.1895 + 0.0198i | 0.9459 |
| 0.1261 − 0.5181i | 0.0509 − 0.1425i |
| 0.0010 + 0.7559i | −0.0220 + 0.2134i |
| Columns 3 through 4 | |
| 0.1281 + 0.5181i | 0.0010 − 0.7559i |
| 0.0509 + 0.1425i | −0.0220 − 0.2134i |
| 0.5766 | 0.5830 + 0.1428i |
| 0.5830 − 0.1428i | 0.1489 |
| m_cb(:, :, 44) = | |
| Columns 1 through 2 | |
| 0.8612 | 0.3610 − 0.0871i |
| 0.3610 + 0.0871i | 0.0062 |
| 0.2273 − 0.2023i | −0.4642 + 0.6690i |
| −0.0091 − 0.1665i | 0.1281 + 0.4273i |
| Columns 3 through 4 | |
| 0.2273 + 0.2023i | −0.0091 + 0.1665i |
| −0.4642 − 0.6690i | 0.1281 − 0.4273i |
| 0.3328 | −0.2278 − 0.2858i |
| −0.2278 + 0.2858i | 0.7998 |
| m_cb(:, :, 45) = | |
| Columns 1 through 2 | |
| 0.4721 | −0.1615 + 0.2107i |
| −0.1615 − 0.2107i | 0.8665 |
| −0.7948 + 0.1069i | −0.2005 + 0.3500i |
| − 0.1053 + 0.2288i | 0.0591 + 0.1120i |
| Columns 3 through 4 | |
| −0.7948 − 0.1069i | −0.1053 − 0.2288i |
| −0.2005 − 0.3500i | 0.0591 − 0.1120i |
| −0.2185 | −0.2048 − 0.3231i |
| −0.2048 + 0.3231i | 0.8799 |
| m_cb(:, :, 46) = | |
| Columns 1 through 2 | |
| 0.3065 | −0.2240 − 0.3579i |
| −0.2240 + 0.3579i | 0.7430 |
| −0.0063 − 0.6069i | 0.3111 − 0.1993i |
| 0.5974 + 0.0506i | 0.1669 + 0.3246i |
| Columns 3 through 4 | |
| −0.0063 + 0.6069i | 0.5974 − 0.0506i |
| 0.3111 + 0.1993i | 0.1669 − 0.3246i |
| 0.4688 | 0.0497 + 0.5223i |
| 0.0497 − 0.5223i | 0.4817 |
| m_cb(:, :, 47) = | |
| Columns 1 through 2 | |
| 0.5949 | 0.1557 + 0.2349i |
| 0.1557 − 0.2349i | 0.8039 |
| 0.6701 − 0.1265i | −0.3310 − 0.3400i |
| −0.0562 − 0.3138i | −0.1604 + 0.1532i |
| Columns 3 through 4 | |
| 0.6701 + 0.1265i | −0.0562 + 0.3138i |
| −0.3310 + 0.3400i | −0.1604 − 0.1532i |
| −0.1480 | −0.0051 − 0.5366i |
| −0.0051 + 0.5366i | 0.7492 |
| m_cb(:, :, 48) = | |
| Columns 1 through 2 | |
| 0.7806 | −0.4452 − 0.0626i |
| −0.4452 + 0.0626i | 0.0787 |
| −0.4040 − 0.0514i | −0.8051 − 0.2194i |
| −0.1043 + 0.1088i | −0.2426 + 0.1911i |
| Columns 3 through 4 | |
| −0.4040 + 0.0514i | −0.1043 − 0.1088i |
| −0.8051 + 0.2194i | −0.2426 − 0.1911i |
| 0.2443 | −0.1664 − 0.2248i |
| −0.1664 + 0.2248i | 0.8965 |
| m_cb(:, :, 49) = | |
| Columns 1 through 2 | |
| 0.2387 | 0.0441 − 0.2702i |
| 0.0441 + 0.2702i | 0.9015 |
| −0.1984 − 0.4442i | 0.1692 − 0.0447i |
| 0.0127 − 0.7945i | 0.2813 + 0.0505i |
| Columns 3 through 4 | |
| −0.1984 + 0.442i | 0.0127 + 0.7945i |
| 0.1692 + 0.0447i | 0.2813 − 0.0505i |
| 0.6891 | −0.4602 + 0.2145i |
| −0.4602 − 0.2145i | 0.1707 |
| m_cb(:, :, 50) = | |
| Columns 1 through 2 | |
| 0.2362 | 0.5885 + 0.2614i |
| 0.5885 − 0.2614i | 0.4571 |
| 0.3821 + 0.5878i | −0.0933 − 0.5837i |
| 0.1612 − 0.1097i | −0.1618 + 0.0293i |
| Columns 3 through 4 | |
| 0.3821 − 0.5878i | 0.1612 + 0.1097i |
| −0.0933 + 0.5837i | −0.1618 − 0.0293i |
| 0.3565 | 0.0037 − 0.1789i |
| 0.0037 + 0.1789i | 0.9502 |
| m_cb(:, :, 51) = | |
| Columns 1 through 2 | |
| 0.7098 | −0.6700 − 0.0265i |
| −0.6700 + 0.0265i | −0.5490 |
| 0.1179 + 0.0871i | 0.2642 + 0.2119i |
| 0.0780 − 0.1381i | 0.1926 − 0.3117i |
| Columns 3 through 4 | |
| 0.1179 − 0.0871i | 0.0780 + 0.1381i |
| 0.2642 − 0.2119i | 0.1926 + 0.3117i |
| 0.9259 | 0.0098 − 0.0795i |
| 0.0098 + 0.0795i | 0.9133 |
| m_cb(:, :, 52) = | |
| Columns 1 through 2 | |
| 0.2052 | −0.1721 − 0.0352i |
| −0.1721 + 0.0352i | 0.9612 |
| −0.1656 − 0.1102i | −0.0310 − 0.0312i |
| −0.9338 − 0.1244i | −0.1967 − 0.0683i |
| Columns 3 through 4 | |
| −0.1656 + 0.1102i | −0.9338 + 0.1244i |
| −0.0310 + 0.0312i | −0.1967 + 0.0683i |
| 0.9502 | −0.2118 − 0.1035i |
| −0.2118 + 0.1035i | −0.1165 |
| m_cb(:, :, 53) = | |
| Columns 1 through 2 | |
| 0.4765 | 0.6113 − 0.5146i |
| 0.6113 + 0.5146i | −0.2196 |
| −0.1360 + 0.3050i | −0.1410 − 0.4898i |
| −0.1514 − 0.0058i | 0.1824 − 0.1420i |
| Columns 3 through 4 | |
| −0.1360 − 0.3050i | −0.1514 + 0.0058i |
| −0.1410 + 0.4898i | 0.1824 + 0.1420i |
| 0.7870 | −0.0359 + 0.0897i |
| −0.0359 − 0.0897i | 0.9562 |
| m_cb(:, :, 54) = | |
| Columns 1 through 2 | |
| 0.4381 | −0.3936 + 0.4501i |
| −0.3936 − 0.4501i | 0.3638 |
| 0.0606 + 0.5087i | 0.4500 + 0.3078i |
| 0.4314 − 0.0443i | 0.2667 − 0.3766i |
| Columns 3 through 4 | |
| 0.0606 − 0.5087i | 0.4314 + 0.0443i |
| 0.4500 − 0.3078i | 0.2687 + 0.3766i |
| 0.5328 | −0.0064 − 0.3954i |
| −0.0064 + 0.3954i | 0.6652 |
| m_cb(:, :, 55) = | |
| Columns 1 through 2 | |
| 0.1984 | −0.3459 − 0.4714i |
| −0.3459 + 0.4714i | 0.5735 |
| 0.1674 − 0.1088i | 0.1362 + 0.0515i |
| −0.2883 + 0.7049i | −0.5381 + 0.1358i |
| Columns 3 through 4 | |
| 0.1674 + 0.1088i | −0.2863 − 0.7049i |
| 0.1362 − 0.0515i | −0.5381 − 0.1358i |
| 0.9503 | 0.1554 + 0.1083i |
| 0.1554 − 0.1083i | 0.2779 |
| m_cb(:, :, 56) = | |
| Columns 1 through 2 | |
| 0.5604 | 0.4187 − 0.4255i |
| 0.4187 + 0.4255i | 0.1895 |
| 0.3390 + 0.0502i | −0.3715 + 0.2803i |
| −0.4327 − 0.1581i | 0.5651 − 0.2682i |
| Columns 3 through 4 | |
| 0.3390 − 0.0502i | −0.4327 + 0.1581i |
| −0.3715 − 0.2803i | 0.5651 + 0.2682i |
| 0.7328 | 0.3517 − 0.0725i |
| 0.3517 + 0.0725i | 0.5173 |
| m_cb(:, :, 57) = | |
| Columns 1 through 2 | |
| 0.6569 | 0.1886 + 0.2454i |
| 0.1886 − 0.2454i | 0.7208 |
| −0.4445 + 0.1772i | 0.3711 + 0.2206i |
| 0.2727 + 0.4115i | 0.1445 − 0.4213i |
| Columns 3 through 4 | |
| −0.4445 − 0.1772i | 0.2727 − 0.4115i |
| 0.3711 − 0.2206i | 0.1445 + 0.4213i |
| 0.3326 | 0.1407 − 0.6740i |
| 0.1407 + 0.6740i | 0.2897 |
| m_cb(:, :, 58) = | |
| Columns 1 through 2 | |
| 0.1785 | 0.4085 − 0.5675i |
| 0.4085 + 0.5675i | 0.4049 |
| 0.1164 − 0.5210i | 0.3021 + 0.3395i |
| 0.4406 − 0.0086i | −0.2132 + 0.3087i |
| Columns 3 through 4 | |
| 0.1164 + 0.5210i | 0.4406 + 0.0086i |
| 0.3021 − 0.3395i | −0.2132 − 0.3087i |
| 0.6531 | −0.0679 + 0.2782i |
| −0.0679 − 0.2782i | 0.7636 |
| m_cb(:, :, 59) = | |
| Columns 1 through 2 | |
| 0.2846 | 0.2028 − 0.0401i |
| 0.2028 + 0.0401i | 0.9403 |
| 0.7669 − 0.0056i | −0.2171 + 0.0446i |
| −0.5189 − 0.1373i | 0.1548 + 0.0098i |
| Columns 3 through 4 | |
| 0.7669 + 0.0056i | −0.5189 + 0.1373i |
| −0.2171 − 0.0446i | 0.1548 − 0.0098i |
| 0.1779 | 0.5552 − 0.1512i |
| 0.5552 + 0.1512i | 0.5973 |
| m_cb(:, :, 60) = | |
| Columns 1 through 2 | |
| 0.9340 | 0.0187 − 0.0451i |
| 0.0187 + 0.0451i | 0.9639 |
| −0.0862 − 0.1445i | 0.1231 − 0.0179i |
| 0.1596 + 0.2674i | −0.2279 + 0.0330i |
| Columns 3 through 4 | |
| −0.0862 + 0.1445i | 0.1596 − 0.2674i |
| 0.1231 + 0.0179i | −0.2279 − 0.0330i |
| 0.5713 | 0.7936 − 0.0001i |
| 0.7936 + 0.0001i | −0.4691 |
| m_cb(:, :, 61) = | |
| Columns 1 through 2 | |
| 0.3030 | 0.3968 + 0.2460i |
| 0.3968 − 0.2460i | 0.6872 |
| −0.3832 − 0.5395i | 0.0278 + 0.4424i |
| −0.3259 − 0.3822i | 0.0507 + 0.3326i |
| Columns 3 through 4 | |
| −0.3832 + 0.5395i | −0.3259 + 0.3822i |
| 0.0278 − 0.4424i | 0.0507 − 0.3326i |
| 0.3717 | −0.4750 − 0.0421i |
| −0.4750 + 0.0421i | 0.6380 |
| m_cb(:, :, 62) = | |
| Columns 1 through 2 | |
| 0.1683 | −0.0101 − 0.3605i |
| −0.0101 + 0.3605i | 0.8436 |
| −0.8263 + 0.0847i | −0.0468 − 0.3571i |
| 0.3460 − 0.1786i | 0.0816 + 0.1478i |
| Columns 3 through 4 | |
| −0.8263 − 0.0847i | 0.3460 + 0.1786i |
| −0.0468 + 0.3571i | 0.0816 − 0.1478i |
| 0.1704 | 0.3620 + 0.1422i |
| 0.3620 − 0.1422i | 0.8177 |
| m_cb(:, :, 63) = | |
| Columns 1 through 2 | |
| 0.8254 | −0.1917 + 0.0197i |
| −0.1917 − 0.0197i | 0.7874 |
| 0.4523 − 0.1278i | 0.4821 − 0.1912i |
| 0.2452 − 0.0239i | 0.2665 − 0.0538i |
| Columns 3 through 4 | |
| 0.4523 + 0.1278i | 0.2452 + 0.0239i |
| 0.4821 + 0.1912i | 0.2665 + 0.0538i |
| −0.2651 | −0.6527 + 0.1176i |
| −0.6527 − 0.1176i | 0.6524 |
| m_cb(:, :, 64) = | |
| Columns 1 through 2 | |
| 0.4508 | −0.3114 + 0.3205i |
| −0.3114 − 0.3205i | 0.6364 |
| −0.3590 − 0.3506i | −0.4082 + 0.0107i |
| −0.5871 + 0.0230i | −0.3195 + 0.3557i |
| Columns 3 through 4 | |
| −0.3590 + 0.3506i | −0.5871 − 0.0230i |
| −0.4082 − 0.0107i | −0.3195 − 0.3557i |
| 0.5414 | −0.3692 − 0.3899i |
| −0.3692 + 0.3899i | 0.3714 |

The new codebook created by multiplying the above codebook by the phase rotation matrices R will now be described. For one transmission stream and 3-bit feedback information, the new codebook is given as follows according to the number of transmit antennas. For two or four transmit antennas, the phase rotation matrix R is the Hadamard matrix, Vandermonde matrix or FFT matrix. For three transmit antennas, the Vandermonde matrix and the FFT matrix are available as the phase rotation matrix R.

<Two Transmit Antennas, One Transmission Stream, 3-Bit Feedback Information, and Hadamard Matrix>

| Index | w1 | w2 | w3 | w4 | w5 | w6 | w7 | w8 |
|---|---|---|---|---|---|---|---|---|
| Antenna 1 | 0.07071 − | 0.1513 + | 0.6022 + | 0.3510 − | 0.9885 + | 0.7003 + 0.4766i | 0.6976 − 0.5063i | −0.3882 − 0.2461i |
| | 0.0000i | 0.1285i | 0.4279i | 0.3746i | 0.0487i | | | |
| Antenna 2 | −0.7071 − | −0.9716 + | −0.5208 + | −0.7721 − | −0.1346 + | 0.2351 + 0.4766i | −0.0253 − 0.5063i | −0.8533 − 0.2461i |
| | 0.0000i | 0.1285i | 0.4279i | 0.3746i | 0.0487i | | | |

<Two Transmit Antennas, One Transmission Stream, 3-Bit Feedback Information, and Vandermonde Matrix>

| Index | w1 | w2 | w3 | w4 | w5 | w6 | w7 | w8 |
|---|---|---|---|---|---|---|---|---|
| Antenna | 0.7071 | 0.1805 − | 0.2877 + j0.3313 | 0.6775 − j0.4138 | 0.8290 + j0.3363 | 0.2263 + j0.6677 | 0.9572 − j0.1203 | −0.0323 − j0.6130 |
| 1 | | j0.1991 | | | | | | |
| Antenna | 0.7071 | 0.9424 + | 0.8353 − j0.3313 | 0.4455 + j0.4138 | 0.2941 − j0.3363 | 0.2389 − j0.6677 | −0.2342 + j0.1203 | 0.4975 + j0.6130 |
| 2 | | j0.1991 | | | | | | |

<Three Transmit Antennas, One Transmission Stream, 3-Bit Feedback Information, and Vandermonde Matrix>

| Index | w1 | w2 | w3 | w4 | w5 | w6 | w7 | w8 |
|---|---|---|---|---|---|---|---|---|
| Antenna 1 | 0.5774 | 0.3509 − | 0.4444 + | −0.3981 + j0.0199 | 0.2240 + j0.2832 | 0.2389 + j0.5213 | 0.1397 | 0.9754 − j0.0304 |
| | | j0.2815 | j0.3855 | | | | j0.3867 | |
| Antenna 2 | 0.5774 | 0.6687 + | 0.6334 | 0.7689 − j0.0569 | −0.0844 − j0.5255 | 0.2079 + j0.1413 | −0.0633 + j0.4470 | −0.1892 + j0.0655 |
| | | j0.5198 | j0.4512 | | | | | |
| Antenna 3 | 0.5774 | −0.1535 − | −0.2118 + | 0.4953 + j0.0370 | 0.7264 + j0.2423 | 0.4111 − j0.6625 | 0.7897 − j0.0603 | 0.0799 − j0.0351 |
| | | j0.2383 | j0.0657 | | | | | |

<Four Transmit Antennas, One Transmission Stream, 3-Bit Feedback Information, and Hadamard Matrix>

| Index | w1 | w2 | w3 | w4 | w5 | w6 | w7 | w8 |
|---|---|---|---|---|---|---|---|---|
| Antenna 1 | 0.5000 − | 0.4313 − | −0.2151 + | 0.2255 − | −0.0075 + 0.0653i | 0.7890 + 0.4828i | 0.3381 − 0.2145i | −0.2381 + 0.1905i |
| | 0.0000i | 0.3250i | 0.2376i | 0.4355i | | | | |
| Antenna 2 | 0.5000 + | 0.5424 + | 0.3581 − | 0.2226 − | 0.4039 − 0.0163i | 0.0004 − 0.3003i | −0.4813 + 0.2979i | 0.2705 + 0.3124i |
| | 0.0000i | 0.4829i | 0.3843i | 0.3906i | | | | |
| Antenna 3 | 0.5000 − | −0.3231 − | −0.1172 − | 0.4355 + | 0.3013 + 0.5825i | 0.1137 − 0.1296i | 0.2457 + 0.0776i | 0.6779 − 0.5237i |
| | 0.0000i | 0.2417i | 0.1050i | 0.3415i | | | | |
| Antenna 4 | 0.5000 + | 0.1054 + | 0.7302 + | −0.1277 + | 0.0582 − 0.6315i | −0.1472 − 0.0529i | 0.6534 − 0.1610i | 0.0457 + 0.0208i |
| | 0.0000i | 0.0839i | 0.2517i | 0.4846i | | | | |

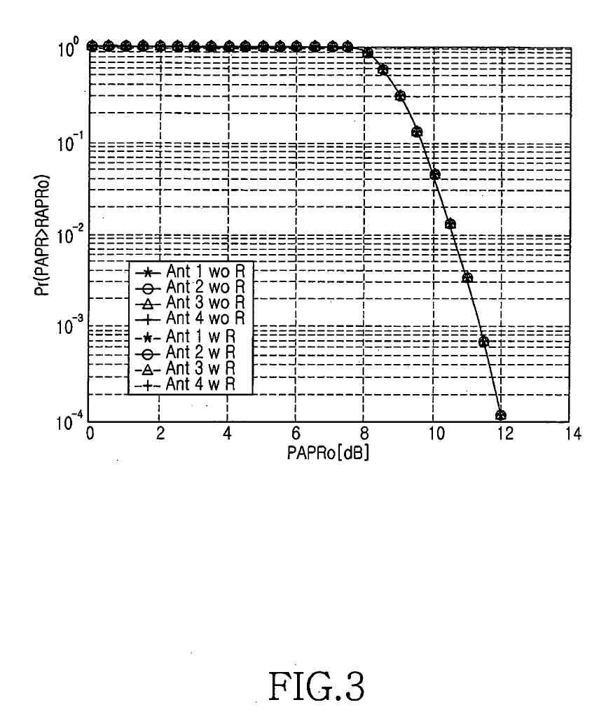

FIG. 3 is a graph illustrating the CCDF of the PAPRs of antennas for the use of the conventional codebook and the use of the codebook according to an exemplary embodiment of the present invention. As noted from FIG. 3, the PAPR is not changed irrespective of which codebook is used. In other words, no codebook influences the PAPR.

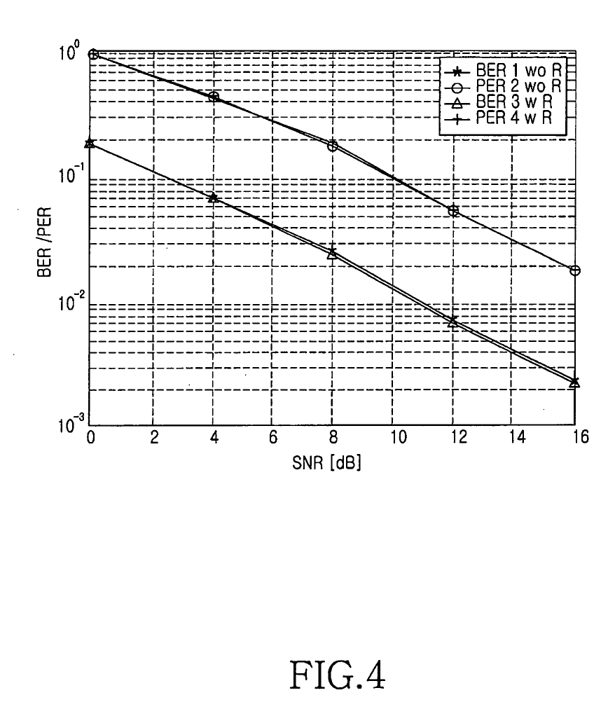

FIG. 4 is a graph comparing the conventional codebook, wo (without) R with the codebook according to an exemplary embodiment of the present invention, w (with) R in terms of link performance. Referring to FIG. 4, it is observed that since chordal distance is not changed in both wo R and w R, the same performance is achieved with w R as with wo R.

The simulation of FIGS. 3 and 4 was performed under the environment of the band Adaptive Modulation and Coding (AMC) subchannel defined in IEEE 802.16e, an LDPC code with R=½, and Red A 3 km/h.

As described above, certain exemplary embodiments of the present invention can avoid power imbalance between antennas caused by the use of the conventional codebook in a closed-loop MIMO system using a codebook. Furthermore, owing to the use of, for example, a simple phase rotation matrix (e.g. Hadamard or Vandermonde), the power imbalance and peak power problems are addressed without complexity.

While certain aspects of the present invention have been shown and described with reference to certain exemplary embodiments thereof, it will be understood by those skilled in the art that various changes in form and details may be made therein without departing from the spirit and scope of the invention as defined by the appended claims and equivalents thereof.

What is claimed is:

1. A transmitter in a multiple-input multiple-output (MIMO) system, the transmitter comprising:
a first calculator for generating a vector by multiplying a transmission vector by a beamforming matrix; and
a second calculator for generating at least one antenna signal by multiplying the vector by a phase rotation matrix.

2. The transmitter of claim 1, wherein the phase rotation matrix comprises a unitary matrix.

3. The transmitter of claim 1, wherein the phase rotation matrix comprises a Hadamard matrix.

4. The transmitter of claim 1, wherein the phase rotation matrix comprises a Vandermonde matrix.

5. The transmitter of claim 1, wherein the phase rotation matrix comprises
$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ]$$
where aᵢ=exp(j2π(i+¼)/Nₜ), (i=0, 1, 2, . . . , Nₜ−1)

6. The transmitter of claim 1, wherein the phase rotation matrix comprises a fast Fourier transform (FFT) matrix.

7. The transmitter of claim 1, wherein the phase rotation matrix comprises
$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ]$$
where aₖⁿ=exp(−j2π×k×n)/Nₜ), (k, n=0, 1, 2, . . . , Nₜ−1)

8. The transmitter of claim 1, wherein for at least two transmit antennas, the phase rotation matrix comprises
$${R}_{2} = \frac{1}{\sqrt{2}} [ \begin{matrix}1 & {ⅇ}^{j π / 4} \\ 1 & {ⅇ}^{j 5 π / 4}\end{matrix} ]$$

9. The transmitter of claim 1, wherein for at least three transmit antennas, the phase rotation matrix comprises
$${R}_{3} = \frac{1}{\sqrt{3}} [ \begin{matrix}1 & {ⅇ}^{j 5 π / 4} & {ⅇ}^{j 10 π / 9} \\ 1 & {ⅇ}^{j 11 π / 4} & {ⅇ}^{j 4 π / 9} \\ 1 & {ⅇ}^{j 17 π / 4} & {ⅇ}^{j 16 π / 9}\end{matrix} ]$$

10. The transmitter of claim 1, wherein the beamforming matrix is decided from a codebook based on feedback information.

11. A transmission method in a multiple-input multiple-output (MIMO) system, comprising the steps of:
generating a vector by multiplying a transmission vector by a beamforming matrix; and
generating at least one antenna signal by multiplying the vector by a phase rotation matrix.

12. The transmission method of claim 11, wherein the phase rotation matrix comprises a unitary matrix.

13. The transmission method of claim 11, wherein the phase rotation matrix comprises a Hadamard matrix.

14. The transmission method of claim 11, wherein the phase rotation matrix comprises a Vandermonde matrix.

15. The transmission method of claim 11, wherein the phase rotation matrix comprises
$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ]$$
where aᵢ=exp(j2π(i+¼)/Nₜ), (i=0, 1, 2, . . . , Nₜ−1)

16. The transmission method of claim 11, wherein the phase rotation matrix comprises a fast Fourier transform (FFT) matrix.

17. The transmission method of claim 11, wherein the phase rotation matrix comprises
$${R}_{{N}_{t}} = \frac{1}{\sqrt{{N}_{t}}} [ \begin{matrix}1 & {a}_{0}^{1} & {a}_{0}^{2} & ⋯ & {a}_{0}^{{N}_{t} - 1} \\ 1 & {a}_{1}^{1} & {a}_{1}^{2} & ⋯ & {a}_{1}^{{N}_{t} - 1} \\ ⋮ & ⋮ & ⋰ & ⋯ & ⋮ \\ 1 & {a}_{{N}_{t} - 1}^{1} & {a}_{{N}_{t} - 1}^{2} & ⋯ & {a}_{{N}_{t} - 1}^{{N}_{t} - 1}\end{matrix} ]$$
where aₖⁿ=exp(−j2π×k×n)/Nₜ), (k, n=0, 1, 2, . . . , Nₜ−1)

18. The transmission method of claim 11, wherein for at least two transmit antennas, the phase rotation matrix comprises
$${R}_{ 2} = \frac{1}{ \sqrt{2}} [ \begin{matrix}1 & {ⅇ}^{ j π / 4} \\ 1 & {ⅇ}^{ j 5 π / 4}\end{matrix} ]$$

19. The transmission method of claim 11, wherein for at least three transmit antennas, the phase rotation matrix comprises
$${R}_{3} = \frac{1}{\sqrt{3}} [ \begin{matrix}1 & {ⅇ}^{j 5 π / 4} & {ⅇ}^{j 10 π / 9} \\ 1 & {ⅇ}^{j 11 π / 4} & {ⅇ}^{j 4 π / 9} \\ 1 & {ⅇ}^{j 17 π / 4} & {ⅇ}^{j 16 π / 9}\end{matrix} ]$$

20. The transmission method of claim 11, wherein the beamforming matrix is decided from a codebook based on feedback information.

21. A transmitter in a multiple-input multiple-output (MIMO) system, the transmitter comprising:
a generator comprising a codebook comprising at least one new beamforming matrix created by multiplying a beamforming matrix by a phase rotation matrix, the generator generating a beamforming matrix by searching the codebook based on feedback information received from a receiver; and
a calculator for generating at least one antenna signal by multiplying a transmission vector by the generated beamforming matrix.

22. The transmitter of claim 21, wherein for at least two transmit antennas, one transmission stream, and 3-bit feedback information, the codebook comprises

| Index | w1 | w2 | w3 | w4 | w5 | w6 | w7 | w8 |
|---|---|---|---|---|---|---|---|---|
| Antenna | 0.07071 − | 0.1513 + | 0.6022 + | 0.3510 − 0.3746i | 0.9885 + 0.0487i | 0.7003 + 0.4766i | 0.6976 − 0.5063i | −0.3882 − 0.2461i |
| 1 | 0.0000i | 0.1285i | 0.4279i | | | | | |
| Antenna | −0.7071 − | −0.9716 + | −0.5208 + | −0.7721 − 0.3746i | −0.1346 + 0.0487i | 0.2351 + 0.4766i | −0.0253 − 0.5063i | −0.8533 − 0.2461i |
| 2 | 0.0000i | 0.1285i | 0.4279i | | | | | |

23. The transmitter of claim 21, wherein for at least two transmit antennas, one transmission stream, and 3-bit feedback information, the codebook comprises

| Index | w1 | w2 | w3 | w4 | w5 | w6 | w7 | w8 |
|---|---|---|---|---|---|---|---|---|
| Antenna | 0.7071 | 0.1805 − | 0.2877 + j0.3313 | 0.6775 − j0.4138 | 0.8290 + j0.3363 | 0.2263 + j0.6677 | 0.9572 − j0.1203 | −0.0323 − j0.6130 |
| 1 | | j0.1991 | | | | | | |
| Antenna | 0.7071 | 0.9424 + | 0.8353 − j0.3313 | 0.4455 + j0.4138 | 0.2941 − j0.3363 | 0.2389 − j0.6677 | −0.2342 + j0.1203 | 0.4975 + j0.6130 |
| 2 | | j0.1991 | | | | | | |

24. The transmitter of claim 21, wherein for at least three transmit antennas, one transmission stream, and 3-bit feedback information, the codebook comprises

| Index | w1 | w2 | w3 | w4 | w5 | w6 | w7 | w8 |
|---|---|---|---|---|---|---|---|---|
| Antenna 1 | 0.5774 | 0.3509 − | 0.4444 + | −0.3981 + j0.0199 | 0.2240 + j0.2832 | 0.2389 + j0.5213 | 0.1397 | 0.9754 − j0.0304 |
| | | j0.2815 | j0.3855 | | | | j0.3867 | |
| Antenna 2 | 0.5774 | 0.6687 + | 0.6334 | 0.7689 − j0.0569 | −0.0844 − j0.5255 | 0.2079 + j0.1413 | −0.0633 + j0.4470 | −0.1892 + j0.0655 |
| | | j0.5198 | j0.4512 | | | | | |
| Antenna 3 | 0.5774 | −0.1535 − | −0.2118 + | 0.4953 + j0.0370 | 0.7264 + j0.2423 | 0.4111 − j0.6625 | 0.7897 − j0.0603 | 0.0799 − j0.0351 |
| | | j0.2383 | j0.0657 | | | | | |

25. The transmitter of claim 21, wherein for at least four transmit antennas, one transmission stream, and 3-bit feedback information, the codebook comprises

| Index | w1 | w2 | w3 | w4 | w5 | w6 | w7 | w8 |
|---|---|---|---|---|---|---|---|---|
| Antenna 1 | 0.5000 − | 0.4313 − | −0.2151 + | 0.2255 − | −0.0075 + 0.0653i | 0.7890 + 0.4828i | 0.3381 − 0.2145i | −0.2381 + 0.1905i |
| | 0.0000i | 0.3250i | 0.2376i | 0.4355i | | | | |
| Antenna 2 | 0.5000 + | 0.5424 + | 0.3581 − | 0.2226 − | 0.4039 − 0.0163i | 0.0004 − 0.3003i | −0.4813 + 0.2979i | 0.2705 + 0.3124i |
| | 0.0000i | 0.4829i | 0.3843i | 0.3906i | | | | |
| Antenna 3 | 0.5000 − | −0.3231 − | −0.1172 − | 0.4355 + | 0.3013 + 0.5825i | 0.1137 − 0.1296i | 0.2457 + 0.0776i | 0.6779 − 0.5237i |
| | 0.0000i | 0.2417i | 0.1050i | 0.3415i | | | | |
| Antenna 4 | 0.5000 + | 0.1054 + | 0.7302 + | −0.1277 + | 0.0582 − 0.6315i | −0.1472 − 0.0529i | 0.6534 − 0.1610i | 0.0457 + 0.0208i |
| | 0.0000i | 0.0839i | 0.2517i | 0.4846i | | | | |

26. The transmitter of claim 21, wherein the phase rotation matrix comprises a Hadamard matrix.

27. The transmitter of claim 21, wherein the phase rotation matrix comprises a Vandermonde matrix.

28. The transmitter of claim 21, wherein the phase rotation matrix comprises a fast Fourier transform (FFT) matrix.

29. A transmission method in a multiple-input multiple-output (MIMO) system, comprising the steps of:
generating a beamforming matrix by searching a stored codebook based on feedback information received from a receiver, the codebook comprising new beamforming matrices created by multiplying predetermined beamforming matrices by a phase rotation matrix; and
generating at least one antenna signal by multiplying a transmission vector by the generated beamforming matrix.

30. The transmission method of claim 29, wherein for at least two transmit antennas, one transmission stream, and 3-bit feedback information, the codebook comprises

| Index | w1 | w2 | w3 | w4 | w5 | W6 | w7 | w8 |
|---|---|---|---|---|---|---|---|---|
| Antenna | 0.07071 − | 0.1513 + | 0.6022 + | 0.3510 − 0.3746i | 0.9885 + 0.0487i | 0.7003 + 0.4766i | 0.6976 − 0.5063i | −0.3882 − 0.2461i |
| 1 | 0.0000i | 0.1285i | 0.4279i | | | | | |
| Antenna | −0.7071 − | −0.9716 + | −0.5208 + | −0.7721 − 0.3746i | −0.1346 + 0.0487i | 0.2351 + 0.4766i | −0.0253 − 0.5063i | −0.8533 − 0.2461i |
| 2 | 0.0000i | 0.1285i | 0.4279i | | | | | |

31. The transmission method of claim 29, wherein for at least two transmit antennas, one transmission stream, and 3-bit feedback information, the codebook comprises

| Index | w1 | w2 | w3 | w4 | w5 | w6 | w7 | w8 |
|---|---|---|---|---|---|---|---|---|
| Antenna 1 | 0.7071 | 0.1805 − j0.1991 | 0.2877 + j0.3313 | 0.6775 − j0.4138 | 0.8290 + j0.3363 | 0.2263 + j0.6677 | 0.9572 − j0.1203 | −0.0323 − |
| | | | | | | | | j0.6130 |
| Antenna 2 | 0.7071 | 0.9424 + j0.1991 | 0.8353 − j0.3313 | 0.4455 + j0.4138 | 0.2941 − j0.3363 | 0.2389 − j0.6677 | −0.2342 + j0.1203 | 0.4975 + |
| | | | | | | | | j0.6130 |

32. The transmission method of claim 29, wherein for at least three transmit antennas, one transmission stream, and 3-bit feedback information, the codebook comprises

| Index | w1 | w2 | w3 | w4 | w5 | W6 | w7 | w8 |
|---|---|---|---|---|---|---|---|---|
| Antenna 1 | 0.5774 | 0.3509 − | 0.4444 + | −0.3981 + j0.0199 | 0.2240 + j0.2832 | 0.2389 + j0.5213 | 0.1397 | 0.9754 − j0.0304 |
| | | j0.2815 | j0.3855 | | | | j0.3867 | |
| Antenna 2 | 0.5774 | 0.6687 + | 0.6334 | 0.7689 − j0.0569 | −0.0844 − j0.5255 | 0.2079 + j0.1413 | −0.0633 + j0.4470 | −0.1892 + j0.0655 |
| | | j0.5198 | j0.4512 | | | | | |
| Antenna 3 | 0.5774 | −0.1535 − | −0.2118 + | 0.4953 + j0.0370 | 0.7264 + j0.2423 | 0.4111 − j0.6625 | 0.7897 − j0.0603 | 0.0799 − j0.0351 |
| | | j0.2383 | j0.0657 | | | | | |

33. The transmission method of claim 29, wherein for at least four transmit antennas, one transmission stream, and 3-bit feedback information, the codebook comprises

| Index | w1 | w2 | w3 | w4 | w5 | W6 | w7 | w8 |
|---|---|---|---|---|---|---|---|---|
| Antenna 1 | 0.5000 − | 0.4313 − | −0.2151 + | 0.2255 − | −0.0075 + 0.0653i | 0.7890 + 0.4828i | 0.3381 − 0.2145i | −0.2381 + |
| | 0.0000i | 0.3250i | 0.2376i | 0.4355i | | | | 0.1905i |
| Antenna 2 | 0.5000 + | 0.5424 + | 0.3581 − | 0.2226 − | 0.4039 − 0.0163i | 0.0004 − 0.3003i | −0.4813 + 0.2979i | 0.2705 + |
| | 0.0000i | 0.4829i | 0.3843i | 0.3906i | | | | 0.3124i |
| Antenna 3 | 0.5000 − | −0.3231 − | −0.1172 − | 0.4355 + | 0.3013 + 0.5825i | 0.1137 − 0.1296i | 0.2457 + 0.0776i | 0.6779 − |
| | 0.0000i | 0.2417i | 0.1050i | 0.3415i | | | | 0.5237i |
| Antenna 4 | 0.5000 + | 0.1054 + | 0.7302 + | −0.1277 + | 0.0582 − 0.6315i | −0.1472 − 0.0529i | 0.6534 − 0.1610i | 0.0457 + |
| | 0.0000i | 0.0839i | 0.2517i | 0.4846i | | | | 0.0208i |

34. The transmission method of claim 29, wherein the phase rotation matrix comprises a Hadamard matrix.

35. The transmission method of claim 29, wherein the phase rotation matrix comprises a Vandermonde matrix.

36. The transmission method of claim 29, wherein the phase rotation matrix comprises a fast Fourier transform (FFT) matrix.
